(19) United States
(12) Patent Application Publication
(10) Pub. No.: US 2024/0023422 A1
(43) Pub. Date: Jan. 18, 2024

(54) COMPOSITION, FILM, ORGANIC PHOTOELECTRIC CONVERSION ELEMENT, AND PHOTODETECTION ELEMENT

(71) Applicant: SUMITOMO CHEMICAL COMPANY, LIMITED, Tokyo (JP)

(72) Inventors: Xiaoxiao SHEN, Tsukuba-shi (JP); Miho OZEKI, Tsukuba-shi (JP)

(73) Assignee: SUMITOMO CHEMICAL COMPANY, LIMITED, Tokyo (JP)

(21) Appl. No.: 18/254,960

(22) PCT Filed: Dec. 3, 2021
(86) PCT No.: PCT/JP2021/044425

§ 371 Date: May 30, 2023

(30) Foreign Application Priority Data
Dec. 8, 2020 (JP) 2020-203132
Apr. 23, 2021 (JP) 2021-073138

(51) Int. Cl. H10K 85/10; C09D 11/52; H10K 85/60; H10K 30/20; H10K 30/50

(52) U.S. Cl. CPC H10K 85/113; C09D 11/52; H10K 85/151; H10K 85/6576; H10K 85/6572; H10K 85/626; H10K 85/141; H10K 85/143; H10K 30/20; H10K 30/50

(57) ABSTRACT

A composition containing a p-type semiconductor material and an n-type semiconductor material, an insulating material; and a solvent, wherein the n-type semiconductor material contains a non-fullerene compound, the insulating material is preferably a material that dissolves in an amount of 0.1 wt % or more at 25° C. in a solvent, preferably contains a polymer containing a constituent unit represented by Formula (I): wherein Rⁱ¹ represents a hydrogen atom, a halogen atom, or an alkyl group having 1 to 20 carbon atoms, and Rⁱ² represents a hydrogen atom, a halogen atom, an alkyl group having 1 to 20 carbon atoms, a group represented by the following Formula (II-1), a group represented by the following Formula (II-2), or a group represented by the following Formula (II-3).

### TECHNICAL FIELD

The present invention relates to a composition, a film, an organic photoelectric conversion element, and a photodetection element.

### BACKGROUND ART

Organic films containing a p-type semiconductor material and an n-type semiconductor material are used, for example, as an active layer included in photoelectric conversion elements.

Photoelectric conversion elements including an organic film have attracted attention as a power generation device extremely useful in view of, for example, energy saving and reduction in carbon dioxide emission, or a photodetection element of a highly sensitive photosensor.

When an organic film containing a p-type semiconductor material and an n-type semiconductor material is formed by coating using a composition as an ink, a spin coating method capable of easily producing a film having a uniform thickness is generally used. The spin coating method is a method of producing a film by dropping ink on a substrate and then rotating the substrate at a high speed to spread the ink on the substrate. In the spin coating method, the rotation speed at the time of coating is set high in order to improve the uniformity of the film thickness, but on the other hand, the film thickness becomes small under the high-speed rotation condition. For example, in the photodetection element, it is necessary to increase the thickness of the organic film to several 100 nm to several μm in order to suppress leakage current. In the case of using the spin coating method, it is usually necessary to increase the concentration or viscosity of the ink.

For example, in Patent Document 1, a composition containing insulative polymer particles in addition to an organic semiconductor material and a solvent is used as a material for forming an organic film by a coating method.

Non-Patent Document 1 discloses a composition containing P3HT and PCBM as an organic semiconductor material, PMMA as an insulating material, and a solvent.

### PRIOR ART DOCUMENTS

### Patent Document

Patent Document 1: JP-T-2018-525487

### Non-Patent Document

Non-Patent Document 1: Adv. Electron. Mater., 2018, 4, 1700345

### SUMMARY OF THE INVENTION

### Problems to be Solved by the Invention

In any of the above documents, improvement in the processability can be expected by adding an insulating material to increase the concentration of the solid content of the ink and increase the viscosity of the ink. However, the photocurrent characteristics of the organic photoelectric conversion element are deteriorated as compared with a case of using an ink containing no polymer particles.

In the step of forming a film containing a p-type semiconductor material and an n-type semiconductor material by a coating method, a composition stored for a long period of time after preparation may be used. In such a case, when the viscosity of the composition varies greatly, there may be a case where the coating conditions for obtaining a film having a predetermined thickness need to be greatly changed from the initial settings. However, the coating conditions are preferably not greatly changed in order to produce a film with stable quality. Therefore, a composition having less temporal change in viscosity is required.

An object of the present invention is to provide a composition containing a p-type semiconductor material and an n-type semiconductor material, the composition being capable of providing a film that has a uniform and predetermined thickness and exhibits less change in characteristics even when an insulating material is added; a film that can be produced from the composition; an organic photoelectric conversion element including the film; and a photodetection element including the organic photoelectric conversion element.

### Means for Solving the Problems

As a result of intensive studies to solve the above problems, the present inventors have found that the above problems can be solved by a composition containing a p-type semiconductor material, an n-type semiconductor material, an insulating material, and a solvent, in which the n-type semiconductor material contains a non-fullerene compound, and have completed the present invention.

That is, the present invention provides the following.

[1] A composition containing: a p-type semiconductor material; an n-type semiconductor material; an insulating material; and a solvent, wherein the n-type semiconductor material contains a non-fullerene compound.

[2] The composition according to [1], wherein the insulating material is a material that dissolves in an amount of 0.1 wt % or more in the solvent at 25° C.

[3] The composition according to [1] or [2], wherein the insulating material contains a polymer containing a constituent unit represented by the following Formula (I):

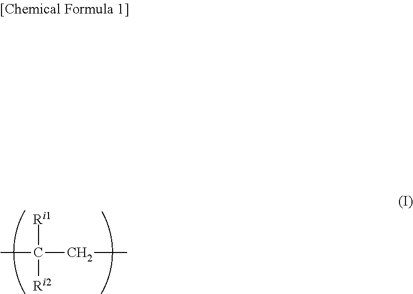

wherein
Rⁱ¹ represents a hydrogen atom, a halogen atom, or an alkyl group having 1 to 20 carbon atoms, and
Rⁱ² represents a hydrogen atom, a halogen atom, an alkyl group having 1 to 20 carbon atoms, a group represented by the following Formula (II-1), a group represented by the following Formula (II-2), or a group represented by the following Formula (II-3):

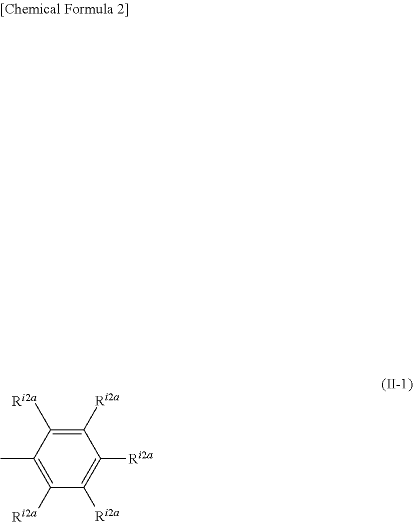

wherein
a plurality of R^{i2a}s each independently represent a hydrogen atom, a halogen atom, or an alkyl group having 1 to 20 carbon atoms;

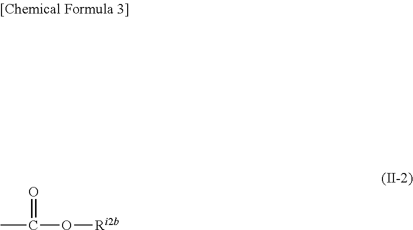

wherein
R^{i2b} represents a hydrogen atom or an alkyl group having 1 to 20 carbon atoms; and

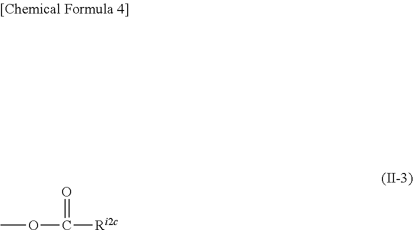

wherein
R^{i2c} represents an alkyl group having 1 to 20 carbon atoms.

[4] The composition according to any one of [1] to [3], wherein the p-type semiconductor material contains a polymer containing one or more types of constituent units selected from the group consisting of a constituent unit represented by the following Formula (III) and a constituent unit represented by the following Formula (IV):

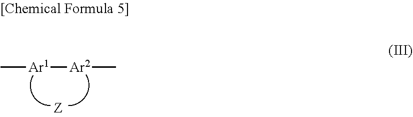

wherein
Ar¹ and Ar² each independently represent a trivalent aromatic heterocyclic group optionally having a substituent, and
Z represents a group represented by the following Formulae (Z-1) to (Z-7):

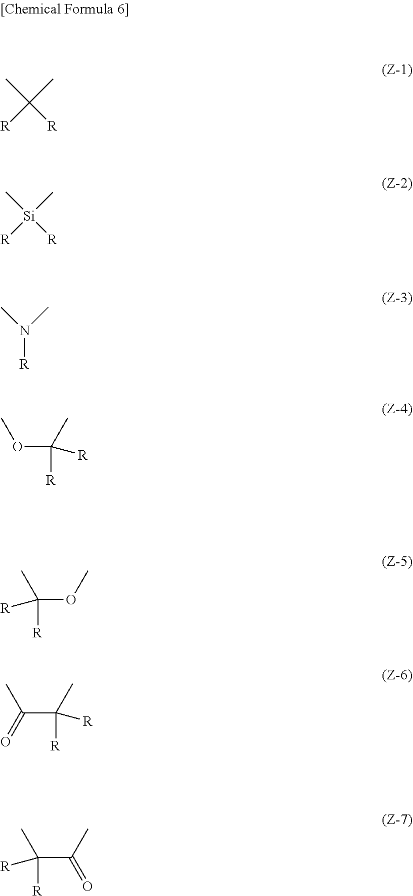

wherein
R is
a hydrogen atom,
a halogen atom,
an alkyl group optionally having a substituent,
a cycloalkyl group optionally having a substituent,
an alkenyl group optionally having a substituent,
a cycloalkenyl group optionally having a substituent,
an alkynyl group optionally having a substituent,
a cycloalkynyl group optionally having a substituent,
an aryl group optionally having a substituent,
an alkyloxy group optionally having a substituent,
a cycloalkyloxy group optionally having a
substituent,
an aryloxy group optionally having a substituent,
an alkylthio group optionally having a substituent,
a cycloalkylthio group optionally having a substituent,
an arylthio group optionally having a substituent,
a monovalent heterocyclic group optionally having a substituent,
a substituted amino group optionally having a substituent,
an imine residue optionally having a substituent,
an amide group optionally having a substituent,
an acid imide group optionally having a substituent,
a substituted oxycarbonyl group optionally having a substituent,
a cyano group,
a nitro group,
a group represented by —C(═O)—R^{a}, or
a group represented by —SO₂—R^{b},
R^{a} and R^{b} each independently represent
a hydrogen atom,
an alkyl group optionally having a substituent,
a cycloalkyl group optionally having a substituent,
an aryl group optionally having a substituent,
an alkyloxy group optionally having a substituent,
a cycloalkyloxy group optionally having a substituent,
an aryloxy group optionally having a substituent, or
a monovalent heterocyclic group optionally having a substituent, and
when there are two Rs, the two Rs may be the same or different; and

—Ar³— (IV)

wherein Ar³ represents a divalent aromatic heterocyclic group.

[5] A film containing: a p-type semiconductor material; an n-type semiconductor material; and an insulating material, wherein the n-type semiconductor material contains a non-fullerene compound.

[6] An organic photoelectric conversion element including: a first electrode; the film according to [5]; and a second electrode in this order.

[7] A photodetection element including the organic photoelectric conversion element according to [6].

### Effect of the Invention

According to the present invention, there is provided a composition containing a p-type semiconductor material and an n-type semiconductor material, the composition being capable of providing a film that has a uniform and predetermined thickness and exhibits less change in characteristics even when an insulating material is mixed; a film that can be produced from the composition; an organic photoelectric conversion element including the film; and a photodetection element including the organic photoelectric conversion element.

### BRIEF DESCRIPTION OF THE DRAWINGS

FIG. 1 is a schematic view illustrating a configuration example of a photoelectric conversion element.

FIG. 2 is a schematic view illustrating a configuration example of an image detection part.

FIG. 3 is a schematic view illustrating a configuration example of a fingerprint detection part.

FIG. 4 is a schematic view illustrating a configuration example of an image detection part for an X-ray imaging device.

FIG. 5 is a schematic view illustrating a configuration example of a vein detection part for a vein authentication device.

FIG. 6 is a schematic view illustrating a configuration example of an image detection part for a TOF type distance measuring device of an indirect method.

### MODE FOR CARRYING OUT THE INVENTION

### Explanation of Common Terms

Terms and the like commonly used in the following description will be described.

The “polymer compound” refers to a polymer having molecular weight distribution and having a number average molecular weight of 1×10³ or more and 1×10⁸ or less in terms of polystyrene. Note that the constituent units contained in the polymer are 100 mol % in total.

The “constituent unit” refers to a unit of a structure of the polymer.

The “hydrogen atom” may be a light hydrogen atom or a heavy hydrogen atom.

Examples of the “halogen atom” include a fluorine atom, a chlorine atom, a bromine atom, and an iodine atom.

The aspect “optionally having a substituent” includes both aspects of a case where all the hydrogen atoms constituting the compound or group are not substituted and a case where some or all of one or more hydrogen atoms are substituted with a substituent.

Examples of the substituent include a halogen atom, an alkyl group, a cycloalkyl group, an alkenyl group, a cycloalkenyl group, an alkynyl group, a cycloalkynyl group, an alkyloxy group, a cycloalkyloxy group, an alkylthio group, a cycloalkylthio group, an aryl group, an aryloxy group, an arylthio group, a monovalent heterocyclic group, a substituted amino group, an acyl group, an imine residue, an amide group, an acid imide group, a substituted oxycarbonyl group, a cyano group, an alkylsulfonyl group, and a nitro group.

The “alkyl group” may be linear or branched. The alkyl group may have a substituent. The number of carbon atoms of the alkyl group does not include the number of carbon atoms of the substituent, and is usually 1 to 50, preferably 1 to 30, and more preferably 1 to 20.

Examples of the alkyl group include an alkyl group having no substituent, such as a methyl group, an ethyl group, an n-propyl group, an isopropyl group, an n-butyl group, an isobutyl group, a tert-butyl group, an n-pentyl group, a 3-methylbutyl group, a 2-ethylbutyl group, an n-hexyl group, an n-heptyl group, an n-octyl group, a 2-ethylhexyl group, a 3-propylheptyl group, an n-decyl group, a 3,7-dimethyloctyl group, a 3-heptyldodecyl group, a 2-ethyloctyl group, a 2-hexyldecyl group, a dodecyl group, an n-tetradecyl group, a hexadecyl tomb, an octadecyl group, and an eicosyl group, and a group in which a hydrogen atom in these groups is substituted with a substituent such as an alkyloxy group, an aryl group, or a fluorine atom.

Specific examples of the alkyl having a substituent include a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di-hexylphenyl)propyl group, and a 6-ethyloxyhexyl group.

The “cycloalkyl group” may be a monocyclic group or a polycyclic group. The cycloalkyl group may have a substituent. The number of carbon atoms of the cycloalkyl group does not include the number of carbon atoms of the substituent, and is usually 3 to 30, and preferably 3 to 20.

Examples of the cycloalkyl group include an alkyl group having no substituent, such as a cyclopentyl group, a cyclohexyl group, a cycloheptyl group, or an adamantyl group, and a group in which a hydrogen atom in these groups is substituted with a substituent such as an alkyl group, an alkyloxy group, an aryl group, or a fluorine atom.

Specific examples of the cycloalkyl group having a substituent include a methylcyclohexyl group and an ethylcyclohexyl group.

The “alkenyl group” may be linear or branched. The alkenyl group may have a substituent. The number of carbon atoms of the alkenyl group does not include the number of carbon atoms of the substituent, and is usually 2 to 30, and preferably 2 to 20.

Examples of the alkenyl group include an alkenyl group having no substituent, such as a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, a 7-octenyl group, and a group in which a hydrogen atom in these groups is substituted with a substituent such as an alkyloxy group, an aryl group, or a fluorine atom.

The “cycloalkenyl group” may be a monocyclic group or a polycyclic group. The cycloalkenyl group may have a substituent. The number of carbon atoms of the cycloalkenyl group does not include the number of carbon atoms of the substituent, and is usually 3 to 30, and preferably 3 to 20.

Examples of the cycloalkenyl group include a cycloalkenyl group having no substituent, such as a cyclohexenyl group, and a group in which a hydrogen atom in these groups is substituted with a substituent such as an alkyl group, an alkyloxy group, an aryl group, or a fluorine atom.

Examples of the cycloalkenyl group having a substituent include a methylcyclohexenyl group and an ethylcyclohexenyl group.

The “alkynyl group” may be linear or branched. The alkynyl group may have a substituent. The number of carbon atoms of the alkynyl group does not include the number of carbon atoms of the substituent, and is usually 2 to 30, and preferably 2 to 20.

Examples of the alkynyl group include an alkynyl group having no substituent, such as an ethynyl group, a 1-propynyl group, a 2-propynyl group, a 2-butynyl group, a 3-butynyl group, a 3-pentynyl group, a 4-pentynyl group, a 1-hexynyl group, and a 5-hexynyl group, and a group in which a hydrogen atom in these groups is substituted with a substituent such as an alkyloxy group, an aryl group, or a fluorine atom.

The “cycloalkynyl group” may be a monocyclic group or a polycyclic group. The cycloalkynyl group may have a substituent. The number of carbon atoms of the cycloalkynyl group does not include the number of carbon atoms of the substituent, and is usually 4 to 30, and preferably 4 to 20.

Examples of the cycloalkynyl group include a cycloalkynyl group having no substituent, such as a cyclohexynyl group, and a group in which a hydrogen atom in these groups is substituted with a substituent such as an alkyl group, an alkyloxy group, an aryl group, or a fluorine atom.

Examples of the cycloalkynyl group having a substituent include a methylcyclohexynyl group and an ethylcyclohexynyl group.

The “alkyloxy group” may be linear or branched. The alkyloxy group may have a substituent. The number of carbon atoms of the alkyloxy group does not include the number of carbon atoms of the substituent, and is usually 1 to 30, and preferably 1 to 20.

Examples of the alkyloxy group include an alkyloxy group having no substituent, such as a methoxy group, an ethoxy group, an n-propyloxy group, an isopropyloxy group, an n-butyloxy group, an isobutyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, a 3,7-dimethyloctyloxy group, a 3-heptyldodecyloxy group, a lauryloxy group, and a group in which a hydrogen atom in these groups is substituted with a substituent such as an alkyloxy group, an aryl group, or a fluorine atom.

The cycloalkyl group included in the “cycloalkyloxy group” may be a monocyclic group or a polycyclic group. The cycloalkyloxy group may have a substituent. The number of carbon atoms of the cycloalkyloxy group does not include the number of carbon atoms of the substituent, and is usually 3 to 30, and preferably 3 to 20.

Examples of the cycloalkyloxy group include a cycloalkyloxy group having no substituent, such as a cyclopentyloxy group, a cyclohexyloxy group, and a cycloheptyloxy group, and a group in which a hydrogen atom in these groups is substituted with a substituent such as a fluorine atom or an alkyl group.

The “alkylthio group” may be linear or branched. The alkylthio group may have a substituent. The number of carbon atoms of the alkylthio group does not include the number of carbon atoms of the substituent, and is usually 1 to 30, and preferably 1 to 20.

Examples of the alkylthio group optionally having a substituent include a methylthio group, an ethylthio group, an n-propylthio group, an isopropylthio group, an n-butylthio group, an isobutylthio group, a tert-butylthio group, an n-pentylthio group, an n-hexylthio group, an n-heptylthio group, an n-octylthio group, a 2-ethylhexylthio group, an n-nonylthio group, an n-decylthio group, a 3,7-dimethyloctylthio group, a 3-heptyldodecylthio group, a laurylthio group, and a trifluoromethylthio group.

The cycloalkyl group included in the “cycloalkylthio group” may be a monocyclic group or a polycyclic group. The cycloalkylthio group may have a substituent. The number of carbon atoms of the cycloalkylthio group does not include the number of carbon atoms of the substituent, and is usually 3 to 30, and preferably 3 to 20.

Examples of the cycloalkylthio group optionally having a substituent include a cyclohexylthio group.

The “p-valent aromatic carbocyclic group” refers to a remaining atomic group in which p hydrogen atoms directly bonded to a carbon atom constituting a ring are removed from an aromatic hydrocarbon optionally having a substituent. The p-valent aromatic carbocyclic group may further have a substituent.

The “aryl group” refers to a monovalent aromatic carbocyclic group. The aryl group may have a substituent. The number of carbon atoms of the aryl group does not include the number of carbon atoms of the substituent, and is usually 6 to 60, and preferably 6 to 48.

Examples of the aryl group include an aryl group having no substituent, such as a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, a 4-phenylphenyl group, and a group in which a hydrogen atom in these groups is substituted with a substituent such as an alkyl group, an alkyloxy group, an aryl group, or a fluorine atom.

The “aryloxy group” may have a substituent. The number of carbon atoms of the aryloxy group does not include the number of carbon atoms of the substituent, and is usually 6 to 60, and preferably 6 to 48.

Examples of the aryloxy group include an aryloxy group having no substituent, such as a phenoxy group, a 1-naphthyloxy group, a 2-naphthyloxy group, a 1-anthracenyloxy group, a 9-anthracenyloxy group, a 1-pyrenyloxy group, and a group in which a hydrogen atom in these groups is substituted with a substituent such as an alkyl group, an alkyloxy group, or a fluorine atom.

The “arylthio group” may have a substituent. The number of carbon atoms of the arylthio group does not include the number of carbon atoms of the substituent, and is usually 6 to 60, and preferably 6 to 48.

Examples of the arylthio group optionally having a substituent include a phenylthio group, a C1 to C12 alkyloxyphenylthio group, a C1 to C12 alkylphenylthio group, a 1-naphthylthio group, a 2-naphthylthio group, and a pentafluorophenylthio group. The expression “C1 to C12” indicates that the number of carbon atoms of the group described immediately after the expression is 1 to 12. Further, the expression “Cm to Cn” indicates that the number of carbon atoms of the group described immediately after the expression is m to n. The same applies to the following.

The “p-valent heterocyclic group” (p represents an integer of 1 or more) refers to a remaining atomic group in which p hydrogen atoms among hydrogen atoms directly bonded to a carbon atom or heteroatom constituting a ring are removed from a heterocyclic compound optionally having a substituent. The “p-valent heterocyclic group” includes a “p-valent aromatic heterocyclic group”. The “p-valent aromatic heterocyclic group” refers to a remaining atomic group in which p hydrogen atoms among hydrogen atoms directly bonded to a carbon atom or heteroatom constituting a ring are removed from an aromatic heterocyclic compound optionally having a substituent.

The aromatic heterocyclic compound includes compounds in which a heterocyclic ring itself exhibits no aromaticity and an aromatic ring is condensed to the heterocyclic ring, in addition to compounds in which a heterocyclic ring itself exhibits aromaticity.

Among the aromatic heterocyclic compounds, specific examples of the compound in which a heterocyclic ring itself exhibits aromaticity include oxadiazole, thiadiazole, thiazole, oxazole, thiophene, pyrrole, phosphole, furan, pyridine, pyrazine, pyrimidine, triazine, pyridazine, quinoline, isoquinoline, carbazole, and dibenzophosphole.

Among the aromatic heterocyclic compounds, specific examples of the compound in which a heterocyclic ring itself exhibits no aromaticity and an aromatic ring is condensed to the heterocyclic ring include phenoxazine, phenothiazine, dibenzoborole, dibenzosilole, and benzopyran.

The p-valent heterocyclic group may have a substituent. The number of carbon atoms of the p-valent heterocyclic group does not include the number of carbon atoms of the substituent, and is usually 2 to 60, and preferably 2 to 20.

Examples of the monovalent heterocyclic group include a monovalent aromatic heterocyclic group (for example, a thienyl group, a pyrrolyl group, a furyl group, a pyridyl group, a quinolyl group, an isoquinolyl group, a pyrimidinyl group, and a triazinyl group), a monovalent nonaromatic heterocyclic group (for example, a piperidyl group, and a piperazyl group), and a group in which a hydrogen atom in these groups is substituted with a substituent such as an alkyl group, an alkyloxy group, or a fluorine atom.

The “substituted amino group” refers to an amino group having a substituent. The substituent included in the amino group is preferably an alkyl group, an aryl group, and a monovalent heterocyclic group. The number of carbon atoms of the substituted amino group does not include the number of carbon atoms of the substituent, and is usually 2 to 30.

Examples of the substituted amino group include a dialkylamino group (for example, a dimethylamino group, and a diethylamino group) and a diarylamino group (for example, a diphenylamino group, a bis(4-methylphenyl)amino group, a bis(4-tert-butylphenyl)amino group, and a bis(3,5-di-tert-butylphenyl)amino group).

The “acyl group” may have a substituent. The number of carbon atoms of the acyl group does not include the number of carbon atoms of the substituent, and is usually 2 to 20, and preferably 2 to 18. Specific examples of the acyl group include an acetyl group, a propionyl group, a butyryl group, an isobutyryl group, a pivaloyl group, a benzoyl group, a trifluoroacetyl group, and a pentafluorobenzoyl group.

The “imine residue” refers to a remaining atomic group in which one hydrogen atom directly bonded to a carbon atom or a nitrogen atom constituting a carbon atom-nitrogen atom double bond is removed from an imine compound. The “imine compound” refers to an organic compound having a carbon atom-nitrogen atom double bond in the molecule. Examples of the imine compound include aldimine, ketimine, and compounds in which a hydrogen atom bonded to a nitrogen atom constituting a carbon atom-nitrogen atom double bond in aldimine is substituted with an alkyl group or the like.

The number of carbon atoms of the imine residue is usually 2 to 20, and preferably 2 to 18. Examples of the imine residue include groups represented by the following structural formula.

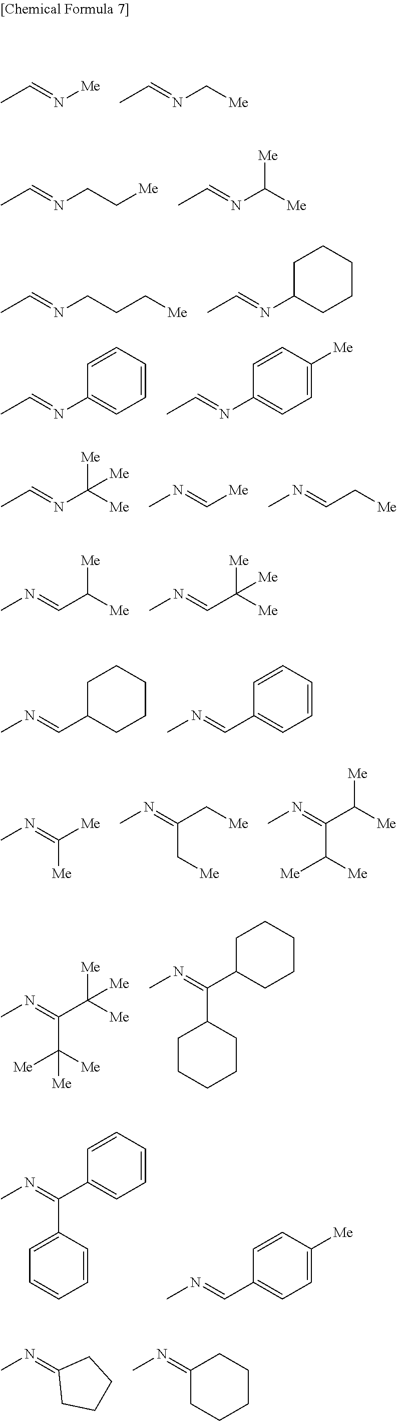

The “amide group” refers to a remaining atomic group in which one hydrogen atom bonded to a nitrogen atom is removed from amide. The number of carbon atoms of the amide group is usually 1 to 20, and preferably 1 to 18. Specific examples of the amide group include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group, and a dipentafluorobenzamide group.

The “acid imide group” refers to a remaining atomic group in which one hydrogen atom bonded to a nitrogen atom is removed from acid imide. The number of carbon atoms of the acid imide group is usually 4 to 20. Specific examples of the acid imide group include groups represented by the following structural formulae.

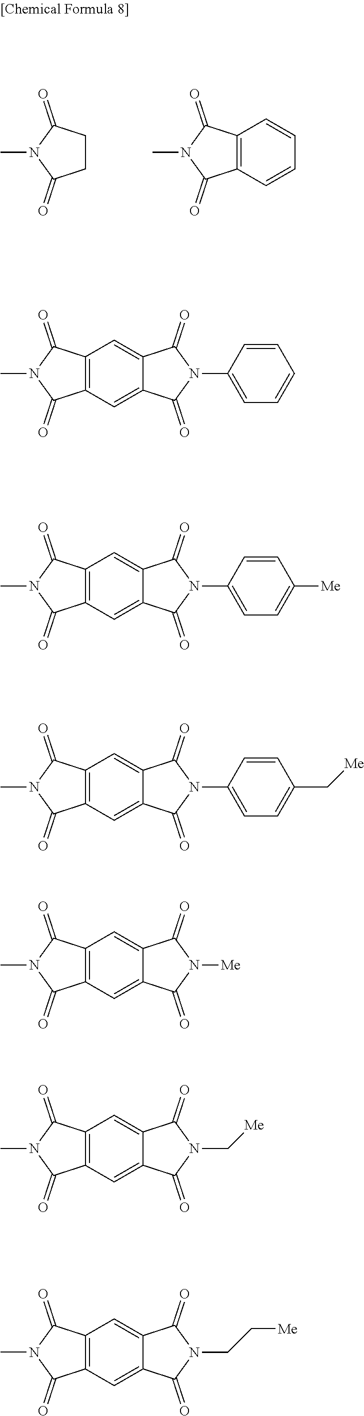

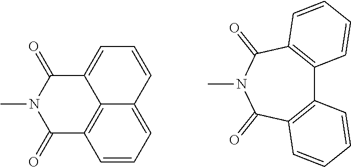 [SMILES: CN1C(=O)c2cccc3cccc(c23)C1=O ; Cn1c(=O)c2ccccc2c2ccccc2c1=O]

The “substituted oxycarbonyl group” refers to a group represented by R′—O—(C═O)—.

Here, R′ represents an alkyl group, a cycloalkyl group, an aryl group, an arylalkyl group, or a monovalent heterocyclic group, and these groups may have a substituent.

The number of carbon atoms of the substituted oxycarbonyl group does not include the number of carbon atoms of the substituent, and is usually 2 to 60, and preferably 2 to 48.

Specific examples of the substituted oxycarbonyl group include a methoxycarbonyl group, an ethoxycarbonyl group, a propoxycarbonyl group, an isopropoxycarbonyl group, a butoxycarbonyl group, an isobutoxycarbonyl group, a tert-butoxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenoxycarbonyl group, a naphthoxycarbonyl group, and a pyridyloxycarbonyl group.

The “alkylsulfonyl group” may be linear or branched. The alkylsulfonyl group may have a substituent. The number of carbon atoms of the alkylsulfonyl group does not include the number of carbon atoms of the substituent, and is usually 1 to 30. Specific examples of the alkylsulfonyl group include a methylsulfonyl group, an ethylsulfonyl group, and a dodecylsulfonyl group.

The symbol “*” attached to the chemical formula represents a bond.

The “π conjugated system” refers to a system in which n electrons are delocalized in a plurality of bonds.

The term “(meth)acryl” includes acryl, methacryl, and a combination thereof.

[1. Composition]

A composition according to one embodiment of the present invention is a composition containing a p-type semiconductor material, an n-type semiconductor material, an insulating material, and a solvent, in which the n-type semiconductor material contains a non-fullerene compound.

By providing a composition containing an insulating material, the concentration and/or viscosity of the solid content of the composition can be increased. As a result, the film formability in the step of applying the composition can be improved.

By providing a composition in which the n-type semiconductor material contains a non-fullerene compound, it is possible to suppress deterioration of characteristics of a film produced from the composition, which may occur when the composition contains an insulating material.

The composition of the present invention may contain a fullerene compound. However, it is considered that an n-type semiconductor material composed of a non-fullerene compound exhibits an effect, as compared with an n-type semiconductor material composed of only a fullerene compound from the following viewpoint.

Regarding an effect of suppressing deterioration of photoelectric conversion characteristics in a composition containing an insulating material, a difference in the effect between a general conventional art using only a fullerene compound as an n-type semiconductor material and the present invention using a non-fullerene compound will be described. It is known that photoelectric conversion in an organic film occurs very near an interface (pn interface) between a p-type semiconductor material and an n-type semiconductor material. Therefore, in order to exhibit higher photoelectric conversion characteristics, a structure in which the p-type semiconductor material and the n-type semiconductor material are finely phase-separated in the organic film is preferable. Here, a fullerene compound used as a general n-type semiconductor material in the conventional art has a three-dimensional bulky skeleton. Therefore, when aggregation of the fullerene compound proceeds, the fullerene compound easily forms coarse particles having a size on the order of micrometers. In a state where the concentration and/or viscosity of the solid content of the composition containing an insulating material in the present invention is high, dispersion of the fullerene compound in the solution is restricted, so that aggregation of the fullerene compound in the ink proceeds. The resulting organic film has phase separation with a coarse structure, and has a small pn interface area, and thus exhibits low photoelectric conversion characteristics. On the other hand, in the present invention, use of a non-fullerene compound as an n-type semiconductor material suppresses progress of aggregation and coarsening of the n-type semiconductor material even in a state where the concentration and viscosity of the composition are high. As a result, fine phase separation is obtained even when an insulating material is added, resulting in high photoelectric conversion characteristics. However, the above presumption does not limit the present invention.

[1.1. p-Type Semiconductor Material and n-Type Semiconductor Material]

The composition of the present embodiment contains a p-type semiconductor material and an n-type semiconductor material. The p-type semiconductor material contains at least one type of electron-donating compound, and the n-type semiconductor material contains at least one type of electron-accepting compound. Whether the semiconductor material contained in the composition functions as either the p-type semiconductor material or the n-type semiconductor material may be relatively determined based on the value of the energy level of the HOMO or the value of the energy of the LUMO of the selected compound. The relationship between the values of the energy levels of the HOMO and LUMO of the p-type semiconductor material and the values of the energy levels of the HOMO and LUMO of the n-type semiconductor material can be appropriately set within a range in which a film produced from the composition exhibits a desired function (for example, a photoelectric conversion function and a photodetection function).

In the composition, the p-type semiconductor material and the n-type semiconductor material may be dissolved or dispersed.

Preferably, at least a part of the p-type semiconductor material and the n-type semiconductor material is dissolved, or more preferably, all of them are dissolved.

(p-Type Semiconductor Material)

The p-type semiconductor material is preferably a polymer compound. Examples of the p-type semiconductor material which is a polymer compound include polyvinylcarbazole and a derivative thereof, polysilane and a derivative thereof, a polysiloxane derivative containing an aromatic amine structure in a side chain or the main chain thereof, polyaniline and a derivative thereof, polythiophene and a derivative thereof, polypyrrole and a derivative thereof, polyphenylene vinylene and a derivative thereof, polythienylene vinylene and a derivative thereof, polyfluorene and a derivative thereof, and a polymer containing one or more types of constituent units selected from the group consisting of a constituent unit represented by the following Formula (III) and a constituent unit represented by the following Formula (IV).

The composition according to the present embodiment may contain only one type of compound or a plurality types of compounds as the p-type semiconductor material.

The p-type semiconductor material according to the present embodiment preferably contains a polymer containing one or more types of constituent units selected from the group consisting of a constituent unit represented by the following Formula (III) and a constituent unit represented by the following Formula (IV).

Hereinafter, the polymer containing one or more types of constituent units selected from the group consisting of a constituent unit represented by Formula (III) and a constituent unit represented by Formula (IV) is also referred to as a polymer (3/4).

When the amount of all the constituent units contained in the polymer (3/4) is 100 mol %, the total amount of the constituent unit represented by Formula (III) and the constituent unit represented by Formula (IV) in the polymer (3/4) is preferably 20 mol % to 100 mol %, and more preferably 40 mol % to 100 mol %, and still more preferably 50 mol % to 100 mol % because the charge transportability as a p-type semiconductor material can be improved.

In one embodiment, the p-type semiconductor material preferably contains a polymer containing a constituent unit represented by the following Formula (III). Hereinafter, the polymer containing a constituent unit represented by Formula (III) is also referred to as a polymer (3). The p-type semiconductor material may contain only one type of the polymer (3), or two or more types thereof. The polymer (3) may contain only one type of the constituent unit represented by Formula (III), or two or more types thereof.

The polymer (3) may further contain a constituent unit represented by Formula (IV) described later.

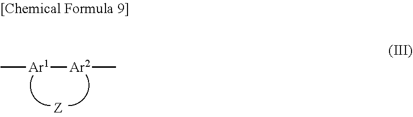

In Formula (III), Ar¹ and Ar² each independently represent a trivalent aromatic heterocyclic group optionally having a substituent.

Z represents a group represented by the following Formulae (Z-1) to (Z-7).

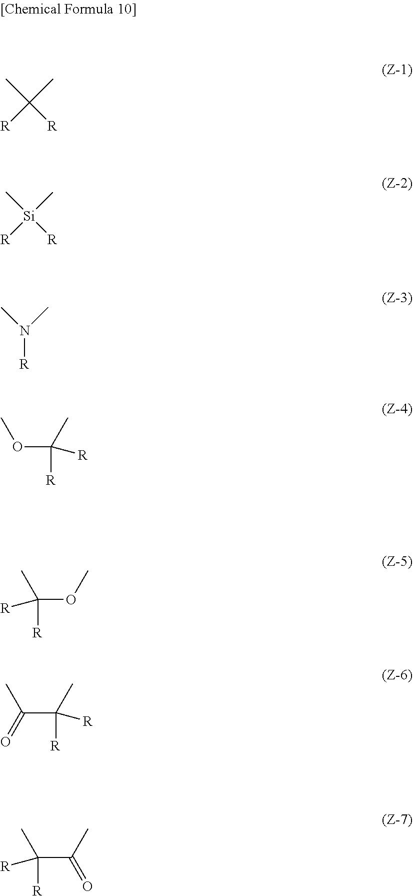

In Formulae (Z-1) to (Z-7), R is
a hydrogen atom,
a halogen atom,
an alkyl group optionally having a substituent,
a cycloalkyl group optionally having a substituent,
an alkenyl group optionally having a substituent,
a cycloalkenyl group optionally having a substituent,
an alkynyl group optionally having a substituent,
a cycloalkynyl group optionally having a substituent,
an aryl group optionally having a substituent,
an alkyloxy group optionally having a substituent,
a cycloalkyloxy group optionally having a substituent,
an aryloxy group optionally having a substituent,
an alkylthio group optionally having a substituent,
a cycloalkylthio group optionally having a substituent,
an arylthio group optionally having a substituent,
a monovalent heterocyclic group optionally having a substituent,
a substituted amino group optionally having a substituent,
an imine residue optionally having a substituent,
an amide group optionally having a substituent,
an acid imide group optionally having a substituent,
a substituted oxycarbonyl group optionally having a substituent,
a cyano group,
a nitro group,
a group represented by —C(═O)—R^{a}, or
a group represented by —SO₂—R^{b},
R^{a} and R^{b} each independently represent a hydrogen atom,
an alkyl group optionally having a substituent,
a cycloalkyl group optionally having a substituent,
an aryl group optionally having a substituent,
an alkyloxy group optionally having a substituent,
a cycloalkyloxy group optionally having a substituent,
an aryloxy group optionally having a substituent, or
a monovalent heterocyclic group optionally having a substituent.

In Formulae (Z-1) to (Z-7), when there are two Rs, the two Rs may be the same or different.

Examples of the aromatic heterocyclic ring constituting the trivalent aromatic heterocyclic group represented by Ar¹ or Ar² include an oxadiazole ring, a thiadiazole ring, a thiazole ring, an oxazole ring, a thiophene ring, a pyrrole ring, a phosphole ring, a furan ring, a pyridine ring, a pyrazine ring, a pyrimidine ring, a triazine ring, a pyridazine ring, a quinoline ring, an isoquinoline ring, a carbazole ring, and a dibenzophosphole ring, and a phenoxazine ring, a phenothiazine ring, a dibenzoborole ring, a dibenzosilole ring, and a benzopyran ring. These rings may have a substituent.

Z is preferably a group represented by any one of Formulae (Z-4), (Z-5), (Z-6), and (Z-7), and more preferably a group represented by Formula (Z-4) or (Z-5).

R in Formulae (Z-1) to (Z-7) is preferably a hydrogen atom, an alkyl group, or an aryl group, more preferably a hydrogen atom or an alkyl group, still more preferably a hydrogen atom or an alkyl group having 1 to 40 carbon atoms, still more preferably a hydrogen atom or an alkyl group having 1 to 30 carbon atoms, and still more preferably a hydrogen atom or an alkyl group having 1 to 20 carbon atoms. These groups may have a substituent. When there are a plurality of Rs, the plurality of Rs may be the same or different from each other.

In one embodiment, the constituent unit represented by Formula (III) is preferably a constituent unit represented by any one of the following Formulae (III-T1) to (III-T5), and more preferably a constituent unit represented by Formula (III-T4) or (III-T5).

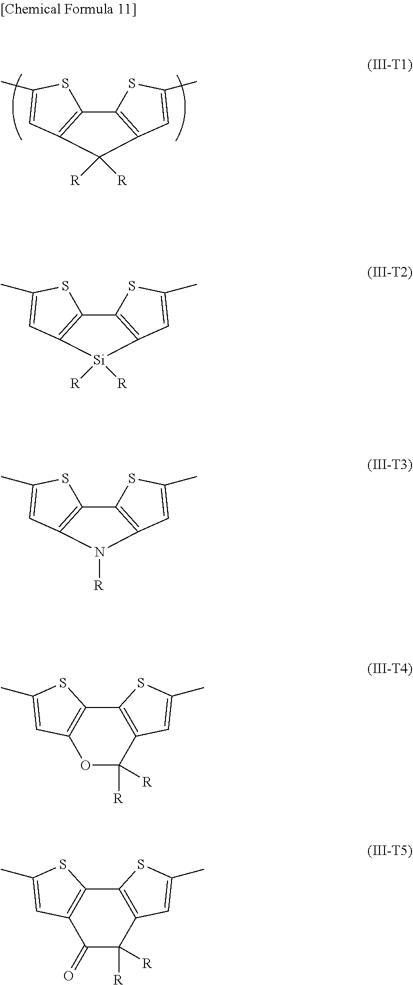

In Formulae (III-T1) to (III-T5), R is the same as defined in Formulae (Z-1) to (Z-7). When there are a plurality of Rs, the plurality of Rs may be the same or different from each other. Preferred R in Formulae (III-T1) to (III-T5) is the same as the groups described as preferred R in Formulae (Z-1) to (Z-7).

In one embodiment, the constituent unit represented by Formula (III) is preferably a constituent unit represented by the following Formula (III-1) or (III-2).

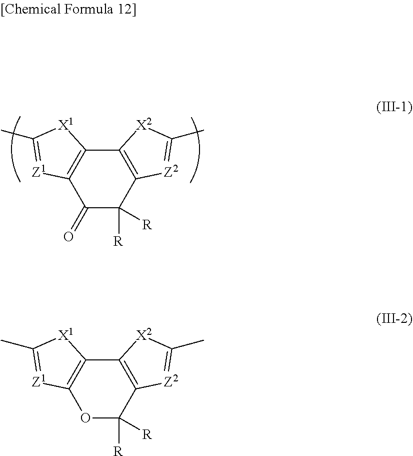

In Formulae (III-1) and (III-2), X¹ and X² are each independently a sulfur atom or an oxygen atom, Z¹ and Z² are each independently a group represented by ═C(R)— or a nitrogen atom, and R is the same as defined in Formulae (Z-1) to (Z-7). A plurality of Rs may be the same or different from each other.

The constituent unit represented by Formula (III-1) is preferably a constituent unit in which X¹ and X² are a sulfur atom, and Z¹ and Z² are a group represented by ═C(R)—. R in the group represented by ═C(R)— as Z¹ and Z² is preferably a hydrogen atom.

The constituent unit represented by Formula (III-2) is preferably a constituent unit in which X¹ and X² are a sulfur atom, and Z¹ and Z² are a group represented by ═C(R)—. R in the group represented by ═C(R)— as Z¹ and Z² is preferably a hydrogen atom.

Examples of the constituent unit (III-1) include constituent units represented by the following Formulae (III-1-1) to (III-1-14). In the following Formulae (III-1-1) to (III-1-14), R is the same as defined in Formulae (Z-1) to (Z-7). A plurality of Rs may be the same or different from each other.

Among them, a constituent unit represented by Formula (III-1-1) is preferable.

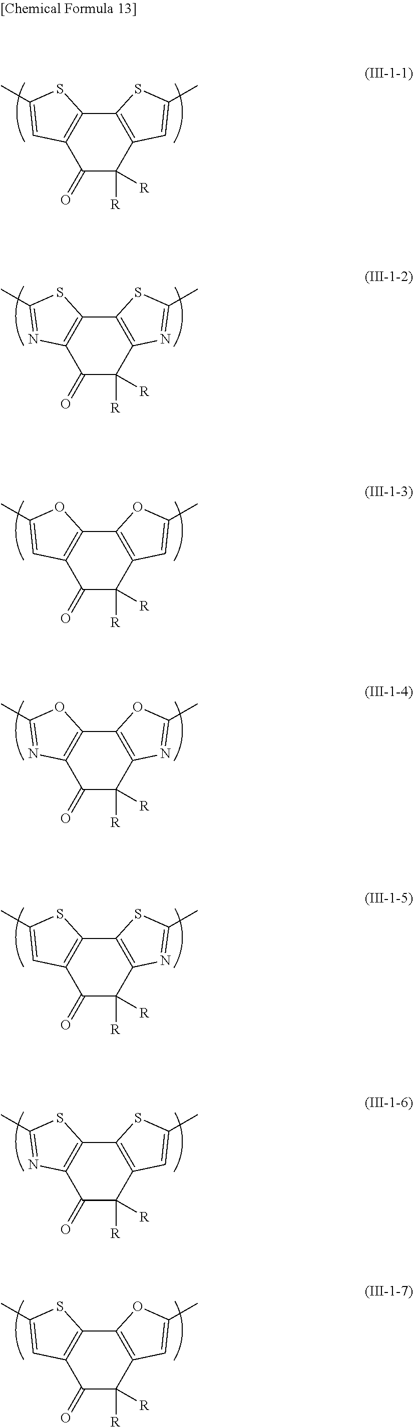

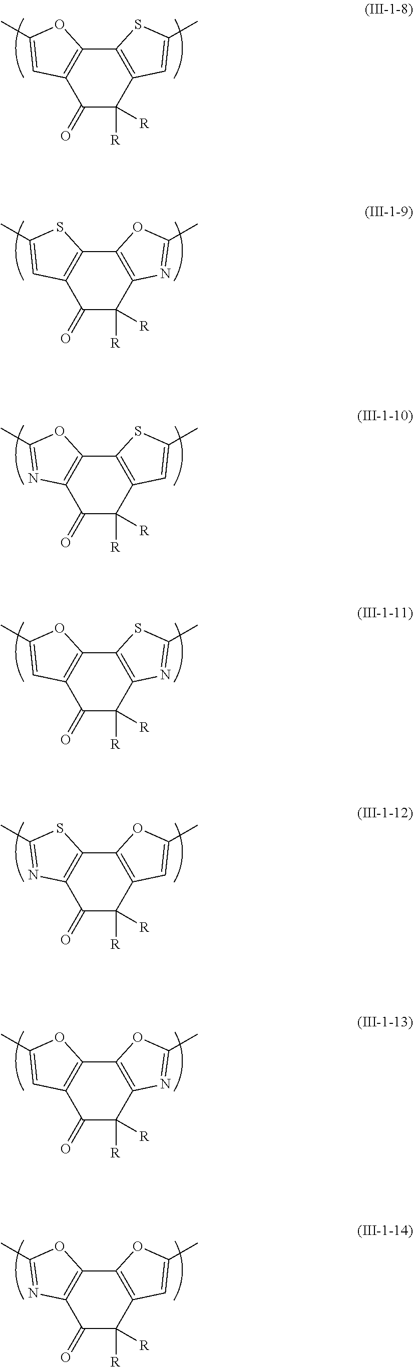

Examples of the constituent unit (III-2) include constituent units represented by the following Formulae (III-2-1) to (III-2-14). In the following Formulae (III-2-1) to (III-2-14), R is the same as defined in Formulae (Z-1) to (Z-7). A plurality of Rs may be the same or different from each other.

Among them, a constituent unit represented by Formula (III-2-1) is preferable.

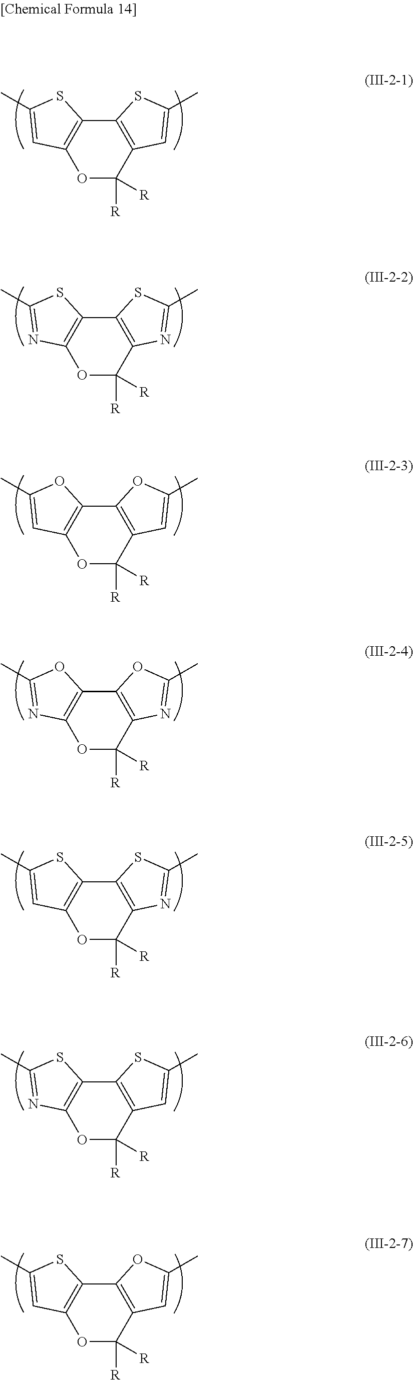

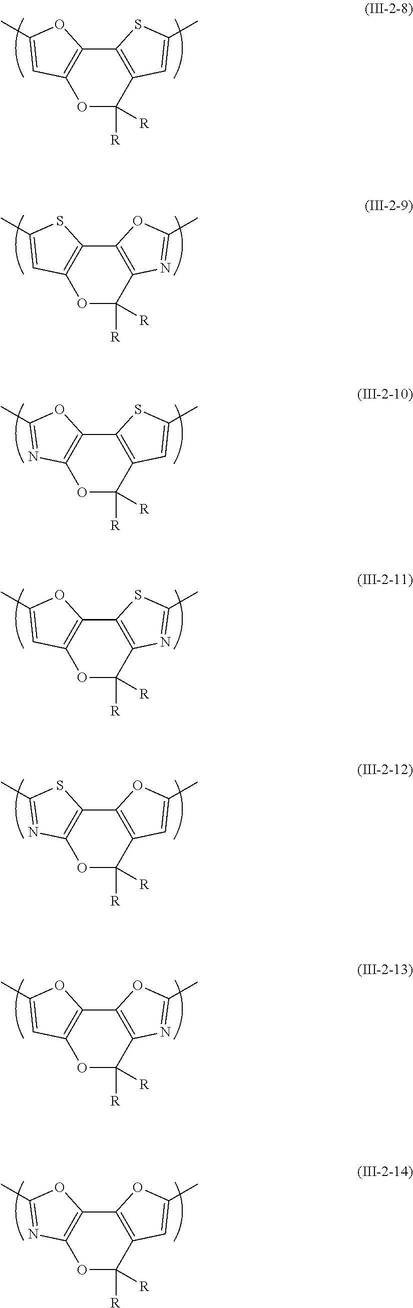

A p-type semiconductor material according to another embodiment preferably contains a polymer containing a constituent unit represented by the following Formula (IV) Hereinafter, the polymer containing a constituent unit represented by Formula (IV) is also referred to as a polymer (4). The p-type semiconductor material may contain only one type of the polymer (4), or two or more types thereof. The polymer (4) may contain only one type of the constituent unit represented by Formula (IV), or two or more types thereof.

—Ar³— (IV)

In Formula (IV), Ar³ represents a divalent aromatic heterocyclic group.

The number of carbon atoms of the divalent aromatic heterocyclic group represented by Ar³ is usually 2 to 60, preferably 4 to 60, and more preferably 4 to 20. The divalent aromatic heterocyclic group represented by Ar³ may have a substituent.

The constituent unit represented by Formula (IV) is preferably a constituent unit represented by any one of the following Formulae (IV-1) to (IV-8).

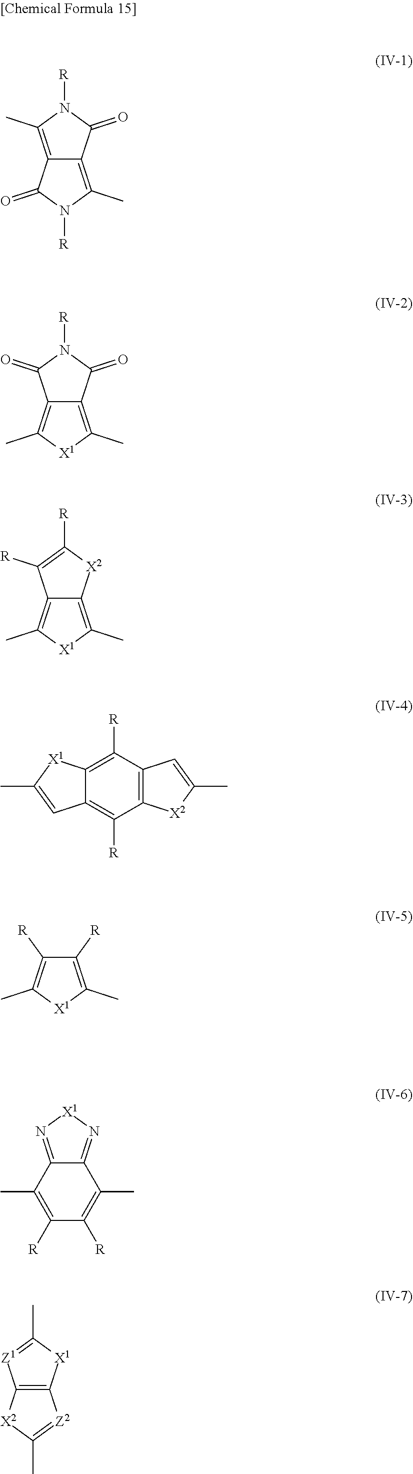

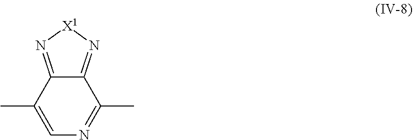

In Formulae (IV-1) to (IV-8), X¹, X², Z¹, Z² and R are the same as defined in Formulae (III-1) and (III-2). When there are two Rs, the two Rs may be the same or different.

In Formula (IV-6), two Rs are preferably each independently a hydrogen atom, an alkyl group, or a halogen atom, more preferably a hydrogen atom or a halogen atom at the same time, and still more preferably a halogen atom at the same time.

X¹ and X² in Formulae (IV-1) to (IV-8) are both preferably a sulfur atom from the viewpoint of availability of raw material compounds.

Specific examples of the divalent aromatic heterocyclic group represented by Ar³ include groups represented by the following Formulae (101) to (190) and groups in which these groups are substituted with a substituent. The substituent is preferably a halogen atom and an alkyl group. Among them, a group represented by Formula (148) or Formula (190) is preferable.

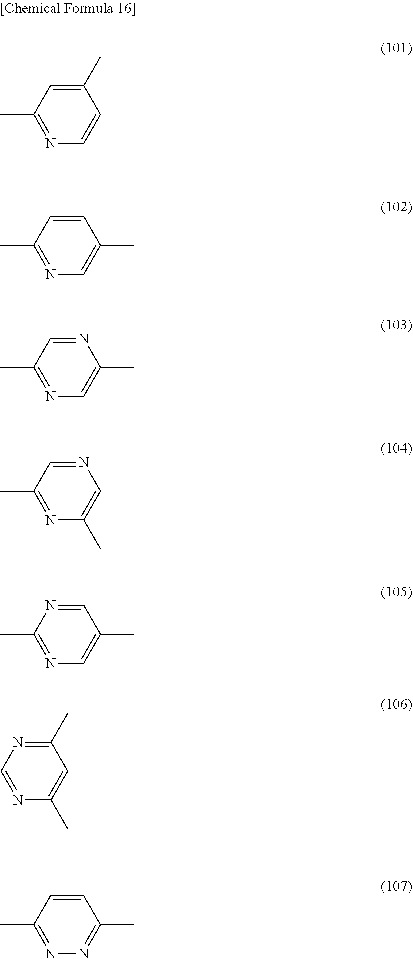

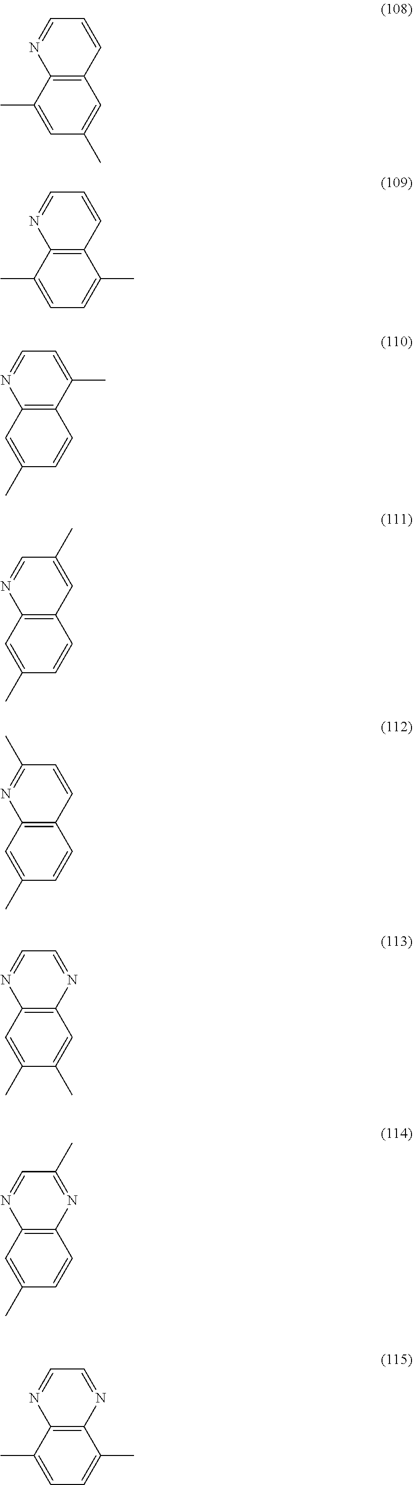

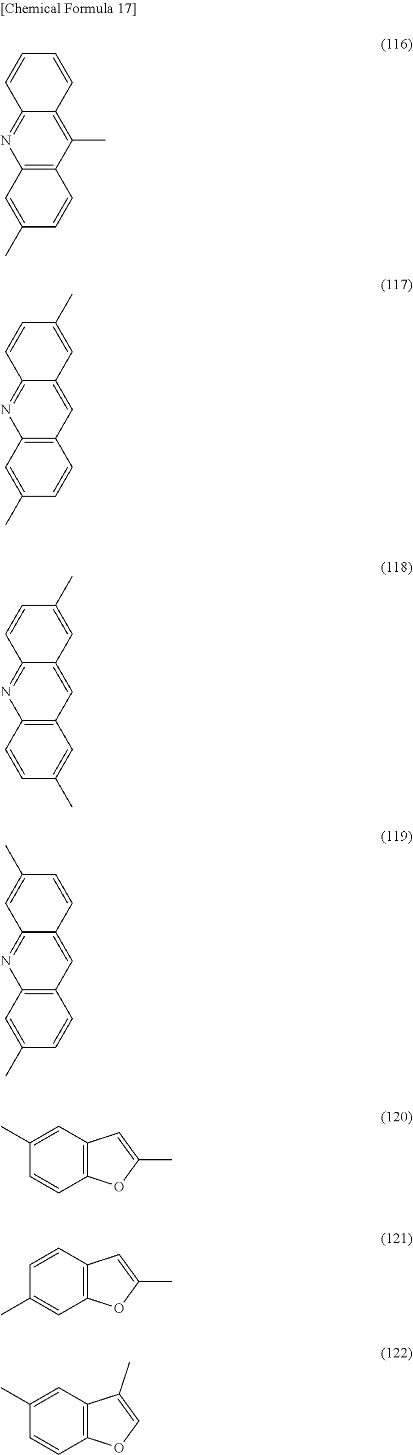

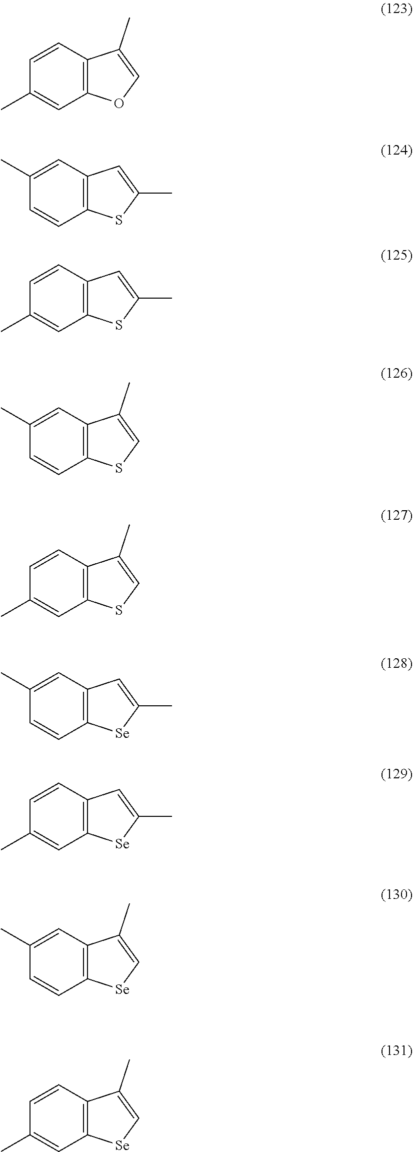

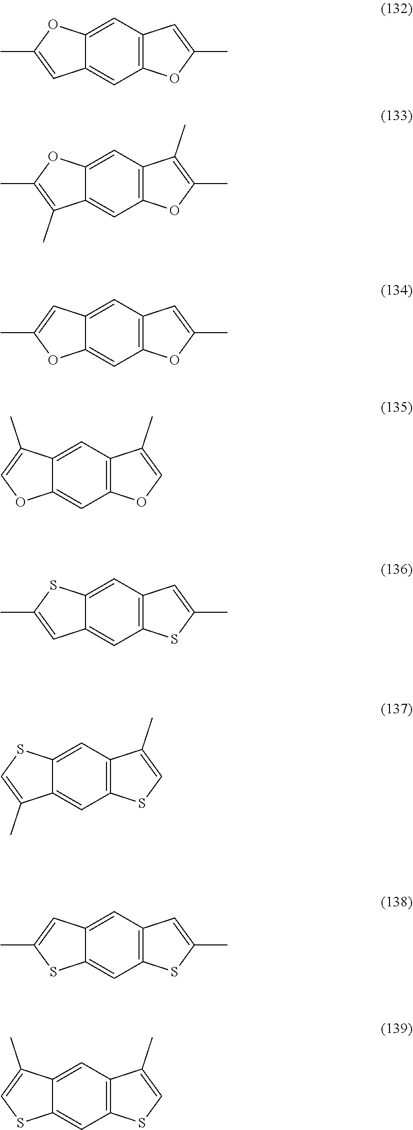

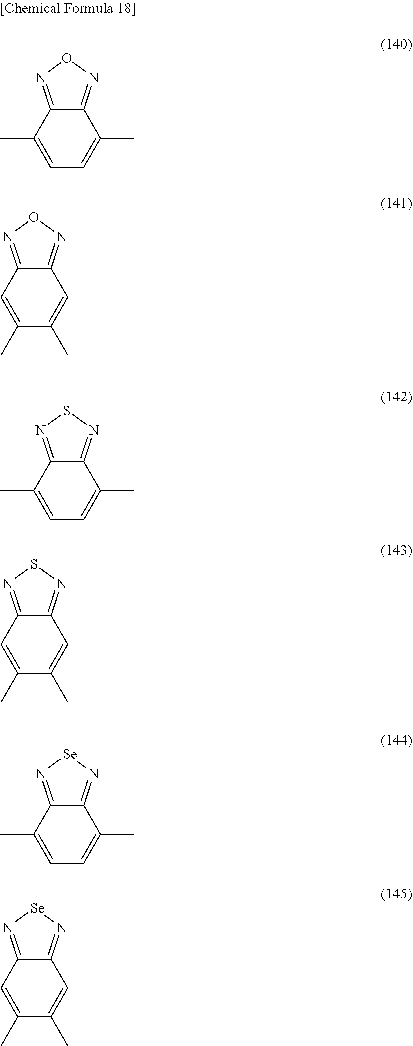

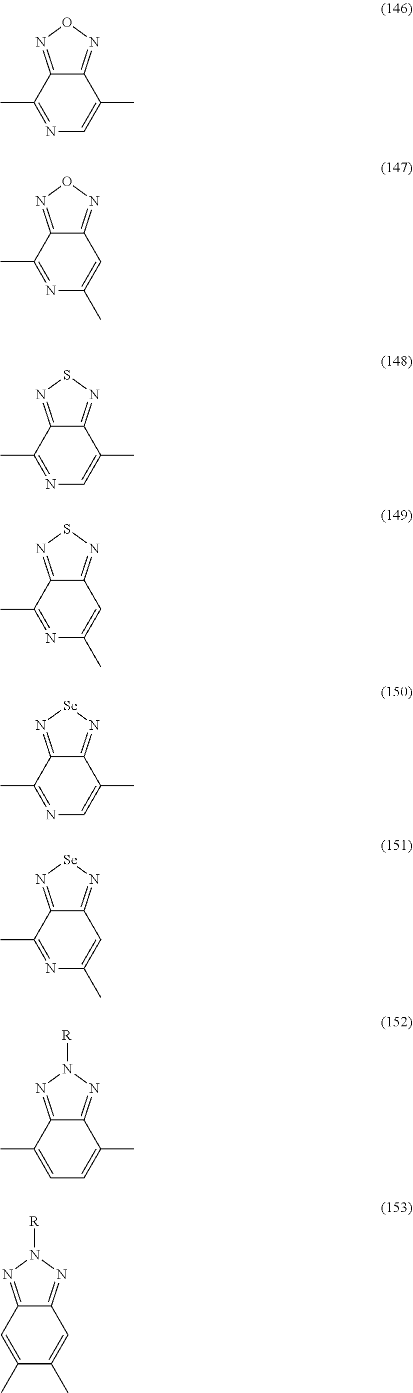

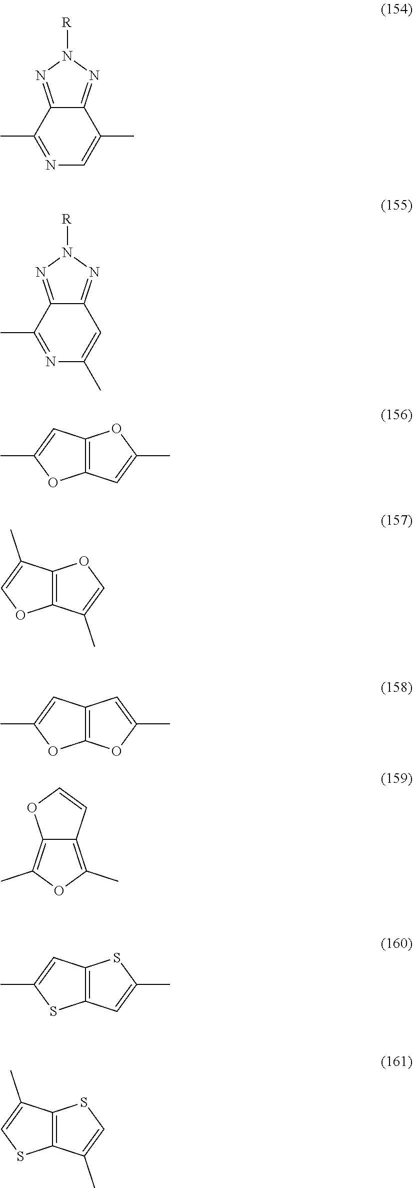

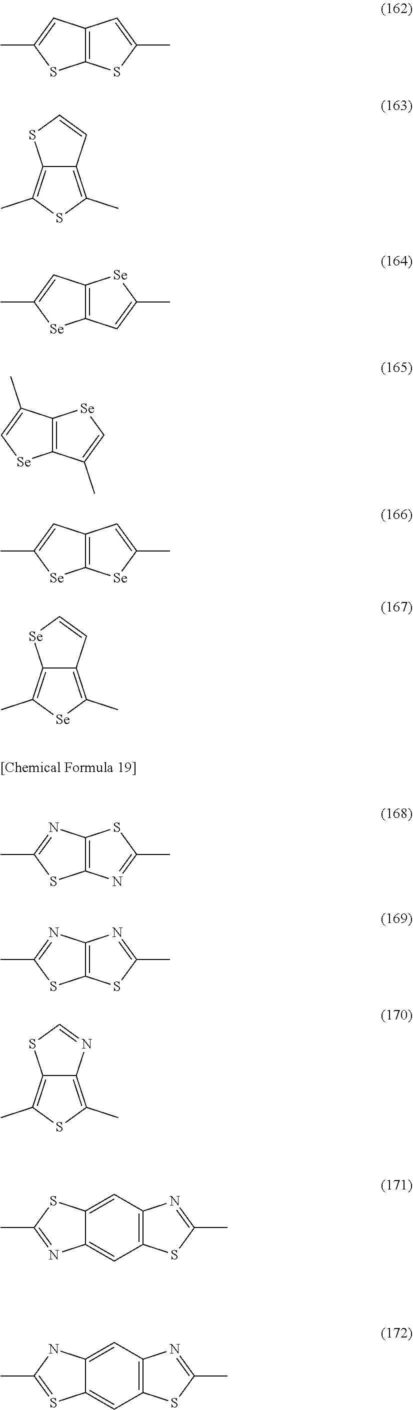

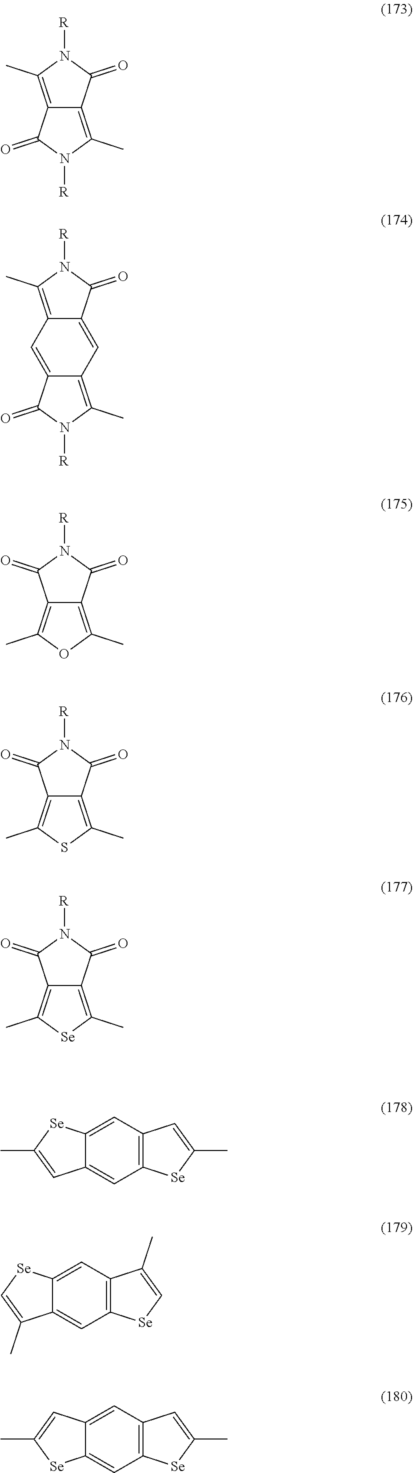

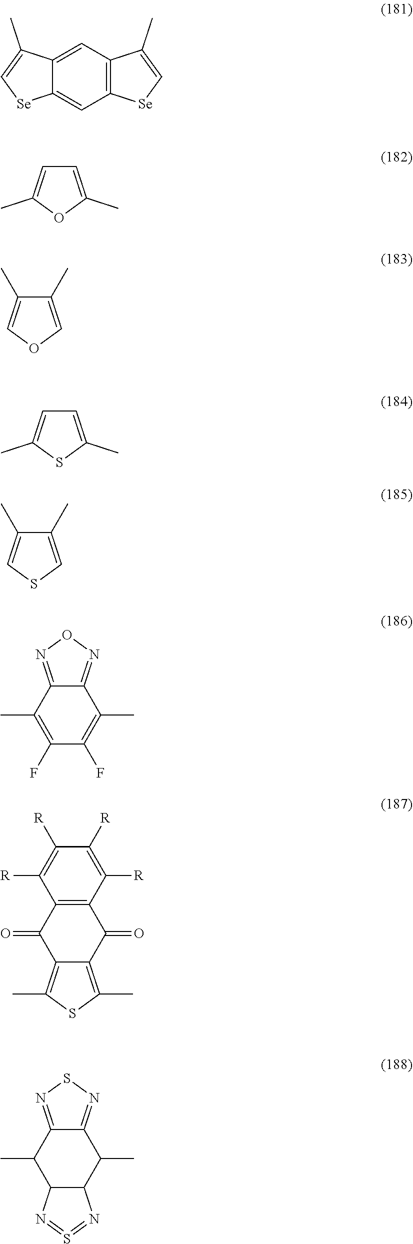

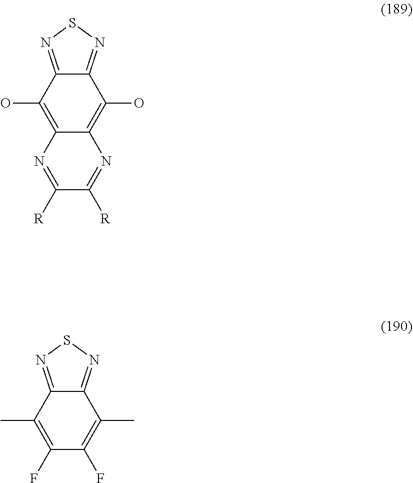

In Formulae (101) to (190), R has the same meaning as described above. When there are a plurality of Rs, the plurality of Rs may be the same or different from each other.

Preferably, the polymer (3/4) contains any one of the following combinations of constituent units.
A combination of the constituent unit represented by Formula (III-2) and the constituent unit represented by Formula (IV-6)
A combination of the constituent unit represented by Formula (III-2) and the constituent unit represented by Formula (IV-8)

More preferably, the polymer (3/4) contains any one of the following combinations of constituent units.
A combination of the constituent unit represented by Formula (III-2-1) and the constituent unit represented by Formula (148)
A combination of the constituent unit represented by Formula (III-2-1) and the constituent unit represented by Formula (190)

Specific examples of the polymer compound which is a p-type semiconductor material in the present embodiment include polymer compounds represented by the following Formulae (P-1) to (P-3).

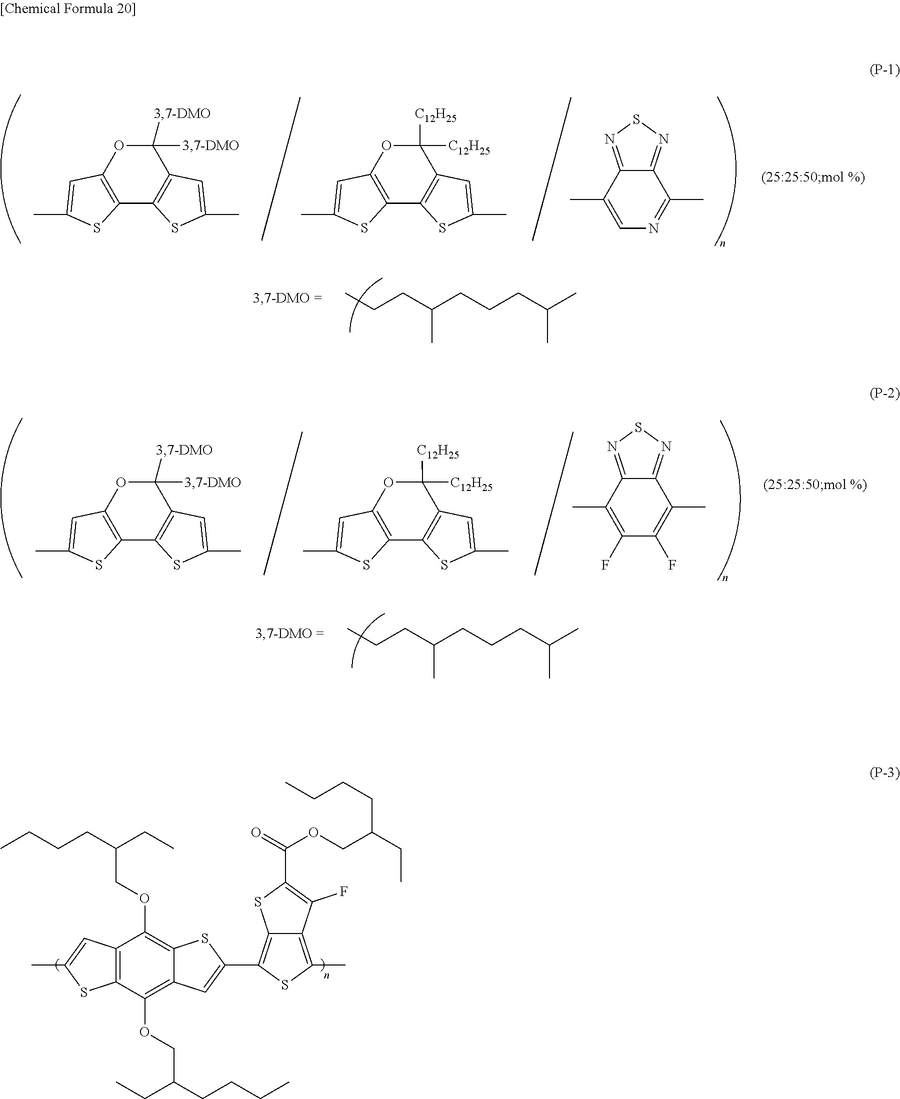

(n-Type Semiconductor Material)

The n-type semiconductor material according to the present embodiment contains a compound that is not a fullerene compound. The fullerene compound refers to fullerene and a fullerene derivative. A compound that is not a fullerene compound is hereinafter also referred to as a non-fullerene compound. Various compounds are known as the n-type semiconductor material which is a non-fullerene compound. These compounds can be used as the n-type semiconductor material according to the present embodiment.

The composition according to the present embodiment may contain only one type of compound or a plurality types of compounds as the n-type semiconductor material.

The n-type semiconductor material according to the present embodiment may be a low molecular weight compound or a high molecular weight compound (polymer compound). Examples of the n-type semiconductor material (electron-accepting compound) include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, and phenanthrene derivatives such as bathocuproine.

In one embodiment, the non-fullerene compound contained in the n-type semiconductor material is preferably a compound having a perylene tetracarboxylic acid diimide structure. Examples of the compound having a perylene tetracarboxylic acid diimide structure as a non-fullerene compound include compounds represented by the following formulae.

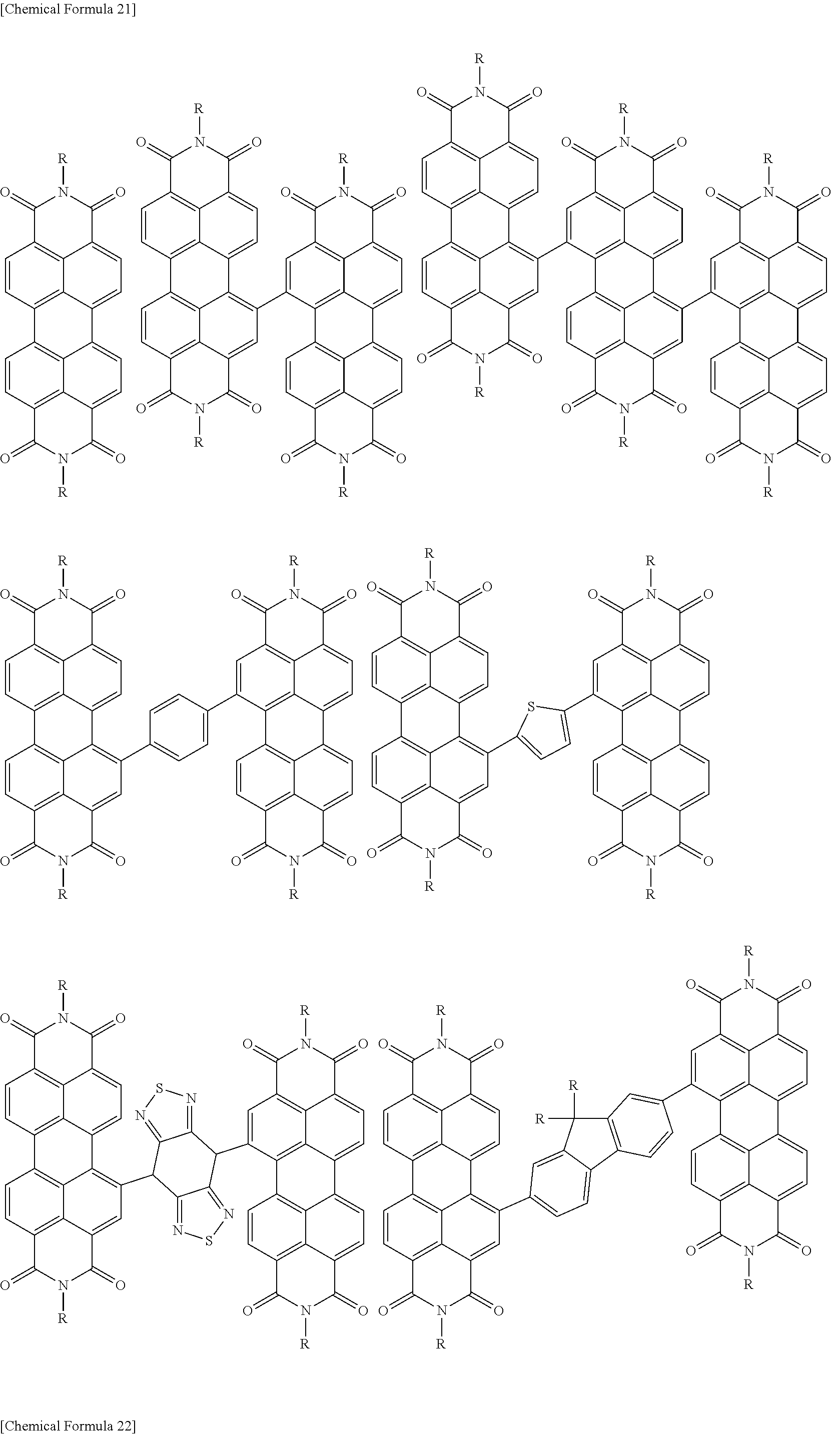

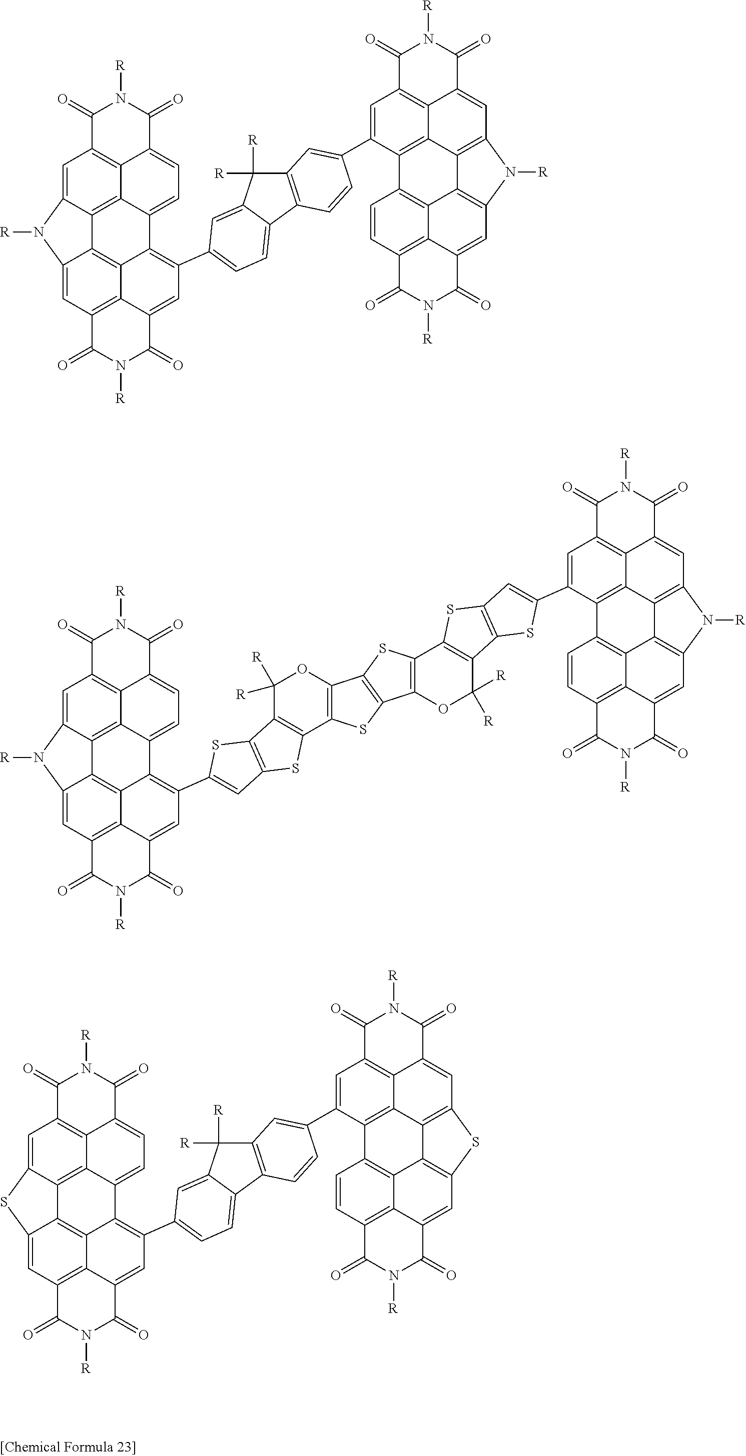

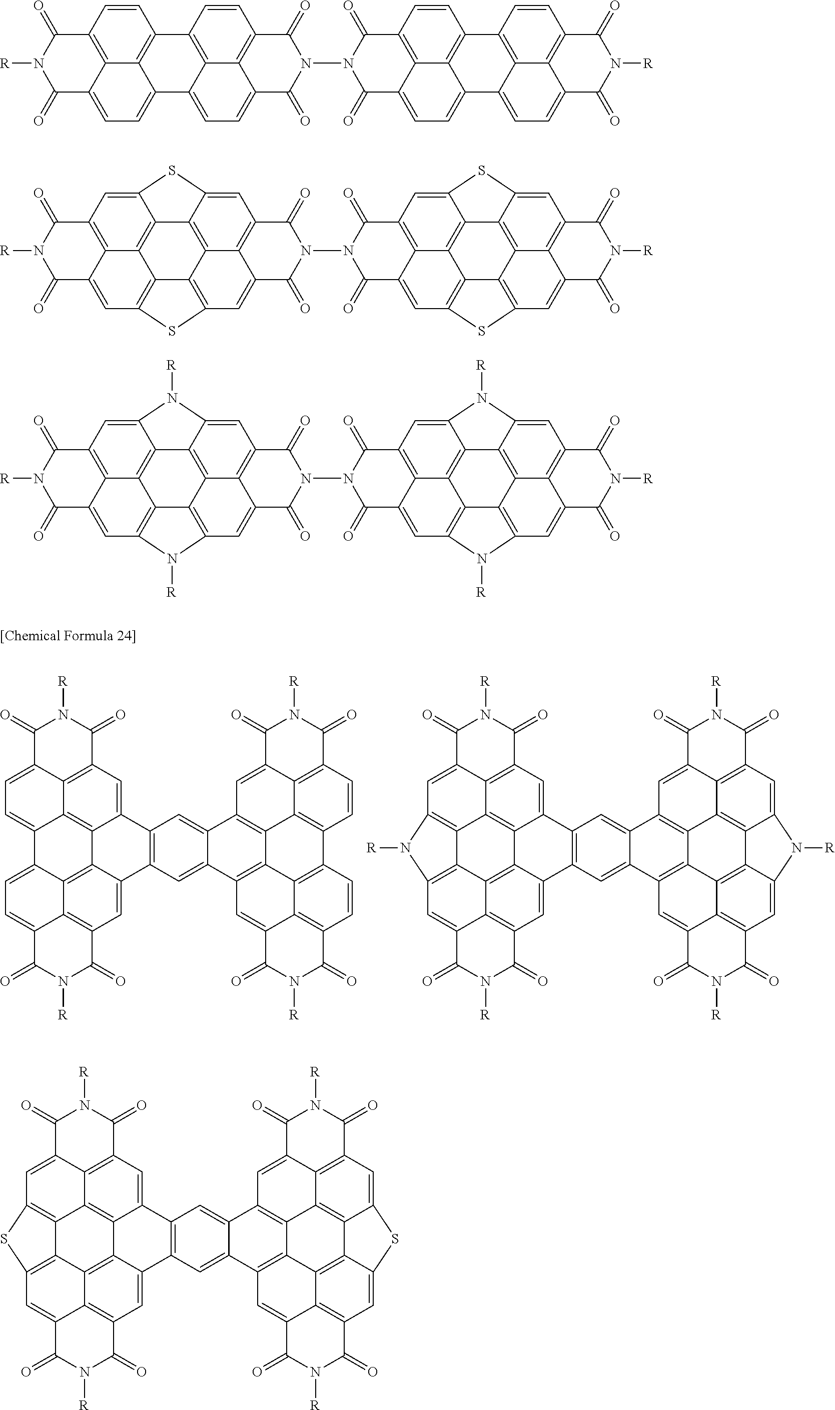

In the formulae, R is as defined above. A plurality of Rs may be the same or different from each other.

In one embodiment, the n-type semiconductor material preferably contains a compound represented by the following Formula (V). The compound represented by the following Formula (V) is a non-fullerene compound having a perylene tetracarboxylic acid diimide structure.

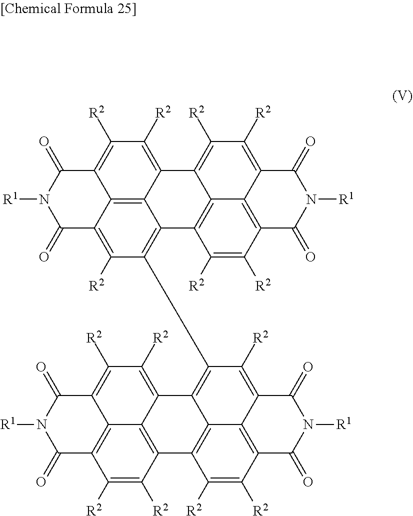

In Formula (V), R¹ represents a hydrogen atom, a halogen atom, an alkyl group optionally having a substituent, a cycloalkyl group optionally having a substituent, an alkyloxy group optionally having a substituent, a cycloalkyloxy group optionally having a substituent, an aryl group optionally having a substituent, or a monovalent aromatic heterocyclic group optionally having a substituent. A plurality of R's may be the same or different from each other.

Preferably, a plurality of R's are each independently an alkyl group optionally having a substituent.

R² represents a hydrogen atom, a halogen atom, an alkyl group optionally having a substituent, a cycloalkyl group optionally having a substituent, an alkyloxy group optionally having a substituent, a cycloalkyloxy group optionally having a substituent, an aryl group optionally having a substituent, or a monovalent aromatic heterocyclic group optionally having a substituent. A plurality of R²s may be the same or different.

Preferred examples of the compound represented by Formula (V) include a compound represented by the following Formula N-1.

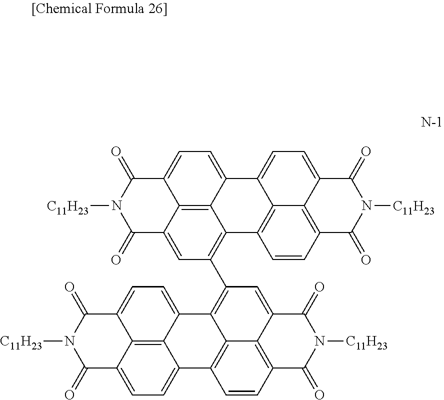

In one embodiment, the n-type semiconductor material preferably contains a compound represented by the following Formula (VI).

A¹-B¹⁰-A² (VI)

In Formula (VI),
A¹ and A² each independently represent an electron-withdrawing group, and B¹⁰ represents a group including a n conjugated system.

Examples of the electron-withdrawing group which is A¹ and A² include a group represented by —CH═C(—CN)₂ and groups represented by the following Formulae (a-1) to (a-9).

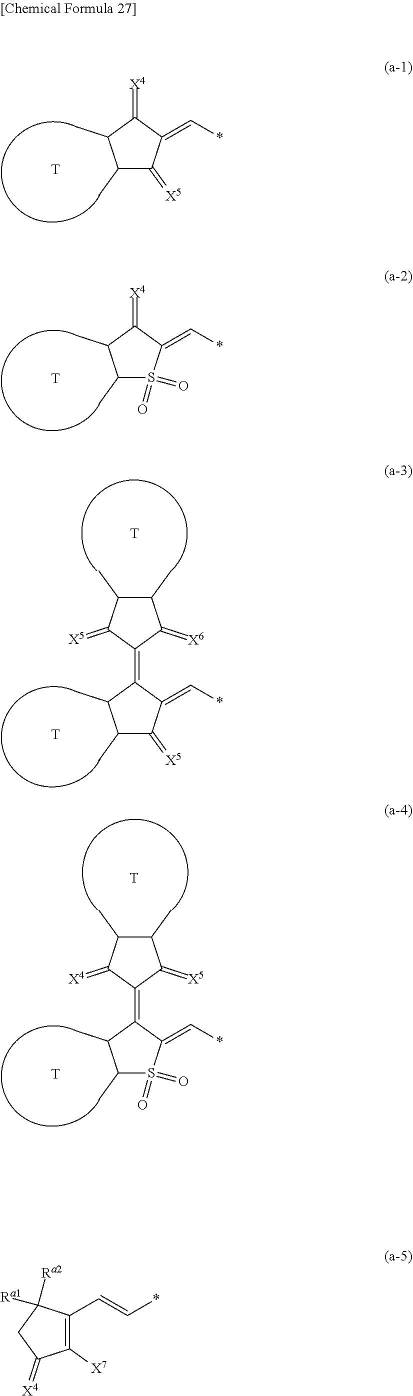

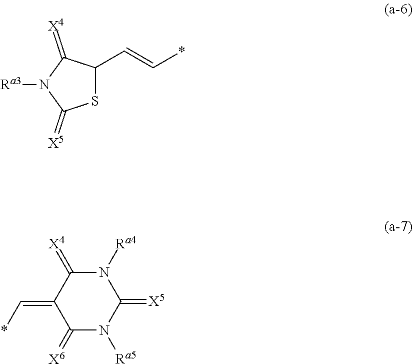

In Formulae (a-1) to (a-7),
T represents a carbocyclic ring optionally having a substituent or a heterocyclic ring optionally having a substituent. The carbocyclic ring and the heterocyclic ring may be a monocyclic ring or a condensed ring. When these rings have a plurality of substituents, the plurality of substituents may be the same or different.

Examples of the carbocyclic ring optionally having a substituent, which is T, include aromatic carbocyclic rings, and aromatic carbocyclic rings are preferable. Specific examples of the carbocyclic ring optionally having a substituent, which is T, include a benzene ring, a naphthalene ring, an anthracene ring, a tetracene ring, a pentacene ring, a pyrene ring, and a phenanthrene ring. A benzene ring, a naphthalene ring, and a phenanthrene ring are preferable, a benzene ring and a naphthalene ring are more preferable, and a benzene ring is still more preferable. These rings may have a substituent.

Examples of the heterocyclic ring optionally having a substituent, which is T, include aromatic heterocyclic rings, and aromatic heterocyclic rings are preferable. Specific examples of the heterocyclic ring optionally having a substituent, which is T, include a pyridine ring, a pyridazine ring, a pyrimidine ring, a pyrazine ring, a pyrrole ring, a furan ring, a thiophene ring, an imidazole ring, an oxazole ring, a thiazole ring, and a thienothiophene ring. A thiophene ring, a pyridine ring, a pyrazine ring, a thiazole ring, and a thienothiophene ring are preferable, and a thiophene ring is more preferable. These rings may have a substituent.

Examples of the substituent that can be included in the carbocyclic ring or heterocyclic ring as T include a halogen atom, an alkyl group, an alkyloxy group, an aryl group, and a monovalent heterocyclic group. The substituent is preferably a fluorine atom and/or an alkyl group having 1 to 6 carbon atoms.

X⁴, X⁵, and X⁶ each independently represent an oxygen atom, a sulfur atom, an alkylidene group, or a group represented by ═C(—CN)₂, and is preferably an oxygen atom, a sulfur atom, or a group represented by ═C(—CN)₂.

X⁷ represents a hydrogen atom, a halogen atom, a cyano group, an alkyl group optionally having a substituent, an alkyloxy group optionally having a substituent, an aryl group optionally having a substituent, or a monovalent heterocyclic group.

R^{a1}, R^{a2}, R^{a3}, R^{a4}, and R^{a5} each independently represent a hydrogen atom, an alkyl group optionally having a substituent, a halogen atom, an alkyloxy group optionally having a substituent, an aryl group optionally having a substituent, or a monovalent heterocyclic group. R^{a1}, R^{a2}, R^{a3}, R^{a4}, and R^{a5} are preferably an alkyl group optionally having a substituent or an aryl group optionally having a substituent.

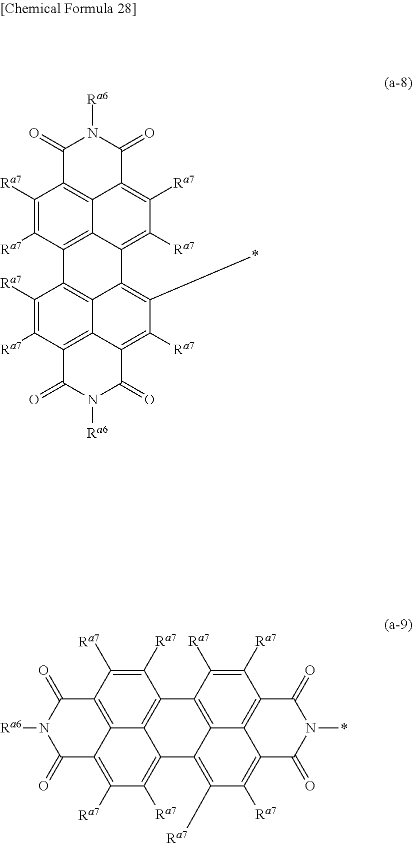

In Formulae (a-8) and (a-9), R^{a6} and R^{a7} each independently represent a hydrogen atom, a halogen atom, an alkyl group optionally having a substituent, a cycloalkyl group optionally having a substituent, an alkyloxy group optionally having a substituent, a cycloalkyloxy group optionally having a substituent, a monovalent aromatic carbocyclic group optionally having a substituent, or a monovalent aromatic heterocyclic group optionally having a substituent, and a plurality of R^{a1}s and R^{a7}s may be the same or different.

As the electron-withdrawing group which is A¹ or A², a group represented by any one of the following Formulae (a-1-1) to (a-1-4), and Formulae (a-6-1) and (a-7-1) is preferable, and a group represented by Formula (a-1-1) is more preferable. Here, a plurality of R^{a10}s each independently represent a hydrogen atom or a substituent, and preferably represent a hydrogen atom, a halogen atom, a cyano group, or an alkyl group optionally having a substituent. R^{a3}, R^{a4}, and R^{a5} each independently have the same meaning as described above, and preferably each independent represent an alkyl group optionally having a substituent or an aryl group optionally having a substituent.

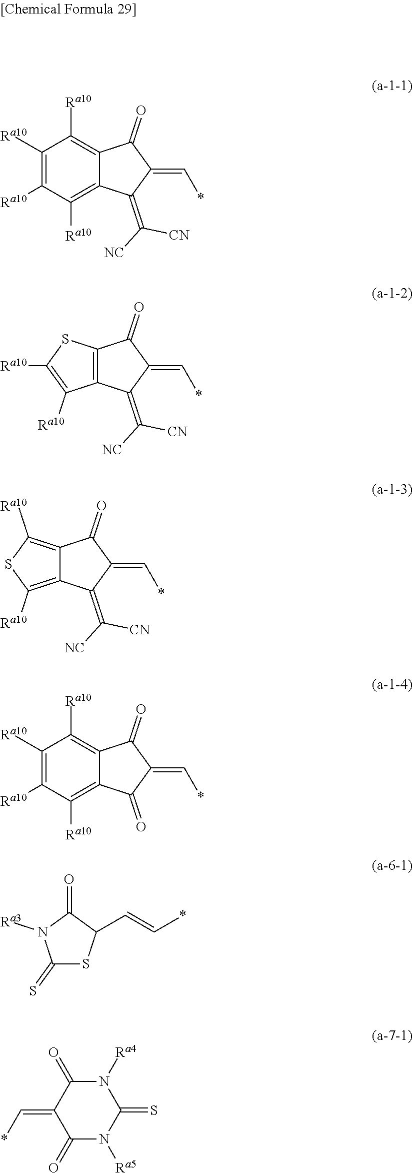

Examples of the group including a n conjugated system, which is B¹⁰, include a group represented by —(S¹)ₙ₁—B¹¹—(S²)ₙ₂— in the compound represented by Formula (VII) described later.

In one embodiment, the n-type semiconductor material is preferably a compound represented by the following Formula (VII).

A¹-(S¹)ₙ₁—B¹¹—(S²)ₙ₂-A² (VII)

In Formula (VII), A¹ and A² each independently represent an electron-withdrawing group. Examples and preferred examples of A¹ and A² are the same as the examples and preferred examples described for A¹ and A² in the above Formula (VI).

S¹ and S² each independently represent a divalent carbocyclic group optionally having a substituent, a divalent heterocyclic group optionally having a substituent, a group represented by —C(R^{s1})═C(R^{s2})— where R^{s1} and R^{s2} each independently represent a hydrogen atom or a substituent (preferably, a hydrogen atom, a halogen atom, an alkyl group optionally having a substituent, or a monovalent heterocyclic group optionally having a substituent), or a group represented by —C≡C—.

The divalent carbocyclic group optionally having a substituent and the divalent heterocyclic group optionally having a substituent, which are represented by S¹ and S², may be a condensed ring. When the divalent carbocyclic group or the divalent heterocyclic group has a plurality of substituents, the plurality of substituents may be the same or different.

In Formula (VII), n1 and n2 each independently represent an integer of 0 or more, preferably each independently represent 0 or 1, and more preferably represent 0 or 1 at the same time.

Examples of the divalent carbocyclic group include divalent aromatic carbocyclic groups.

Examples of the divalent heterocyclic group include divalent aromatic heterocyclic groups.

When the divalent aromatic carbocyclic group or the divalent aromatic heterocyclic group is a condensed ring, all of the rings constituting the condensed ring may be a condensed ring having aromaticity, or only a part thereof may be a condensed ring having aromaticity.

Examples of S¹ and S² include a group represented by any one of Formulae (101) to (190), which has been described as an example of the divalent aromatic heterocyclic group represented by Ar³, and a group in which a hydrogen atom in these groups is substituted with a substituent.

S¹ and S² preferably each independently represent a group represented by the following Formula (s-1) or (s-2).

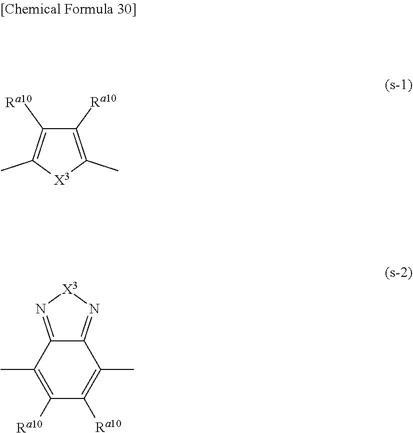

In Formulae (s-1) and (s-2),
X³ represents an oxygen atom or a sulfur atom.
R^{a10} is as defined above.

S¹ and S² are preferably each independently a group represented by Formula (142), (148), or (184), or a group in which a hydrogen atom in these groups is substituted with a substituent. S¹ and S² are more preferably a group represented by Formula (142) or (184), or a group in which one hydrogen atom in the group represented by Formula (184) is substituted with an alkyloxy group.

B¹¹ is a condensed ring group having two or more structures selected from the group consisting of carbocyclic structures and heterocyclic structures, is a condensed ring group including no ortho-peri condensed structure, and represents a condensed ring group optionally having a substituent.

The condensed ring group which is represented by B¹¹ may include a structure in which two or more structures identical to each other are condensed.

When the condensed ring group which is represented by B¹¹ has a plurality of substituents, the plurality of substituents may be the same or different.

Examples of the carbocyclic structure that can constitute the condensed ring group represented by B¹¹ include a ring structure represented by the following Formula (Cy1) or (Cy2).

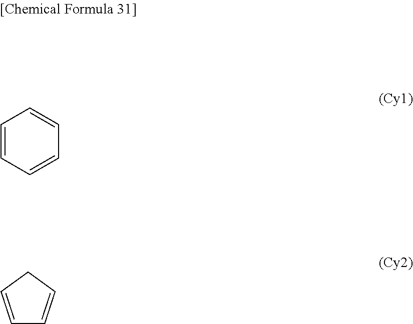 [SMILES: c1ccccc1 ; C1=CCC=C1]

Examples of the heterocyclic structure that can constitute the condensed ring group represented by B¹¹ include a ring structure represented by any one of the following Formulae (Cy3) to (Cy10).

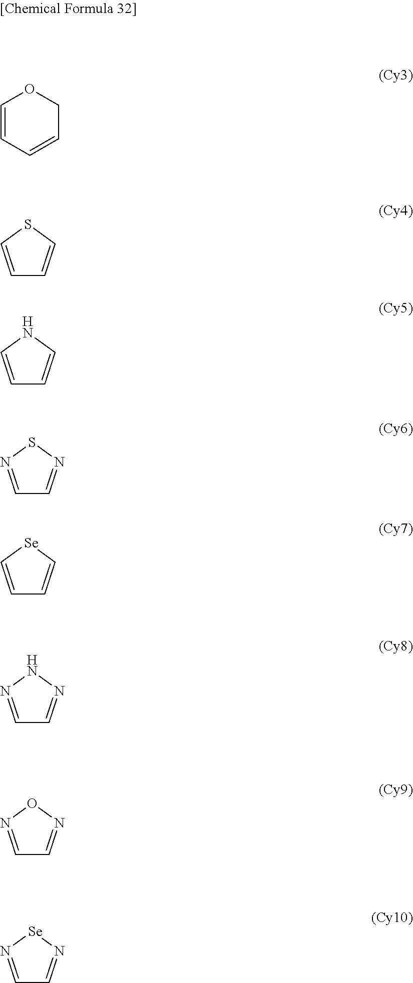

In Formula (VII), B¹¹ is preferably a condensed ring group of two or more structures selected from the group consisting of structures represented by the above Formulae (Cy1) to (Cy10), is a condensed ring group including no ortho-peri condensed structure, and is a condensed ring group optionally having a substituent. B¹¹ may include a structure in which two or more identical structures among the structures represented by Formulae (Cy1) to (Cy10) are condensed.

B¹¹ is more preferably a condensed ring group of two or more structures selected from the group consisting of structures represented by Formulae (Cy1) to (Cy6) and (Cy8), is a condensed ring group including no ortho-peri condensed structure, and is a condensed ring optionally having a substituent.

The substituent optionally included in the condensed ring group as B¹¹ is preferably an alkyl group optionally having a substituent, an aryl group optionally having a substituent, an alkyloxy group optionally having a substituent, and a monovalent heterocyclic group optionally having a substituent. The aryl group optionally included in the condensed ring group represented by B¹¹ may be substituted with, for example, an alkyl group.

Examples of the condensed ring group as B¹¹ include groups represented by the following Formulae (b-1) to (b-14) and a group in which a hydrogen atom in these groups is substituted with a substituent (preferably, an alkyl group optionally having a substituent, an aryl group optionally having a substituent, an alkyloxy group optionally having a substituent, or a monovalent heterocyclic group optionally having a substituent). The condensed ring group as B¹¹ is preferably a group represented by the following Formula (b-2) or (b-3), or a group in which a hydrogen atom in these groups is substituted with a substituent (preferably, an alkyl group optionally having a substituent, an aryl group optionally having a substituent, an alkyloxy group optionally having a substituent, or a monovalent heterocyclic group optionally having a substituent), and more preferably a group represented by the following Formula (b-2) or (b-3).

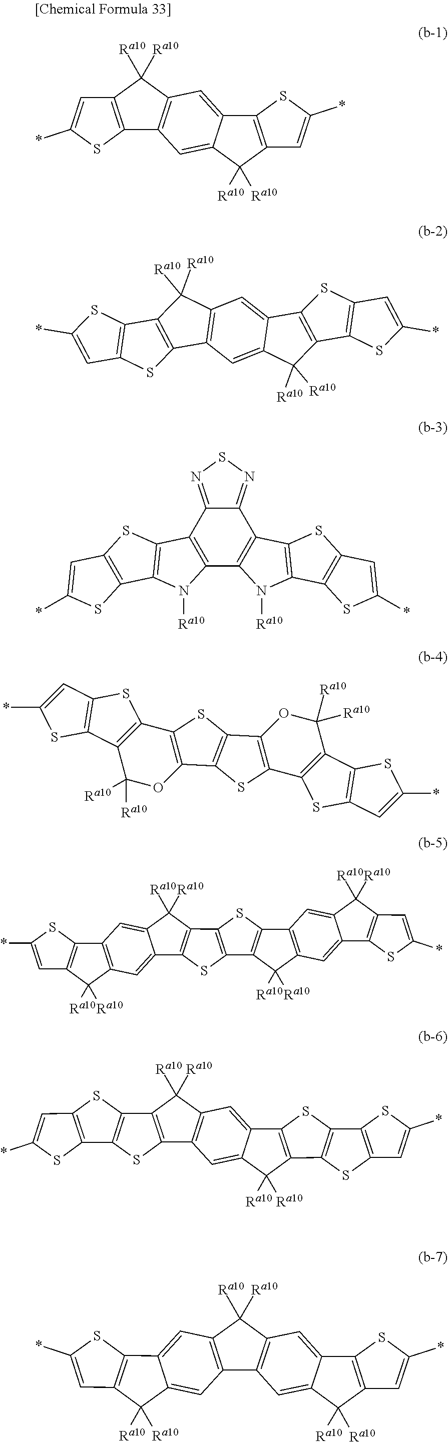

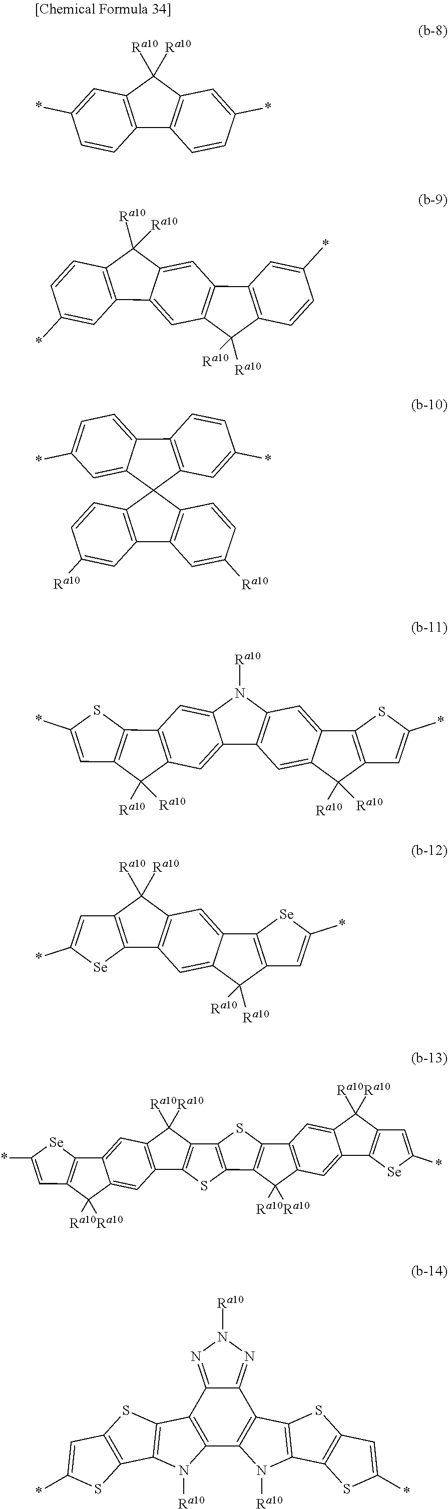

In Formulae (b-1) to (b-14),

R^{a10} is as defined above.

In Formulae (b-1) to (b-14), a plurality of R^{a10}s are each independently preferably an alkyl group optionally having a substituent or an aryl group optionally having a substituent.

Examples of the compound represented by Formula (VI) or (VII) include compounds represented by the following formulae.

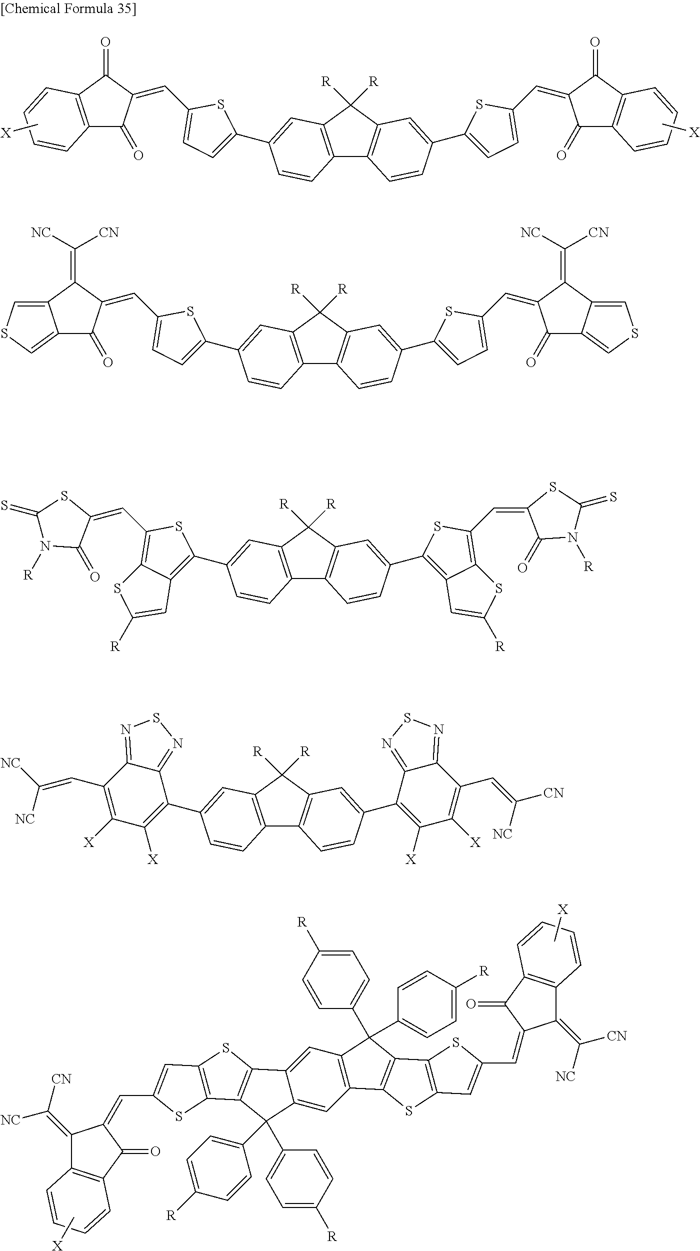

In the above formulae, R is as defined above, and X represents a hydrogen atom, a halogen atom, a cyano group, or an alkyl group optionally having a substituent.

In the above formulae, R is preferably a hydrogen atom, an alkyl group optionally having a substituent, an aryl group optionally having a substituent, or an alkyloxy group optionally having a substituent.

Examples of the compound represented by Formula (VI) or (VII) include compounds represented by the following Formulae N-2 to N-3.

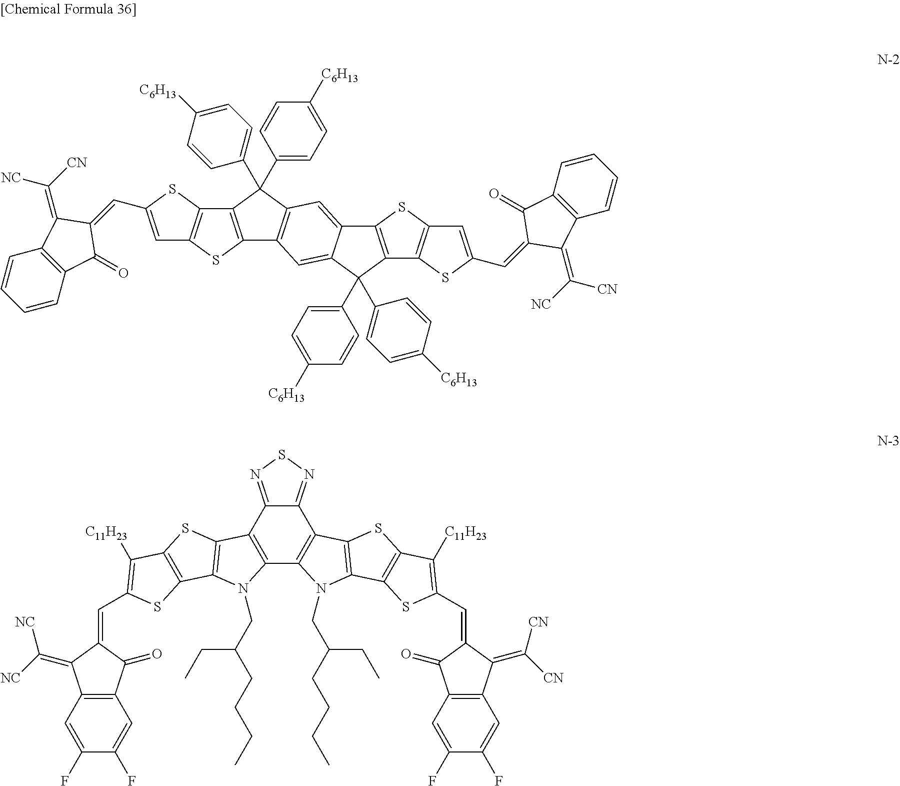

The n-type semiconductor material according to the present embodiment may further optionally contain a fullerene compound in addition to the above non-fullerene compound. Examples of the fullerene include C₆₀ fullerene, C₇₀ fullerene, C₇₆ fullerene, C₇₈ fullerene, and C₈₄ fullerene. Examples of the fullerene derivative include [6,6]-phenyl-C61 butyric acid methyl ester (C60PCBM, [6,6]-Phenyl C61 butyric acid methyl ester), [6,6]-phenyl-C71 butyric acid methyl ester (C70PCBM, [6,6]-Phenyl C71 butyric acid methyl ester), [6,6-phenyl-C85 butyric acid methyl ester (C84PCBM, [6,6]-Phenyl C85 butyric acid methyl ester), and [6,6]-thienyl-C61 butyric acid methyl ester ([6,6]-Thienyl C61 butyric acid methyl ester).

When the composition according to the present embodiment contains a fullerene compound as an n-type semiconductor material, the content of the fullerene compound in the composition is usually 0 parts by weight or more, preferably 50 parts by weight or less, more preferably 10 parts by weight or less, and may be 0 parts by weight based on 100 parts by weight of the non-fullerene compound of the n-type semiconductor material.

(Concentration of p-Type Semiconductor Material and n-Type Semiconductor Material in Composition)

The concentration of the total of the p-type semiconductor material and the n-type semiconductor material in the composition can be any preferred concentration depending on the required thickness of the active layer. The total concentration of the p-type semiconductor material and the n-type semiconductor material is preferably 0.01 wt % or more, more preferably 0.1 wt % or more, preferably 10 wt % or less, more preferably 5 wt % or less, still more preferably 0.01 wt % or more and 20 wt % or less, still more preferably 0.01 wt % or more and 10 wt % or less, still more preferably 0.01 wt % or more and 5 wt % or less, and particularly preferably 0.1 wt % or more and 5 wt % or less.

(Weight Ratio (p/n Ratio) of p-Type Semiconductor Material to n-Type Semiconductor Material)

The weight ratio of the p-type semiconductor material to the n-type semiconductor material (p-type semiconductor material/n-type semiconductor material) in the composition is preferably 1/9 or more, more preferably 1/5 or more, still more preferably 1/3 or more, and preferably 9/1 or less, more preferably 5/1 or less, still more preferably 3/1 or less.

[1.2. Insulating Material]

The composition of the present embodiment contains an insulating material. Here, the insulating material refers to a material that is neither a conductor nor a semiconductor. The insulating material usually has an electrical resistivity of 1×10⁷ Ω·m or more at 20° C. The insulating material usually does not participate in the photoelectric conversion process.

The insulating material is preferably an organic compound, and more preferably an organic polymer. The insulating material may contain only one type of organic compound, or may contain a combination of two or more types thereof.

As the insulating material, various known organic compounds can be used for the composition of the present embodiment.

Examples of the organic polymer as an insulating material include polyolefin (for example, polyethylene, polypropylene, poly(1-butene), and polyisobutylene), poly(aromatic vinyl) (for example, polystyrene and a derivative thereof), methyl poly(meth)acrylate, polyester, vinyl polycarboxylate, polyvinyl acetal, polycarbonate, polyurethane, polyarylate, polyamide, polyimide, cellulose and a derivative thereof, polysiloxane, rubber, and thermoplastic elastomer. The organic polymer that can be contained in the insulating material may be a homopolymer or a copolymer.

The insulating material preferably contains a polymer containing a constituent unit represented by the following Formula (I). Hereinafter, the polymer containing the constituent unit represented by Formula (I) is also referred to as a polymer (1). The polymer (1) may contain only one type of the constituent unit represented by Formula (I), or may contain a combination of two or more types thereof.

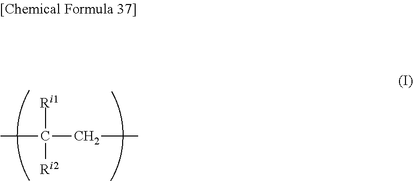

In Formula (I), Rⁱ¹ represents a hydrogen atom, a halogen atom, or an alkyl group having 1 to 20 carbon atoms, and Rⁱ² represents a hydrogen atom, a halogen atom, an alkyl group having 1 to 20 carbon atoms, a group represented by the following Formula (II-1), a group represented by the following Formula (II-2), or a group represented by the following Formula (II-3).

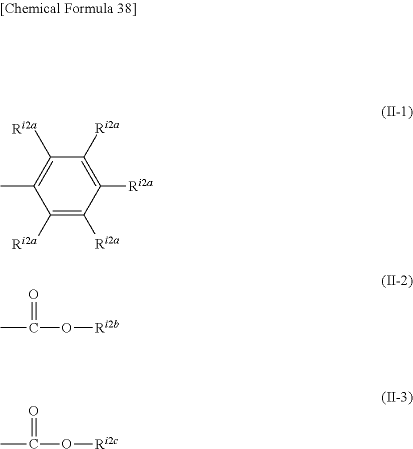

In Formula (II-1), R^{i2a} represents a hydrogen atom, a halogen atom, or an alkyl group having 1 to 20 carbon atoms.

In Formula (II-2), R^{i2b} represents a hydrogen atom or an alkyl group having 1 to 20 carbon atoms.

In Formula (II-3), R^{i2c} represents an alkyl group having 1 to 20 carbon atoms.

Rⁱ¹ is preferably a hydrogen atom or an alkyl group having 1 to 10 carbon atoms, more preferably a hydrogen atom or an alkyl group having 1 to 5 carbon atoms, and still more preferably a hydrogen atom.

R^{i2a} is preferably a hydrogen atom, a halogen atom, or an alkyl group having 1 to 10 carbon atoms, more preferably a hydrogen atom, a halogen atom, or an alkyl group having 1 to 5 carbon atoms, and still more preferably a hydrogen atom.

R^{i2b} is preferably an alkyl group having 1 to 10 carbon atoms, more preferably an alkyl group having 1 to 5 carbon atoms, and still more preferably a methyl group.

R^{i2c} is preferably an alkyl group having 1 to 10 carbon atoms, more preferably an alkyl group having 1 to 5 carbon atoms, and still more preferably a methyl group.

Rⁱ² is preferably a hydrogen atom, an alkyl group having 1 to 20 carbon atoms, or a group represented by Formulae (II-1) to (II-3), more preferably a hydrogen atom, an alkyl group having 1 to 10 carbon atoms, or a group represented by Formulae (II-1) to (II-3), and still more preferably an alkyl group having 1 to 5 carbon atoms or a group represented by Formulae (II-1) to (II-3).

In one embodiment, the polymer (1) preferably contains one or more types of constituent units selected from the group consisting of a constituent unit in which Rⁱ² in Formula (I) is an alkyl group having 1 to 20 carbon atoms and a constituent unit in which Rⁱ² in Formula (I) is a group represented by Formula (II-1), and is more preferably polystyrene, or a polymer containing a styrene unit and a constituent unit in which Rⁱ² in Formula (I) is a group represented by Formula (II-1).

In another embodiment, the polymer (1) preferably contains a constituent unit in which Rⁱ² in Formula (I) is a group represented by Formula (II-2), and more preferably contains a methyl methacrylate unit.

The content of the polymer (1) in the insulating material is preferably 70 wt % or more, more preferably 80 wt % or more, still more preferably 90 wt % or more, and particularly preferably 95 wt % or more, and is usually 100 wt % or less, and may be 100 wt %. The insulating material may contain only one type of the polymer (1), or may contain a combination of two or more types thereof.

The polymer (1) may contain an optional constituent unit in addition to the constituent unit represented by Formula (I). Examples of the optional constituent unit include alkadiene units (for example, a 1,3-butadiene unit, and an isoprene unit).

The polymer (1) can be produced by a previously known production method. A commercially available product can also be used as the polymer (1).

Preferably, the insulating material is a material that dissolves in an amount of 0.1 wt % or more in the solvent of the composition at 25° C.

More preferably, the insulating material is the polymer (1), and is a polymer that dissolves in an amount of 0.1 wt % or more in the solvent of the composition at 25° C.

The weight average molecular weight (Mw) of the organic polymer that can be contained in the insulating material is not particularly limited, but is preferably 1,000,000 or less, more preferably 500,000 or less, and still more preferably 200,000 or less from the viewpoint of solubility in the solvent.

Specific examples of the insulating material according to the present embodiment include polystyrene-block-poly(ethylene-ran-butylene)-block-polystyrene (weight average molecular weight: 118,000 or less), polystyrene (weight average molecular weight: 35,000), polystyrene-block-polyisoprene-block-polystyrene (number average molecular weight: 1,900), and poly(methyl methacrylate) (weight average molecular weight: 15,000 or less).

The content of the insulating material in the composition is, for example, 0.5 wt % or more or 0.1 wt % or more, and is, for example, 5 wt % or less or 1 wt % or less. Here, the total weight of the p-type semiconductor material, the n-type semiconductor material, the insulating material, and the solvent in the composition is 100 wt %.

The weight ratio of the insulating material to the p-type semiconductor material (insulating material/p-type semiconductor material) in the composition is, for example, 1/10 or more or 1/5 or more, and is, for example, 1/3 or less or 1/2 or less.

[1.3. Solvent]

The composition according to the present embodiment contains a solvent. The composition may contain only one type of solvent, or may contain a combination of two or more types thereof.

The composition according to the present embodiment preferably contains a first solvent described below, and may optionally further contain a second solvent.

(First Solvent)

The solvent may be selected considering the solubility for the selected p-type semiconductor material and the n-type semiconductor material, and the characteristics corresponding to the drying conditions in the formation of the film (such as the boiling point).

The first solvent is preferably an aromatic hydrocarbon optionally having a substituent such as an alkyl group or a halogen atom (hereinafter, simply referred to as an aromatic hydrocarbon) or a halogenated alkyl solvent. The first solvent is preferably selected considering the solubility for the selected p-type semiconductor material and the n-type semiconductor material.

Examples of the aromatic hydrocarbon as a first solvent include toluene, xylenes (for example, o-xylene, m-xylene, and p-xylene), trimethylbenzenes (for example, mesitylene, and 1,2,4-trimethylbenzene (pseudocumene)), butylbenzenes (for example, n-butylbenzene, sec-butylbenzene, and tert-butylbenzene), methylnaphthalenes (for example, 1-methylnaphthalene), tetralin, indan, chlorobenzene, and dichlorobenzene (1,2-dichlorobenzene).

Examples of the halogenated alkyl solvent as a first solvent include chloroform.

The first solvent may be composed of only one type of aromatic hydrocarbon, or composed of two or more types of aromatic hydrocarbons. The first solvent is preferably composed of only one type of aromatic hydrocarbon.

The first solvent preferably contains one or more types selected from the group consisting of toluene, o-xylene, m-xylene, p-xylene, mesitylene, pseudocumene, n-butylbenzene, sec-butylbenzene, tert-butylbenzene, methylnaphthalene, tetralin, indan, chlorobenzene, o-dichlorobenzene, and chloroform.

(Second Solvent)

The second solvent is particularly preferably a solvent selected from the viewpoint of enhancing the solubility for the n-type semiconductor material. Examples of the second solvent include ketone solvents (for example, acetone, methyl ethyl ketone, cyclohexanone, acetophenone, and propiophenone), and ester solvents (for example, ethyl acetate, butyl acetate, phenyl acetate, ethyl cellosolve acetate, methyl benzoate, butyl benzoate, and benzyl benzoate).

(Weight Ratio of First Solvent to Second Solvent)

When the composition contains the first solvent and the second solvent, the weight ratio of the first solvent to the second solvent (first solvent/second solvent) is preferably in a range of 85/15 to 99/1 from the viewpoint of further improving the solubility for the p-type semiconductor material and the n-type semiconductor material.

(Weight Percentage of Solvent in Composition)

The total weight of the solvent contained in the composition is preferably 90 wt % or more, more preferably 92 wt % or more, and still more preferably 95 wt % or more when the total weight of the composition is 100 wt %, from the viewpoint of further improving the solubility of the p-type semiconductor material and the n-type semiconductor material. The total weight of the solvent is preferably 99.9 wt % or less from the viewpoint of increasing the concentration of the p-type semiconductor material and the n-type semiconductor material in the coating liquid to facilitate formation of a layer having a predetermined thickness or more.

The composition may further contain an optional third solvent in addition to the first solvent and the optional second solvent. The content of the optional third solvent is preferably 5 wt % or less, more preferably 3 wt % or less, and still more preferably 1 wt % or less when the total weight of the entire solvent contained in the coating liquid is 100 wt %. The optional third solvent is preferably a solvent having a boiling point higher than that of the second solvent.

[1.4. Optional Components]

The composition according to the present embodiment may contain optional components in addition to the p-type semiconductor material, the n-type semiconductor material, the insulating material, and the solvent as long as the objects and effects of the present invention are not impaired. Examples of the optional component include an ultraviolet absorber, an antioxidant, a sensitizer for sensitizing a function of generating a charge due to absorbed light, and a light stabilizer for increasing stability against ultraviolet rays.

The total content of the optional component in the composition is preferably 10 wt % or less, more preferably 5 wt % or less, and usually 0 wt % or more.

[1.5. Contents of p-Type Semiconductor Material, n-Type Semiconductor Material, and Insulating Material]

The total content of the p-type semiconductor material, the n-type semiconductor material, and the insulating material in the composition can be appropriately set according to, for example, the type of coating method, and the viscosity of the component to be used. The total content of the p-type semiconductor material, the n-type semiconductor material, and the insulating material in the composition is not particularly limited as long as these materials can be dissolved in the composition, but is preferably 1 wt % or more, more preferably 2 wt % or more, still more preferably 3 wt % or more, and preferably 20 wt % or less, more preferably 10 wt % or less, still more preferably 7 wt % or less.

When the composition contains the insulating material, the content of the p-type semiconductor material and/or the n-type semiconductor material can be reduced while the solid content concentration in the composition is maintained in a desired range. Further, even when the content of the p-type semiconductor material and/or the n-type semiconductor material is reduced, variation in characteristics of a film that can be produced from the composition can be reduced.

[1.6. Method for Producing Composition]

The composition can be produced by a publicly known method. For example, when the first solvent and the second solvent are used as the solvent, the composition can be produced by, for example, a method of mixing the first solvent and the second solvent to prepare a mixed solvent, and adding the p-type semiconductor material, the n-type semiconductor material, and the insulating material to the mixed solvent, or a method of adding the p-type semiconductor material and the insulating material to the first solvent, adding the n-type semiconductor material to the second solvent, and then mixing the first solvent and the second solvent to which each material is added.

The solvent, the p-type semiconductor material, the n-type semiconductor material, and the insulating material may be mixed while heating these materials to a temperature equal to or lower than the boiling point of the solvent.

After mixing the solvent with the p-type semiconductor material, the n-type semiconductor material, and the insulating material, the obtained mixture may be filtered with a filter, and the resulting filtrate may be used as a composition. As the filter, a filter made of a fluororesin such as polytetrafluoroethylene (PTFE) can be used, for example.

[1.7. Application of Composition]

The composition can be suitably used as an ink for forming a film containing a p-type semiconductor material, an n-type semiconductor material, and an insulating material by a coating method. In the present specification, the “ink” refers to a liquid material used in a coating method, and is not limited to a colored liquid. In addition, the “coating method” includes a method of forming a film (layer) using a liquid material. The composition of the present invention is particularly suitable for a spin coating method, but other coating methods can also be used. Examples of the coating method include a slot die coating method, a slit coating method, a knife coating method, a casting method, a micro gravure coating method, a gravure coating method, a bar coating method, a roll coating method, a wire bar coating method, a dip coating method, a spray coating method, a screen printing method, a gravure printing method, a flexo printing method, an offset printing method, an inkjet coating method, a dispenser printing method, a nozzle coating method, and a capillary coating method.

[2. Film]

A film according to one embodiment of the present invention contains a p-type semiconductor material, an n-type semiconductor material, and an insulating material, and the n-type semiconductor material contains a non-fullerene compound. Hereinafter, a film containing a p-type semiconductor material, an n-type semiconductor material, and an insulating material, in which the n-type semiconductor material contains a non-fullerene compound, is also referred to as a “film A”.

Examples and preferred examples of the p-type semiconductor material, examples and preferred examples of the n-type semiconductor material, examples and preferred examples of the insulating material, and examples and preferred examples of the non-fullerene compound are the same as those of the examples described in the item [1. Composition].

The preferable range of the weight ratio of the p-type semiconductor material to the n-type semiconductor material (p-type semiconductor material/n-type semiconductor material) in the film according to the present embodiment can be the same as the preferable range of the weight ratio in the composition.

The preferable range of the weight ratio of the insulating material to the p-type semiconductor material (insulating material/p-type semiconductor material) in the film according to the present embodiment can be the same as the preferable range of the weight ratio in the composition.

The thickness of the film according to the present embodiment can be appropriately set according to the intended function of the film. The thickness of the film according to the present embodiment is preferably 100 nm or more, more preferably 150 nm or more, still more preferably 200 nm or more, and preferably 10 μm or less, more preferably 5 μm or less, still more preferably 1 μm or less.

The film according to the present embodiment can be produced by any method. The film according to the present embodiment can be produced by, for example, a method including the following steps.

Step (1): a step of applying a composition to an application target to form a coating film.

Step (2): drying the coating film.

The step (1) and the step (2) are usually performed in this order.

(Step (1))

The composition is a composition containing a p-type semiconductor material, an n-type semiconductor material, an insulating material, and a solvent, in which the n-type semiconductor material contains a non-fullerene compound. As the composition, the preferred compositions already exemplified can be used.

When the film according to the present embodiment functions as an active layer of a photoelectric conversion element, examples of an object to which the composition is applied include an electrode, an electron transportation layer, and a hole transportation layer.

As a method for applying the composition to the application target, any coating method can be used. Examples of the method of applying the composition to the application target in the step (1) include the coating methods exemplified above. Among them, a spin coating method is preferable because a coating film having a uniform thickness is easily obtained.

According to the composition according to the present embodiment, a thick coating film can be formed at a high rotation speed in the spin coating method. From the viewpoint of obtaining this advantage, a spin coating method is preferable as a method of applying the composition to the application target.

(Step (2))

The solvent usually contained in the coating film is removed by drying the coating film. Examples of the method for drying the coating film include drying methods such as a method of directly heating the coating film by using a hot plate in an inert gas atmosphere such as nitrogen gas, a hot-air drying method, an infrared-radiation heat drying method, a flash lamp annealing method, and a reduced-pressure drying method, and a combination thereof.

The drying conditions such as the drying temperature and the drying treatment time can be optionally and suitably set in consideration of the boiling point of the solvent contained in the composition, the thickness of the coating film, and the like.

The method for producing a film according to the present embodiment may include an optional step in addition to the steps (1) and (2).

[3. Photoelectric Conversion Element]

[3.1. Configuration of Photoelectric Conversion Element]

A photoelectric conversion element according to one embodiment of the present invention includes a first electrode, the film A, and a second electrode in this order. In the photoelectric conversion element, the film A can usually function as an active layer. When the photoelectric conversion element is irradiated with light, the first electrode is an electrode that causes a positive charge to flow out to the external circuit, and the second electrode is an electrode into which a positive charge flow from the external circuit.

Hereinafter, the photoelectric conversion element of the present embodiment will be described with reference to the drawings.

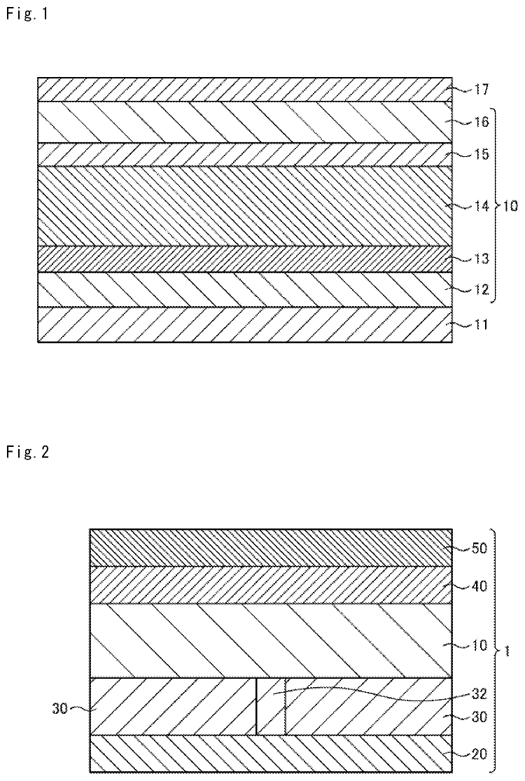

FIG. 1 is a schematic view illustrating a configuration example of a photoelectric conversion element.

As illustrated in FIG. 1, a photoelectric conversion element 10 is provided on a supporting substrate 11. The photoelectric conversion element 10 includes a first electrode 12 provided in contact with the supporting substrate 11, a hole transportation layer 13 provided in contact with the first electrode 12, an active layer 14 provided in contact with the hole transportation layer 13, an electron transportation layer 15 provided in contact with the active layer 14, and a second electrode 16 provided in contact with the electron transportation layer 15. In this configuration example, a sealing member 17 is further provided in contact with the second electrode 16.

Hereinafter, components that can be included in the photoelectric conversion element of the present embodiment will be specifically described.

(Substrate)

The photoelectric conversion element is usually formed on a substrate (supporting substrate). Further, there is also a case where the photoelectric conversion element is sealed by a substrate (sealing substrate). One of a pair of electrodes composed of a first electrode and a second electrode is usually formed on the substrate. The material of the substrate is not particularly limited particularly as long as the material does not chemically change in the formation of a layer containing an organic compound.

Examples of the material of the substrate include glass, plastic, a polymer film, and silicon. In a case where an opaque substrate is used, an electrode opposite to an electrode provided on the opaque substrate side (that is, an electrode provided far from the opaque substrate) is preferably a transparent or translucent electrode.

(Electrode)

The photoelectric conversion element includes a first electrode and a second electrode which are a pair of electrodes. At least one of the first electrode and the second electrode is preferably a transparent or translucent electrode in order to allow light to enter.

Examples of the material of the transparent or translucent electrode include a conductive metal oxide film, and a translucent metal thin film. Specific examples thereof include conductive materials such as indium oxide, zinc oxide, tin oxide, and indium tin oxide (ITO), indium zinc oxide (IZO), and NESA which are composites thereof, gold, platinum, silver, and copper. As the material of the transparent or translucent electrode, ITO, IZO, and tin oxide are preferable. Also, a transparent conductive film formed by using, as a material, an organic compound such as polyaniline and a derivative thereof, and polythiophene and a derivative thereof may be used as the electrode. The transparent or translucent electrode may be the first electrode or the second electrode.

If one of the pair of electrodes is transparent or translucent, the other electrode may be an electrode with low light transmittance. Examples of the material of the electrode with low light transmittance include a metal, and a conductive polymer. Specific examples of the material of the electrode with low light transmittance include metals such as lithium, sodium, potassium, rubidium, cesium, magnesium, calcium, strontium, barium, aluminum, scandium, vanadium, zinc, yttrium, indium, cerium, samarium, europium, terbium, and ytterbium; and alloys of two or more types of these metals, or alloys of one or more types of these metals and one or more types of metal selected from the group consisting of gold, silver, platinum, copper, manganese, titanium, cobalt, nickel, tungsten, and tin; graphite; graphite intercalation compounds; polyaniline and derivatives thereof; and polythiophene and derivatives thereof. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

(Active Layer)

The photoelectric conversion element of the present embodiment includes the film A as an active layer. The active layer which is the film A according to the present embodiment has a bulk-heterojunction structure, and contains a p-type semiconductor material, an n-type semiconductor material, and an insulating material, and the n-type semiconductor material contains a non-fullerene compound. Examples and preferred examples of the p-type semiconductor material, examples and preferred examples of the n-type semiconductor material, examples and preferred examples of the insulating material, and examples and preferred examples of the non-fullerene compound are the same as those of the examples described in the item [1. Composition].

The preferable range of the weight ratio of the p-type semiconductor material to the n-type semiconductor material (p-type semiconductor material/n-type semiconductor material) in the active layer can be the same as the preferable range of the weight ratio in the composition.

The preferable range of the weight ratio of the insulating material to the p-type semiconductor material (insulating material/p-type semiconductor material) in the active layer can be the same as the preferable range of the weight ratio in the composition.

In the present embodiment, the thickness of the active layer is not particularly limited. The thickness of the active layer can be optionally and suitably set in consideration of a balance between suppression of dark current and extraction of generated photocurrent. The thickness of the active layer is preferably 100 nm or more, more preferably 150 nm or more, and still more preferably 200 nm or more, particularly, from the viewpoint of further reducing dark current. The thickness of the active layer is preferably 10 μm or less, more preferably 5 μm or less, and still more preferably 1 μm or less.

(Intermediate Layer)

As illustrated in FIG. 1, the photoelectric conversion element of the present embodiment preferably includes, for example, an intermediate layer (buffer layer) such as a charge transportation layer (electron transportation layer, hole transportation layer, electron injection layer, hole injection layer) as a component for improving characteristics such as photoelectric conversion efficiency.

Examples of the material used for the intermediate layer include metals such as calcium, inorganic oxide semiconductors such as molybdenum oxide and zinc oxide, and a mixture of PEDOT (poly(3,4-ethylenedioxythiophene)) and PSS (poly(4-styrenesulfonate)) (PEDOT:PSS).

In one embodiment, as illustrated in FIG. 1, the photoelectric conversion element preferably includes a hole transportation layer between the first electrode and the active layer. The hole transportation layer has a function of transporting holes from the active layer to the electrode.

In another embodiment, the photoelectric conversion element need not include a hole transportation layer.

A hole transportation layer provided in contact with the first electrode may be particularly referred to as a hole injection layer. The hole transportation layer (hole injection layer) provided in contact with the first electrode has a function of promoting injection of holes into the first electrode. The hole transportation layer (hole injection layer) may be in contact with the active layer.

The hole transportation layer contains a hole transporting material. Examples of the hole transporting material include polythiophene and derivatives thereof, aromatic amine compounds, polymer compounds containing a constituent unit having an aromatic amine residue, CuSCN, CuI, NiO, tungsten oxide (WO₃), and molybdenum oxide (MoO₃).

The intermediate layer can be formed by any preferred publicly known forming method. The intermediate layer can be formed by a vacuum vapor deposition method or the same coating method as the method for forming the active layer.

The photoelectric conversion element according to the present embodiment preferably has a configuration in which the intermediate layer is an electron transportation layer, and a substrate (supporting substrate), a first electrode, a hole transportation layer, an active layer, an electron transportation layer, and a second electrode are layered in this order so as to be in contact with each other.

As illustrated in FIG. 1, the photoelectric conversion element of the present embodiment preferably includes an electron transportation layer as an intermediate layer between the second electrode and the active layer. The electron transportation layer has a function of transporting electrons from the active layer to the second electrode. The electron transportation layer may be in contact with the second electrode.

The electron transportation layer may be in contact with the active layer.

Note that an electron transportation layer provided in contact with the second electrode may be particularly referred to as an electron injection layer. The electron transportation layer (electron injection layer) provided in contact with the second electrode has a function of promoting injection of electrons generated in the active layer into the second electrode.

The electron transportation layer contains an electron transporting material. Examples of the electron transporting material include polyalkyleneimine and derivatives thereof, polymer compounds having a fluorene structure, metals such as calcium, and metal oxides.

Examples of the polyalkyleneimine and derivatives thereof include alkylene imines having from 2 to 8 carbon atoms such as ethyleneimine, propyleneimine, butyleneimine, dimethylethyleneimine, pentyleneimine, hexyleneimine, heptyleneimine, and octyleneimine, particularly, polymers obtained by polymerizing one or two or more types of alkylene imines having from 2 to 4 carbon atoms by a common method, and chemically modified polymers formed by reacting these polymers with various compounds. As the polyalkyleneimine and derivatives thereof, polyethyleneimine (PEI) and ethoxylated polyethyleneimine (PEIE) are preferable.

Examples of the polymer compound having a fluorene structure include poly[(9,9-bis(3′-(N,N-dimethylamino)propyl)-2,7-fluorene)-ortho-2,7-(9,9′-dioctylfluorene)] (PFN) and PFN-P2.

Examples of the metal oxide include zinc oxide, gallium-doped zinc oxide, aluminum-doped zinc oxide, titanium oxide, and niobium oxide. As the metal oxide, a metal oxide containing zinc is preferable, and zinc oxide is particularly preferable.

Examples of other electron transporting materials include poly(4-vinylphenol) and perylene diimide.

(Sealing Member)

The photoelectric conversion element of the present embodiment preferably further includes a sealing member, and is preferably a sealed body sealed by the sealing member.

Any preferred publicly known member can be used as the sealing member. Examples of the sealing member include a combination of a glass substrate as a substrate (sealing substrate) and a sealing material (adhesive) such as a UV curable resin.

The sealing member may be a sealing layer having a layer structure of one or more layers. Examples of the layer constituting the sealing layer include a gas barrier layer and a gas barrier film.

The sealing layer is preferably formed of a material having a property of blocking moisture (water vapor barrier property) or a property of blocking oxygen (oxygen barrier property). Examples of materials suitable as the material of the sealing layer include organic materials such as polytrifluoroethylene, polychlorotrifluoroethylene (PCTFE), polyimide, polycarbonate, polyethylene terephthalate, alicyclic polyolefin, and ethylene-vinyl alcohol copolymers; and inorganic materials such as silicon oxide, silicon nitride, aluminum oxide, and diamond-like carbon.

The sealing member is formed of a material that can withstand a heat treatment that can be performed when the sealing member is incorporated into a device to which the photoelectric conversion element is usually applied, for example, a device of the following application example described later.

[3.2. Method for Producing Photoelectric Conversion Element]

The photoelectric conversion element of the present embodiment can be produced by any method. The photoelectric conversion element of the present embodiment can be produced by combining a forming method suitable for the material selected in the formation of components.

Hereinafter, as an embodiment of the present invention, a method for producing a photoelectric conversion element having a configuration in which a substrate (supporting substrate), a first electrode, a hole transportation layer, a film A as an active layer, an electron transportation layer, and a second electrode are in contact with each other in this order will be described.

(Step of Preparing Substrate)

In this step, for example, a supporting substrate provided with a first electrode is prepared. In addition, a supporting substrate provided with a first electrode can be prepared by obtaining a substrate provided with a conductive thin film formed of the material of the electrode which has been described from the market, and patterning the conductive thin film as necessary to form the first electrode.

In the method for producing a photoelectric conversion element according to the present embodiment, a method for forming the first electrode in the case of forming the first electrode on the supporting substrate is not particularly limited. The first electrode can be formed on a configuration on which the first electrode is to be formed (for example, a supporting substrate, an active layer, a hole transportation layer) by using the material which has been described, by any preferred publicly known method such as a vacuum vapor deposition method, a sputtering method, an ion plating method, a plating method, or a coating method.

(Step of Forming Hole Transportation Layer)

The method for producing a photoelectric conversion element may include a step of forming a hole transportation layer (hole injection layer) provided between the active layer and the first electrode.

A method for forming the hole transportation layer is not particularly limited. From the viewpoint of further simplifying the step of forming the hole transportation layer, the hole transportation layer is preferably formed by any preferred publicly known coating method.

The hole transportation layer can be formed, for example, by a coating method or a vacuum vapor deposition method using a coating liquid containing the material of the hole transportation layer, which has been described, and a solvent.

(Step of Forming Active Layer)

In the method for producing a photoelectric conversion element of the present embodiment, a film A as an active layer is formed on the hole transportation layer. The film A can be formed by any preferred publicly known forming step. In the present embodiment, the film A as an active layer can be produced by a coating method using the composition.

The film A as an active layer can be formed by the same method as the method for producing a film described in the item [2. Film]. In the present embodiment, the film A as an active layer can be formed by a process including: a step of applying a composition containing a p-type semiconductor material, an n-type semiconductor material, an insulating material, and a solvent, in which the n-type semiconductor material contains a non-fullerene compound, onto a hole transportation layer, to form a coating film; and a step of drying the coating film.

(Step of Forming Electron Transportation Layer)

The method for producing a photoelectric conversion element of the present embodiment includes a step of forming an electron transportation layer (electron injection layer) provided on the active layer.

A method for forming the electron transportation layer is not particularly limited. From the viewpoint of further simplifying the step of forming the electron transportation layer, the electron transportation layer is preferably formed by any preferred publicly known vacuum vapor deposition method.

(Step of Forming Second Electrode)

A method for forming the second electrode is not particularly limited. The second electrode can be formed on the electron transportation layer by, for example, using the material of the electrode exemplified above, by any preferred publicly known method such as a coating method, a vacuum vapor deposition method, a sputtering method, an ion plating method, or a plating method. The photoelectric conversion element of the present embodiment is produced through the above steps.

(Step of Forming Sealed Body)

In the present embodiment, any preferred publicly known sealing material (adhesive) and substrate (sealing substrate) are used for forming the sealed body. Specifically, a sealed body of the photoelectric conversion element can be obtained by the following method. A sealing material such as a UV curable resin is applied onto the supporting substrate so as to surround the periphery of the produced photoelectric conversion element. Then, the supporting substrate and a sealing substrate are firmly bonded to each other with a sealing material. Thereafter, the photoelectric conversion element is sealed in a gap between the supporting substrate and the sealing substrate by a method suitable for the selected sealing material, such as irradiation with UV light.

[3.3. Application of Photoelectric Conversion Element]

Examples of application of the photoelectric conversion element of the present embodiment include a photodetection element and a solar cell.

More specifically, the photoelectric conversion element of the present embodiment allows photocurrent to flow by irradiation with light from the transparent or translucent electrode side in a state in which a voltage (reverse bias voltage) is applied between electrodes. Thus, the photoelectric conversion element of the present embodiment can be operated as a photodetection element (photosensor). Further, the photoelectric conversion element of the present embodiment can be used as an image sensor by integrating a plurality of such photodetection elements. As described above, the photoelectric conversion element of the present embodiment can be particularly suitably used as a photodetection element.

Further, the photoelectric conversion element of the present embodiment can generate a photovoltaic power between the electrodes when it is irradiated with light, and thus can be operated as a solar cell. The photoelectric conversion element of the present embodiment can be used as a solar cell module by integrating a plurality of such photoelectric conversion elements.

(Application Example of Photoelectric Conversion Element)

The photoelectric conversion element according to the present embodiment can be suitably applied, as a photodetection element, to a detection part included in various electronic devices such as work stations, personal computers, portable information terminals, entering/leaving management systems, digital cameras, and medical appliances.

The photoelectric conversion element of the present embodiment can be suitably applied to, for example, an image detection part (for example, an image sensor such as an X-ray sensor) for solid-state imaging devices such as an X-ray imaging device and a CMOS image sensor; a detection part of biological information authentication devices (for example, a near-infrared sensor) for detecting predetermined characteristics of a part of the living body, such as a fingerprint detection part, a face detection part, a vein detection part, and an iris detection part; and a detection part of optical biosensors such as a pulse oximeter, which are included in the above exemplified electronic devices.

The photoelectric conversion element of the present embodiment can also be suitably applied, as an image detection part for a solid-state imaging device, to a time-of-flight (TOF) type distance measuring device (TOF type distance measuring device).

In the TOF type distance measuring device, a distance is measured by causing radiation light from a light source to be reflected by an object to be measured, and then causing the photoelectric conversion element to receive the reflected light. Specifically, a distance to the object to be measured is obtained by detecting a flight time during which irradiation light emitted from the light source is reflected by the object to be measured and returns as reflected light. As the TOF type, there are a direct TOF method and an indirect TOF method. In the direct TOF method, a difference between the time at which light is emitted from the light source and the time at which the reflected light is received by the photoelectric conversion element is directly measured. In the indirect TOF method, a distance is measured by converting a change in charge accumulation amount depending on the flight time into a time change. A distance measuring principle for determining the flight time by charge accumulation used in the indirect TOF method includes a continuous wave (particularly, sinusoidal wave) modulation method and a pulse modulation method. In these methods, the flight time is determined based on the phase of the radiation light emitted from the light source and the phase of the reflected light reflected by the measurement target.

Hereinafter, among detection parts to which the photoelectric conversion element according to the present embodiment can be suitably applied, configuration examples of an image detection part for a solid-state imaging device and an image detection part for an X-ray imaging device, a fingerprint detection part and a vein detection part for a biometric authentication device (for example, a fingerprint authentication device and a vein authentication device), and an image detection part of a TOF type distance measuring device (indirect TOF method) will be described with reference to the drawings.

(Image Detection Part for Solid-State Imaging Device)

FIG. 2 is a schematic view illustrating a configuration example of an image detection part for a solid-state imaging device.

An image detection part 1 includes a CMOS transistor substrate 20, an interlayer insulating film 30 provided so as to cover the CMOS transistor substrate 20, a photoelectric conversion element 10 according to an embodiment of the present invention provided on the interlayer insulating film 30, an interlayer wiring part 32 provided so as to penetrate the interlayer insulating film 30 and electrically connecting the CMOS transistor substrate 20 and the photoelectric conversion element 10, a sealing layer 40 provided so as to cover the photoelectric conversion element 10, and a color filter 50 provided on the sealing layer 40.

The CMOS transistor substrate 20 includes any preferred publicly known components in an aspect according to the design.

The CMOS transistor substrate 20 includes a transistor, a capacitor, and the like formed within the thickness of the substrate. The CMOS transistor substrate 20 includes functional elements such as a CMOS transistor circuit (MOS transistor circuit) for achieving various functions.

Examples of the functional element include a floating diffusion, a reset transistor, an output transistor, and a selection transistor.

In the CMOS transistor substrate 20, a signal reading circuit and the like is fabricated with such a functional element and wiring.

The interlayer insulating film 30 can be formed of any preferred publicly known insulating material such as silicon oxide, and an insulating resin, for example. The interlayer wiring part 32 can be formed of any preferred publicly known conductive material (wiring material) such as copper, and tungsten, for example. The interlayer wiring part 32 may be, for example, a wiring in the hole, formed simultaneously with formation of a wiring layer, or an embedded plug formed separately from the wiring layer.

The sealing layer 40 can be formed of any preferred publicly known material on the condition that permeation of harmful substances such as oxygen and water, which may deteriorate the function of the photoelectric conversion element 10, can be prevented or suppressed. The sealing layer 40 can have the same configuration as the sealing member 17 which has been described.

As the color filter 50, a primary color filter, which is formed of any preferred publicly known material and corresponds to the design of the image detection part 1, can be used, for example. As the color filter 50, a complementary color filter, which enables to increase the thickness compared to the primary color filter, can also be used. As the complementary color filter, color filters of the following combination of three types of (yellow, cyan, magenta), three types of (yellow, cyan, transparent), three types of (yellow, transparent, magenta), and three types of (transparent, cyan, magenta) can be used, for example. These filters can be optionally and suitably arranged according to the design of the photoelectric conversion element 10 and the CMOS transistor substrate 20 on the condition that color image data can be generated.

The light received in the photoelectric conversion element 10 though the color filter 50 is converted into an electric signal corresponding to the received light amount by the photoelectric conversion element 10, and then output outside the photoelectric conversion element 10 via the electrode, as a received light signal, that is, an electric signal corresponding to an imaging target.

Then, the received light signal output from the photoelectric conversion element 10 is received as input in the CMOS transistor substrate 20 via the interlayer wiring part 32, and then read by the signal reading circuit fabricated in the CMOS transistor substrate 20 and subjected to signal processing in any preferred publicly known functional part (not illustrated). Thus, image information based on the imaging target can be generated.

(Fingerprint Detection Part)

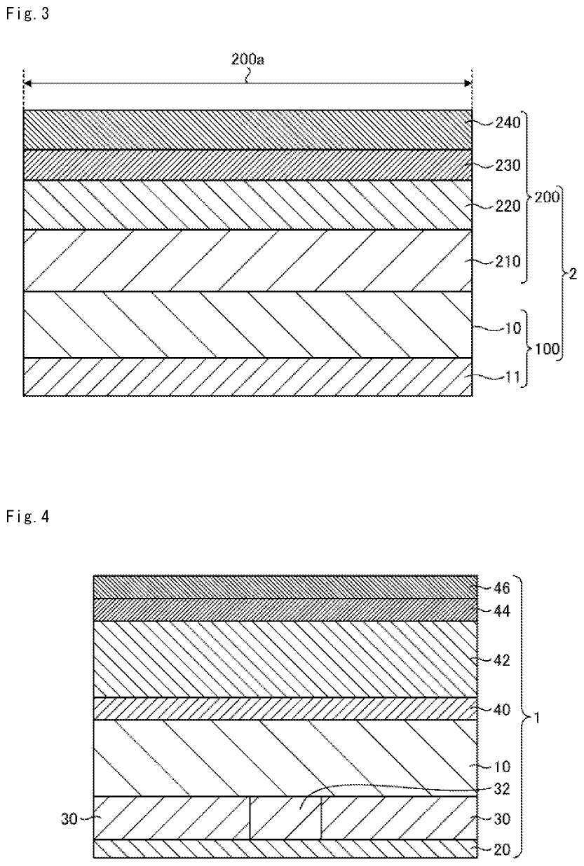

FIG. 3 is a schematic view illustrating a configuration example of a fingerprint detection part integrally formed in a display device.

A display device 2 of a portable information terminal includes a fingerprint detection part 100 including a photoelectric conversion element 10 according to an embodiment of the present invention as a main component, and a display panel part 200 provided on the fingerprint detection part 100 and displaying a predetermined image.

In this configuration example, the fingerprint detection part 100 is provided in a region corresponding to a display region 200a of the display panel part 200. In other words, the display panel part 200 is integrally layered on the fingerprint detection part 100.

In a case where fingerprint detection is performed only in a part of the display region 200a, the fingerprint detection part 100 may be provided corresponding to only the part of the display region 200a.

The fingerprint detection part 100 includes the photoelectric conversion element 10 according to an embodiment of the present invention as a functional part exhibiting an essential function. The fingerprint detection part 100 can include any preferred publicly known members such as a protection film, a supporting substrate, a sealing substrate, a sealing member, a barrier film, a bandpass filter, and an infrared cut film (not illustrated) in an aspect corresponding to the design where desired characteristics can be obtained. The configuration of the image detection part which has been described can be employed for the fingerprint detection part 100.

The photoelectric conversion element 10 can be included in the display region 200a in any aspect. For example, a plurality of photoelectric conversion elements 10 may be arranged in a matrix pattern.

The photoelectric conversion element 10 is provided on the supporting substrate 11 as described above. The supporting substrate 11 is provided with an electrode (first electrode or second electrode) in a matrix pattern, for example.

The light received in the photoelectric conversion element 10 is converted into an electric signal corresponding to the received light amount by the photoelectric conversion element 10, and then output outside the photoelectric conversion element 10 via the electrode as a received light signal, that is, an electric signal corresponding to the imaged fingerprint.

In this configuration example, the display panel part 200 is configured as an organic electroluminescence display panel (organic EL display panel) including a touch sensor panel. The display panel part 200 may be composed of a display panel having any preferred publicly known components such as a liquid crystal display panel including a light source such as a back light instead of the organic EL display panel, for example.

The display panel part 200 is provided on the fingerprint detection part 100 which has been described. The display panel part 200 includes an organic electroluminescence element (organic EL element) 220 as a functional part exhibiting an essential function. The display panel part 200 can further include any preferred publicly known components, for example, a substrate (a supporting substrate 210 or a sealing substrate 240) such as any preferred publicly known glass substrate, a sealing member, a barrier film, a polarizing plate such as a circularly polarizing plate, and a touch sensor panel 230 in an aspect corresponding to desired characteristics.

In the configuration example as described above, the organic EL element 220 is used as a light source of pixels in the display region 200a, and is also used as a light source for imaging a fingerprint in the fingerprint detection part 100.

Here, operations of the fingerprint detection part 100 will be simply described.

In execution of fingerprint authentication, the fingerprint detection part 100 detects a fingerprint by using light emitted from the organic EL element 220 in the display panel part 200. Specifically, light emitted from the organic EL element 220 passes through components existing between the organic EL element 220 and the photoelectric conversion element 10 of the fingerprint detection part 100, and is reflected by the skin of the fingertip (surface of the finger) placed on the surface of the display panel part 200 in the display region 200a. At least a part of light reflected by the surface of the finger passes through components exiting between the organic EL element 220 and the photoelectric conversion element 10, is then received by the photoelectric conversion element 10, and converted into an electric signal corresponding to the received light amount of the photoelectric conversion element 10. Then, image information about the fingerprint of the surface of the finger is constituted based on the converted electric signal.

The portable information terminal including the display device 2 executes fingerprint authentication by comparing the obtained image information with fingerprint data for fingerprint authentication which has been recorded in advance by any preferred publicly known step.

(Image Detection Part for X-Ray Imaging Device)

FIG. 4 is a schematic view illustrating a configuration example of an image detection part for an X-ray imaging device.

The image detection part 1 for an X-ray imaging device includes a CMOS transistor substrate 20, an interlayer insulating film 30 provided so as to cover the CMOS transistor substrate 20, a photoelectric conversion element 10 according to an embodiment of the present invention provided on the interlayer insulating film 30, an interlayer wiring part 32 provided so as to penetrate the interlayer insulating film 30 and electrically connecting the CMOS transistor substrate 20 and the photoelectric conversion element 10, a sealing layer 40 provided so as to cover the photoelectric conversion element 10, a scintillator 42 provided on the sealing layer 40, a reflective layer 44 provided so as to cover the scintillator 42, and a protective layer 46 provided so as to cover the reflective layer 44.

The CMOS transistor substrate 20 includes any preferred publicly known components in an aspect according to the design.

The CMOS transistor substrate 20 includes a transistor, a capacitor, and the like formed within the thickness of the substrate. The CMOS transistor substrate 20 includes functional elements such as a CMOS transistor circuit (MOS transistor circuit) for achieving various functions.

Examples of the functional element include a floating diffusion, a reset transistor, an output transistor, and a selection transistor.

In the CMOS transistor substrate 20, a signal reading circuit and the like is fabricated with such a functional element and wiring.

The interlayer insulating film 30 can be formed of any preferred publicly known insulating material such as silicon oxide, and an insulating resin, for example. The interlayer wiring part 32 can be formed of any preferred publicly known conductive material (wiring material) such as copper, and tungsten, for example. The interlayer wiring part 32 may be, for example, a wiring in the hole, formed simultaneously with formation of a wiring layer, or an embedded plug formed separately from the wiring layer.

The sealing layer 40 can be formed of any preferred publicly known material on the condition that permeation of harmful substances such as oxygen and water, which may deteriorate the function of the photoelectric conversion element 10, can be prevented or suppressed. The sealing layer 40 can have the same configuration as the sealing member 17 which has been described.

The scintillator 42 can be formed of any preferred publicly known material corresponding to the design of the image detection part 1 for an X-ray imaging device. Examples of preferred materials for the scintillator 42 include inorganic crystals of inorganic materials such as CsI (cesium iodide), NaI (sodium iodide), ZnS (zinc sulfide), GOS (gadolinium oxysulfide), and GSO (gadolinium silicate); organic crystals of organic materials such as anthracene, naphthalene, and stilbene; organic liquids obtained by dissolving an organic material such as diphenyloxazole (PPO) or terphenyl (TP) in an organic solvent such as toluene, xylene, or dioxane; gases such as xenon and helium; and plastics.

The above components can be optionally and suitably arranged corresponding to the design of the photoelectric conversion element 10 and the CMOS transistor substrate 20, on the condition that the scintillator 42 can convert an incident X-ray into light having a wavelength centered on the visible region to generate image data.

The reflective layer 44 reflects the light converted by the scintillator 42. The reflective layer 44 can reduce the loss of the converted light to increase the detection sensitivity. The reflective layer 44 can also block light directly incident from the outside.

The protective layer 46 can be formed of any preferred publicly known material on the condition that permeation of harmful substances such as oxygen and water, which may deteriorate the function of the scintillator 42, can be prevented or suppressed.

Here, the operations of the image detection part 1 for an X-ray imaging device having the above configuration will be simply described.

When radiation energy such as X-rays and γ-rays is incident on the scintillator 42, the scintillator 42 absorbs the radiation energy and converts the radiation energy into light (fluorescence) having a wavelength from the ultraviolet region to the infrared region centered on the visible region. Then, the light converted by the scintillator 42 is received by the photoelectric conversion element 10.

The light received in the photoelectric conversion element 10 though the scintillator 42 is converted into an electric signal corresponding to the received light amount by the photoelectric conversion element 10, and then output outside the photoelectric conversion element 10 via the electrode, as a received light signal, that is, an electric signal corresponding to an imaging target. The radiation energy (X-ray) as a detection target may be incident from either the scintillator 42 side or the photoelectric conversion element 10 side.

Then, the received light signal output from the photoelectric conversion element 10 is received as input in the CMOS transistor substrate 20 via the interlayer wiring part 32, and then read by the signal reading circuit fabricated in the CMOS transistor substrate 20 and subjected to signal processing in any preferred publicly known functional part (not illustrated). Thus, image information based on the imaging target can be generated.

(Vein Detection Part)

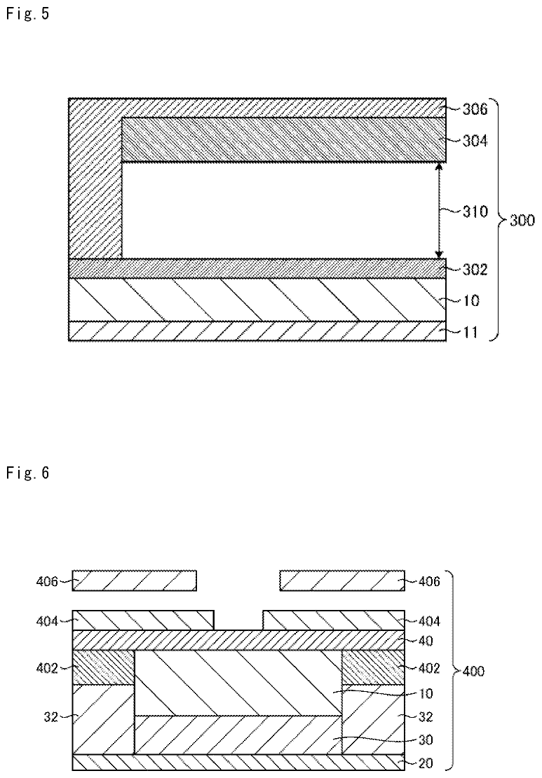

FIG. 5 is a schematic view illustrating a configuration example of a vein detection part for a vein authentication device.

A vein detection part 300 for a vein authentication device includes a cover part 306 that defines an insertion part 310 into which a finger (for example, one or more fingertips of fingers, fingers, or palms) as a measurement target is inserted at the time of measurement, a light source part 304 that is provided in the cover part 306 and irradiates the measurement target with light, a photoelectric conversion element 10 that receives the light emitted from the light source part 304 through the measurement target, a supporting substrate 11 that supports the photoelectric conversion element 10, and a glass substrate 302 that is arranged to face the support substrate 11 with the photoelectric conversion element 10 interposed therebetween, is separated from the cover part 306 at a predetermined distance, and defines the insertion part 306 together with the cover part 306.

In this configuration example, a transmission imaging system is employed in which the light source part 304 is integrated with the cover part 306 so as to be separated from the photoelectric conversion element 10 with the measurement target interposed therebetween at the time of use. The light source part 304 is not necessarily located on the cover part 306 side.

For example, a reflection imaging system may be employed in which the measurement target is irradiated from the photoelectric conversion element 10 side, on the condition that the measurement target can be efficiently irradiated with light from the light source part 304.

The vein detection part 300 includes the photoelectric conversion element 10 according to an embodiment of the present invention as a functional part exhibiting an essential function. The vein detection part 300 may include any preferred publicly known members such as a protection film, a sealing member, a barrier film, a bandpass filter, a near infrared transmission filter, a visible light cut film, and a finger placing guide (not illustrated) in an aspect corresponding to the design where desired characteristics can be obtained. The configuration of the image detection part 1 which has been described can be employed for the vein detection part 300.

The photoelectric conversion element 10 can be included in any aspect. For example, a plurality of photoelectric conversion elements 10 may be arranged in a matrix pattern.

The photoelectric conversion element 10 is provided on the supporting substrate 11 as described above. The supporting substrate 11 is provided with an electrode (first electrode or second electrode) in a matrix pattern, for example.

The light received in the photoelectric conversion element 10 is converted into an electric signal corresponding to the received light amount by the photoelectric conversion element 10, and then output outside the photoelectric conversion element 10 via the electrode as a received light signal, that is, an electric signal corresponding to the imaged vein.

At the time of vein detection (at the time of use), the measurement target may or may not be in contact with the glass substrate 302 on the photoelectric conversion element 10 side.

Here, operations of the vein detection part 300 will be simply described.

At the time of vein detection, the vein detection part 300 detects a vein pattern of the measurement target by using the light emitted from the light source part 304. Specifically, the light emitted from the light source part 304 passes through the measurement target, and is converted into an electric signal corresponding to the received light amount in the photoelectric conversion element 10. Then, image information of the vein pattern of the measurement target is constituted based on the converted electric signal.

The vein authentication device executes vein authentication by comparing the obtained image information with vein data for vein authentication which has been recorded in advance by any preferred publicly known step.

(Image Detection Part for TOF Type Distance Measuring Device)

FIG. 6 is a schematic view illustrating a configuration example of an image detection part for a TOF type distance measuring device of an indirect method.

An image detection part 400 for a TOF type distance measuring device includes a CMOS transistor substrate 20, an interlayer insulating film 30 provided so as to cover the CMOS transistor substrate 20, a photoelectric conversion element 10 according to an embodiment of the present invention provided on the interlayer insulating film 30, two floating diffusion layers 402 arranged to be separated from each other with the photoelectric conversion element 10 interposed therebetween, an insulating layer 40 provided so as to cover the photoelectric conversion element 10 and the floating diffusion layers 402, and two photogates 404 provided on the insulating layer 40 and arranged to be separated from each other.

A part of the insulating layer 40 is exposed through the gap between the two photogates 404 which are separated from each other, and the remaining region of the insulating layer 40 is shielded by a light shielding part 406. The CMOS transistor substrate 20 and the floating diffusion layer 402 are electrically connected by an interlayer wiring part 32 provided so as to penetrate the interlayer insulating film 30.

The interlayer insulating film 30 can be formed of any preferred publicly known insulating material such as silicon oxide, and an insulating resin, for example. The interlayer wiring part 32 can be formed of any preferred publicly known conductive material (wiring material) such as copper, and tungsten, for example. The interlayer wiring part 32 may be, for example, a wiring in the hole, formed simultaneously with formation of a wiring layer, or an embedded plug formed separately from the wiring layer.

In this configuration example, the insulating layer 40 may have any preferred publicly known configuration such as a field oxide film formed of silicon oxide.

The photogate 404 can be formed of any preferred publicly known material such as polysilicon, for example.

The image detection part 400 for a TOF type distance measuring device includes the photoelectric conversion element 10 according to an embodiment of the present invention as a functional part exhibiting an essential function. The image detection part 400 for a TOF type distance measuring device can include any preferred publicly known members such as a protection film, a supporting substrate, a sealing substrate, a sealing member, a barrier film, a bandpass filter, and an infrared cut film (not illustrated) in an aspect corresponding to the design where desired characteristics can be obtained.

Here, the operations of the image detection part 400 for a TOF type distance measuring device will be simply described.

Light is emitted from the light source, the light from the light source is reflected by the measurement target, and the reflected light is received by the photoelectric conversion element 10. The two photogates 404 are provided between the photoelectric conversion element 10 and the floating diffusion layers 402. When pulse is alternately applied to the two photogates 404, signal charges are generated by the photoelectric conversion element 10. The generated signal charges are transferred to one of the two floating diffusion layers 402, and the charges are accumulated in the floating diffusion layers 402. When the light pulse arrives so as to overlap equally with respect to the timing at which the two photogates 404 are opened, the amounts of charge accumulated in the two floating diffusion layers 402 become equal. When the light pulse arrives at one photogate 404 later than the timing at which the light pulse arrives at the other photogate 404, a difference occurs in the amount of charge accumulated in the two floating diffusion layers 402.

The difference in the amount of charge accumulated in the floating diffusion layers 402 depends on the delay time of the light pulse. A distance L to the measurement target has a relationship of L=(1/2) ctd where td is the round-trip time of light and c is the velocity of light. Therefore, if the delay time can be estimated from the difference between the amounts of charge of the two floating diffusion layers 402, the distance to the measurement target can be obtained.

The amount of light received by the photoelectric conversion element 10 is converted into an electric signal as a difference in the amount of charge accumulated in the two floating diffusion layers 402. The signal is output to the outside of the photoelectric conversion element 10, as a received light signal, that is, an electric signal corresponding to the measurement target.

Then, the received light signal output from the floating diffusion layers 402 is received as input in the CMOS transistor substrate 20 via the interlayer wiring part 32, then read by the signal reading circuit fabricated in the CMOS transistor substrate 20, and subjected to signal processing in any preferred publicly known functional part (not illustrated). Thus, distance information based on the measurement target can be generated.

[4. Photodetection Element]

As described above, the organic photoelectric conversion element of the present embodiment may have a photodetection function capable of converting emitted light into an electric signal corresponding to the received light amount and outputting the electric signal to the external circuit via electrodes.

Therefore, the photodetection element according to one embodiment of the present invention may have a photodetection function by including the organic photoelectric conversion element. The photodetection element of the present embodiment may be the organic photoelectric conversion element itself, or may include a functional element for voltage control or the like in addition to the organic photoelectric conversion element.

### EXAMPLES

Hereinafter, examples will be given for further detailed description of the present invention. The present invention is not limited to examples described below. The following examples were performed under the conditions of normal temperature and normal pressure unless otherwise specified. The unit “%” and “part(s)” represent “wt %” and “part(s) by weight”, respectively, unless otherwise specified.

<Materials Used>

The p-type semiconductor material (electron-donating compound), the n-type semiconductor material (electron-accepting compound), and the insulating material (compound not involved in the photoelectric conversion process) used in the following examples are as follows.

(p-Type Semiconductor Material)

As the p-type semiconductor material, the following polymers P-1 to P-3 as polymer compounds were used.

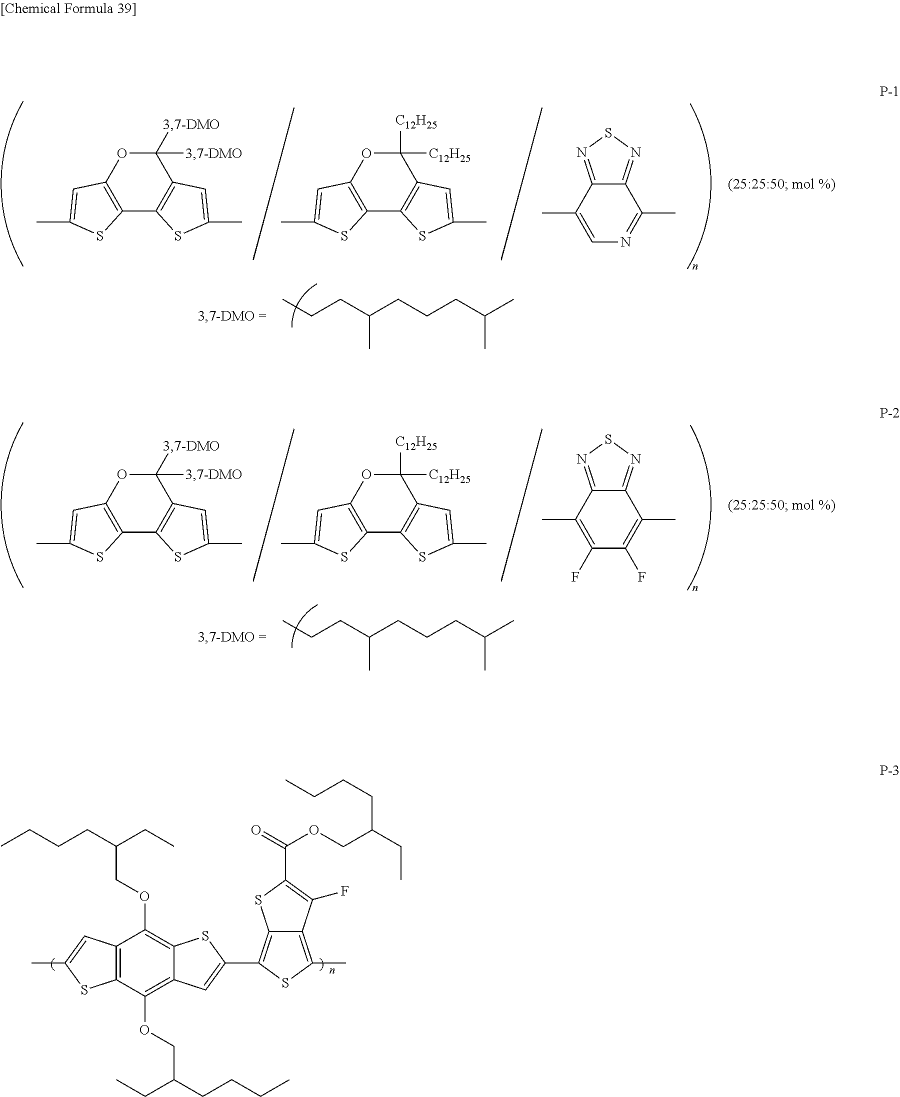

The polymer P-1 which is a p-type semiconductor material was synthesized with reference to the method described in WO 2011/052709 A and used.

The polymer P-2 which is a p-type semiconductor material was synthesized with reference to the method described in WO 2013/051676 A and used.

As the polymer P-3 which is a p-type semiconductor material, PTB7 (trade name, manufactured by 1-material) was obtained from the market and used.

(n-Type Semiconductor Material)

As the n-type semiconductor material, the following compounds N-1 to N-4 were used.

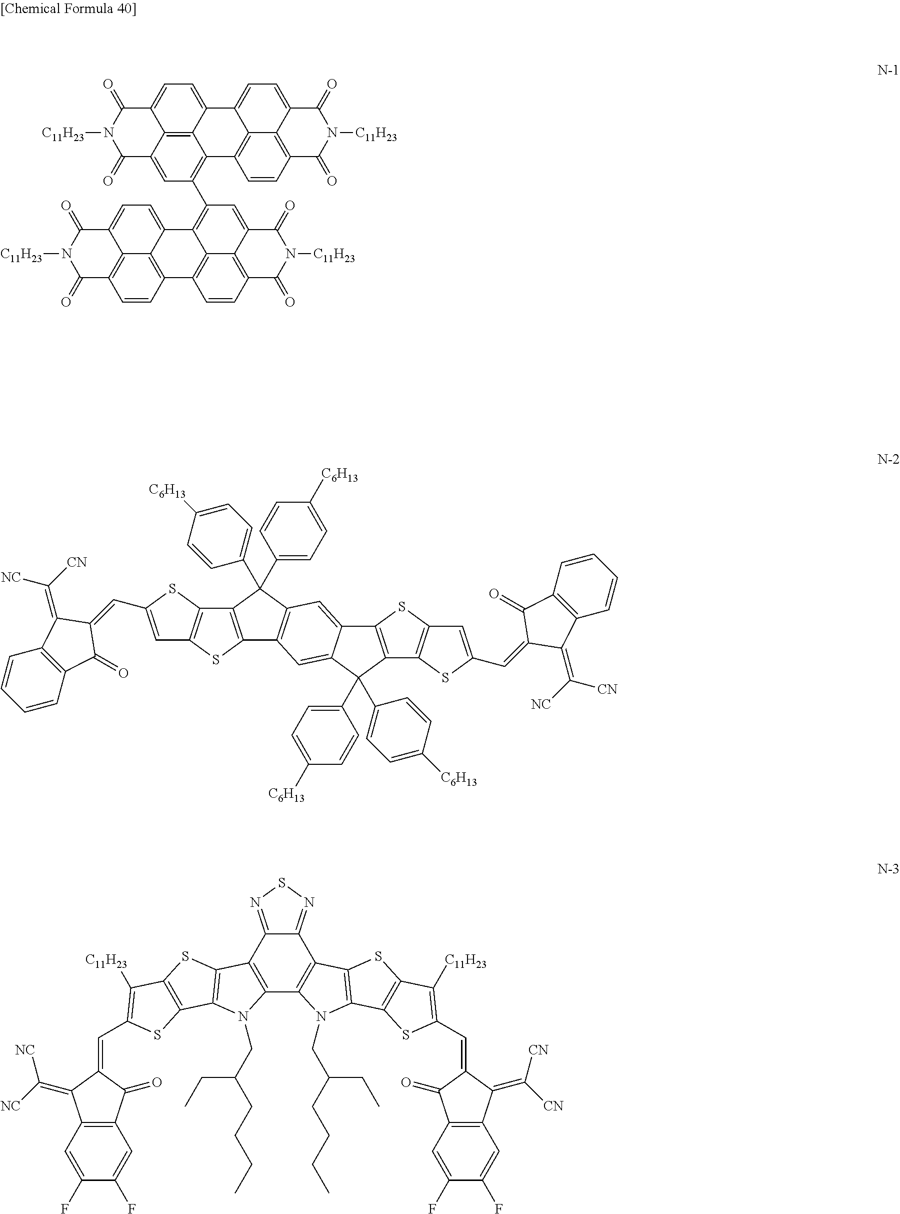

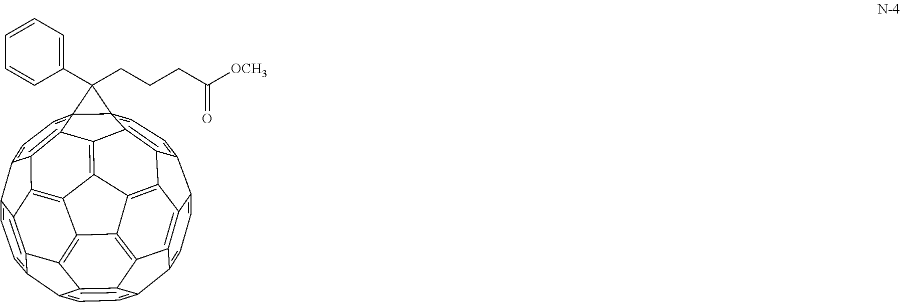

As the compound N-1 which is an n-type semiconductor material, diPDI (trade name, manufactured by 1-material) was obtained from the market and used.

As the compound N-2 which is an n-type semiconductor material, ITIC (trade name, manufactured by 1-material) was obtained from the market and used.

As the compound N-3 which is an n-type semiconductor material, Y6 (trade name, manufactured by 1-material) was obtained from the market and used.

As the compound N-4 which is an n-type semiconductor material, E100 (trade name, manufactured by Frontier Carbon Corporation) was obtained from the market and used.

(Insulating Material)

As the insulating material, the following polymers Z-1 to Z-5 were used.

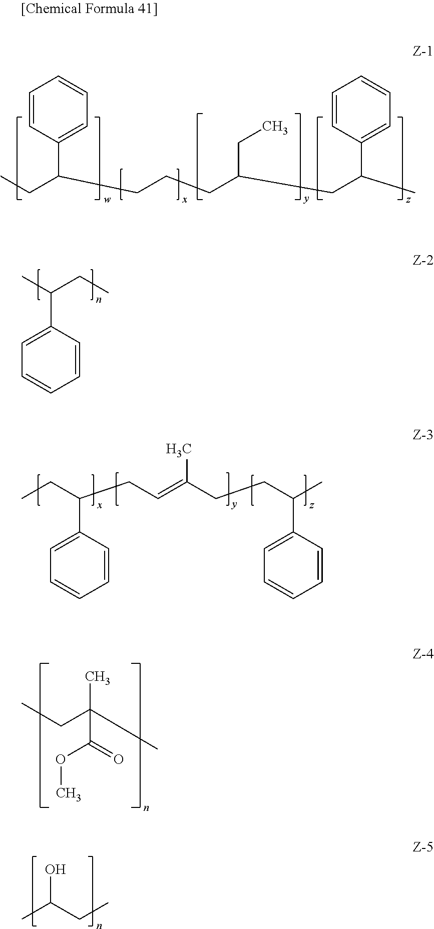

As the compound Z-1 which is an insulating material, polystyrene-block-poly(ethylene-ran-butylene)-block-polystyrene (weight average molecular weight (Mw): 118,000 or less, manufactured by Sigma-Aldrich Co. LLC) was obtained from the market and used.

As the compound Z-2 which is an insulating material, polystyrene (weight average molecular weight (Mw): 35,000, manufactured by Sigma-Aldrich Co. LLC) was obtained from the market and used.

As the compound Z-3 which is an insulating material, polystyrene-block-polyisoprene-block-polystyrene (number average molecular weight (Mn): 1,900, manufactured by Sigma-Aldrich Co. LLC) was obtained from the market and used.

As the compound Z-4 which is an insulating material, poly(methyl methacrylate) (weight average molecular weight (Mw): 15,000 or less, manufactured by Sigma-Aldrich Co. LLC) was obtained from the market and used.

As the compound Z-5 which is an insulating material, poly(vinyl alcohol) (weight average molecular weight (Mw): 9,000 or more and 10,000 or less, manufactured by Sigma-Aldrich Co. LLC) was obtained from the market and used.

[Solubility of Insulating Material in Solvent]

The solubility of the insulating material in the solvent was evaluated as follows.

A mixed solvent was prepared using tetralin as a first solvent and butyl benzoate as a second solvent at a weight ratio of the first solvent to the second solvent of 97: 3. To 99 parts by weight of the mixed solvent was added 1 part by weight of any one of the compounds Z-1 to Z-5 as an insulating material, and the mixture was stirred at 60° C. for 1 hour.

The mixture after cooling to 25° C. was visually observed, and whether or not the insulating material remained undissolved was confirmed.

The solubility of the insulating material was evaluated according to the following criteria.

Good: There is no undissolved residue.

Poor: There is an undissolved residue.

The evaluation results are shown in Table 1 below. The results show that the insulating materials Z-1 to Z-4 are materials that dissolve in an amount of 0.1 wt % or more in the mixed solvent at 25° C.

TABLE 1

| Insulating material | Solubility in solvent |
|---|---|
| Z-1 | Good |
| Z-2 | Good |
| Z-3 | Good |
| Z-4 | Good |
| Z-5 | Poor |

To 99.9 parts by weight of the mixed solvent was added 0.1 parts by weight of the insulating material Z-5, and the mixture was stirred at 60° C. for 1 hour. The mixture after stirring was cooled to 25° C. When the mixture was visually observed, the insulating material remained undissolved. The result shows that the insulating material Z-5 is a material that does not dissolve in an amount of 0.1 wt % or more in the mixed solvent at 25° C.

Ink compositions were prepared using, as insulating materials, the compounds Z-1 to Z-4 which dissolve in an amount of 0.1 wt % or more in the mixed solvent at 25° C.

<Evaluation of Film Formability and Photoelectric Conversion Element Characteristics>

[Preparation of Ink (Composition)]

### [Preparation Example 1] Preparation of Ink I-1

A mixed solvent was prepared using tetralin as a first solvent and butyl benzoate as a second solvent at a weight ratio of the first solvent to the second solvent of 97:3.

The polymer compound (polymer) P-1 as a p-type semiconductor material, the compound N-1 as an n-type semiconductor material, and the compound Z-1 as an insulating material were added to the obtained mixed solvent so as to have a concentration of 1.5 wt %, 1.5 wt %, and 0.75 wt %, respectively, with respect to the total weight of the ink, and the mixture was stirred at 60° C. for 8 hours to obtain a mixed liquid. The resulting mixed liquid was filtered with a filter to obtain an ink I-1.

### [Preparation Example 2] Preparation of Ink I-2

As an insulating material, the compound Z-2 was used in place of the compound Z-1.

An ink I-2 was obtained by the same operation as in Preparation Example 1 except for the above item.

### [Preparation Example 3] Preparation of Ink I-3

As an insulating material, the compound Z-3 was used in place of the compound Z-1.

An ink I-3 was obtained by the same operation as in Preparation Example 1 except for the above item.

### [Reference Preparation Example 1] Preparation of Ink R-1

The compound Z-1 as an insulating material was not added to the mixed solvent.

An ink R-1 was obtained by the same operation as in Preparation Example 1 except for the above item.

### [Preparation Example 4] Preparation of Ink I-4

As a p-type semiconductor material, the polymer P-2 was used in place of the polymer P-1, and the polymer P-2 was added to the mixed solvent so as to have a concentration of 2 wt % with respect to the total weight of the ink.
As an n-type semiconductor material, the compound N-2 was used in place of the compound N-1, and the compound N-2 was added to the mixed solvent so as to have a concentration of 4 wt % with respect to the total weight of the ink.
The compound Z-1 as an insulating material was added to the mixed solvent so as to have a concentration of 1 wt % with respect to the total weight of the ink.

An ink I-4 was obtained by the same operation as in Preparation Example 1 except for the above items.

### [Reference Preparation Example 2] Preparation of Ink R-2

As a p-type semiconductor material, the polymer P-2 was used in place of the polymer P-1, and the polymer P-2 was added to the mixed solvent so as to have a concentration of 2 wt % with respect to the total weight of the ink.
As an n-type semiconductor material, the compound N-2 was used in place of the compound N-1, and the compound N-2 was added to the mixed solvent so as to have a concentration of 4 wt % with respect to the total weight of the ink.
The compound Z-1 as an insulating material was not added to the mixed solvent.

An ink R-2 was obtained by the same operation as in Preparation Example 1 except for the above items.

### [Preparation Example 5] Preparation of Ink I-5

As a p-type semiconductor material, the polymer P-3 was used in place of the polymer P-1.
As an n-type semiconductor material, the compound N-3 was used in place of the compound N-1.
As an insulating material, the compound Z-4 was used in place of the compound Z-1.

An ink I-5 was obtained by the same operation as in Preparation Example 1 except for the above items.

### [Reference Preparation Example 3] Preparation of Ink R-3

As a p-type semiconductor material, the polymer P-3 was used in place of the polymer P-1.
As an n-type semiconductor material, the compound N-3 was used in place of the compound N-1.
The compound Z-1 as an insulating material was not added to the mixed solvent.

An ink R-3 was obtained by the same operation as in Preparation Example 1 except for the above items.

### [Comparative Preparation Example 1] Preparation of Ink C-1

As an n-type semiconductor material, the compound N-4 was used in place of the compound N-1.

An ink C-1 was obtained by the same operation as in Preparation Example 1 except for the above item.

### [Reference Preparation Example 4] Preparation of Ink R-4

As an n-type semiconductor material, the compound N-4 was used in place of the compound N-1.
The compound Z-1 as an insulating material was not added to the mixed solvent.

An ink R-4 was obtained by the same operation as in Preparation Example 1 except for the above items.

The formulation of each preparation example is shown in Table 2 below.

TABLE 2

| | | P-type semiconductor | | n-type semiconductor | | | |
|---|---|---|---|---|---|---|---|
| | | material | | material | | Insulating material | |
| | | | Concentration | | Concentration | | Concentration |
| | | Type | (wt %) | Type | (wt %) | Type | (wt %) |
| Reference | R-1 | P-1 | 1.5 | N-1 | 1.5 | — | — |
| Preparation | | | | | | | |
| Example 1 | | | | | | | |
| Preparation | I-1 | P-1 | 1.5 | N-1 | 1.5 | Z-1 | 0.75 |
| Example 1 | | | | | | | |
| Preparation | I-2 | P-1 | 1.5 | N-1 | 1.5 | Z-2 | 0.75 |
| Example 2 | | | | | | | |
| Preparation | I-3 | P-1 | 1.5 | N-1 | 1.5 | Z-3 | 0.75 |
| Example 3 | | | | | | | |
| Reference | R-2 | P-2 | 2 | N-2 | 4 | — | — |
| Preparation | | | | | | | |
| Example 2 | | | | | | | |
| Preparation | I-4 | P-2 | 2 | N-2 | 4 | Z-1 | 1 |
| Example 4 | | | | | | | |
| Reference | R-3 | P-3 | 1.5 | N-3 | 1.5 | — | — |
| Preparation | | | | | | | |
| Example 3 | | | | | | | |
| Preparation | I-5 | P-3 | 1.5 | N-3 | 1.5 | Z-4 | 0.75 |
| Example 5 | | | | | | | |
| Reference | R-4 | P-1 | 1.5 | N-4 | 1.5 | — | — |
| Preparation | | | | | | | |
| Example 4 | | | | | | | |
| Comparative | C-1 | P-1 | 1.5 | N-4 | 1.5 | Z-1 | 0.75 |
| Preparation | | | | | | | |
| Example 1 | | | | | | | |

### Examples 1 to 5, Reference Examples 1a, 1b, and 2 to 4, and Comparative Example 1

(1) Production of Photoelectric Conversion Element and Sealed Body Thereof

A glass substrate was prepared on which an ITO thin film (first electrode) having a thickness of 50 nm has been formed by a sputtering method. The glass substrate was subjected to ozone UV treatment as a surface treatment.

Next, any one of the inks I-1 to I-5, the inks R-1 to R-4, and the ink C-1 prepared on the previous day was applied onto the ITO thin film by a spin coating method at a rotation speed of X rpm to form a coating film. The coating program is as follows.
The rotation speed is increased from 0 rpm to X rpm in 1 second, maintained at X rpm for 30 seconds, and then decreased from X rpm to 0 rpm in 1 second to stop the rotation. The rotation speed X was as shown in Table 3.

Then, the coating film was heated and dried for 10 minutes using a hot plate heated at 100° C. under a nitrogen gas atmosphere to form a film as an active layer. The thickness of the film (active layer) thus formed was approximately as shown in Table 3.

Next, in a resistance heating vapor deposition apparatus, a calcium (Ca) layer having a thickness of about 5 nm was formed on the active layer thus formed, thereby forming an electron transportation layer.

Then, a silver (Ag) layer having a thickness of about 60 nm was formed on the electron transportation layer thus formed, thereby forming a second electrode.

Through the above steps, a photoelectric conversion element was produced on the glass substrate.

Next, a UV-curable sealing agent as a sealing material was applied onto the glass substrate as a supporting substrate so as to surround the periphery of the produced photoelectric conversion element. Then, a glass substrate as a sealing substrate was bonded to the supporting substrate. Subsequently, this assembly was irradiated with UV light, thereby sealing the photoelectric conversion element in the gap between the supporting substrate and the sealing substrate. Thus, a sealed body of the photoelectric conversion element was obtained. The planar shape of the photoelectric conversion element sealed in the gap between the supporting substrate and the sealing substrate as viewed from the thickness direction was a square of 2 mm×2 mm.

(2) Evaluation of Photoelectric Conversion Element

A bias voltage (2.5 V) was applied in a reverse direction to the sealed body of the produced photoelectric conversion element in a dark place. An external quantum efficiency (EQE) at this applied voltage was measured and evaluated with a solar simulator (CEP-2000, manufactured by Bunkoukeiki Co., Ltd.).

Regarding the EQE, first, the sealed body of the photoelectric conversion element was irradiated with light of a predetermined number of photons (1.0×10¹⁶) every 20 nm in a wavelength range of 300 nm to 1,200 nm in a state where a bias voltage (2.5 V) was applied in a reverse direction to the sealed body in a dark place, and the value of a current generated at that time was measured. Then, a spectrum of the EQE at a wavelength of 300 nm to 1,200 nm was obtained by a known technique.

Next, among a plurality of measured values obtained for every 20 nm, a measured value at a wavelength (Amax) closest to the peak wavelength of the EQE spectrum was taken as the value (%) of the EQE.

The coating conditions (rotation speed) for the spin coating method and the approximate thickness of the obtained active layer in each of examples, reference examples, and comparative examples are shown in Table 3.

TABLE 3

| | | | Spin coating | Film |
|---|---|---|---|---|
| | | | rotation speed | thickness |
| | | Ink | X rpm | (nm) |
| Reference | Active layer R1 | R-1 | 750 | 240 |
| Example 1a | | | | |
| Example 1 | Active layer 1 | I-1 | 1200 | 240 |
| Example 2 | Active layer 2 | I-2 | 1000 | 240 |
| Reference | Active layer R1b | R-1 | 700 | 310 |
| Example 1b | | | | |
| Example 3 | Active layer 3 | I-3 | 1000 | 340 |
| Reference | Active layer R2 | R-2 | 800 | 660 |
| Example 2 | | | | |
| Example 4 | Active layer 4 | I-4 | 1200 | 660 |
| Reference | Active layer R3 | R-3 | 600 | 430 |
| Example 3 | | | | |
| Example 5 | Active layer 5 | I-5 | 700 | 450 |
| Reference | Active layer R4 | R-4 | 500 | 330 |
| Example 4 | | | | |
| Comparative | Active layer C1 | C-1 | 800 | 340 |
| Example 1 | | | | |

[Evaluation Result of Film Formability]

The following matters can be seen from the results in Table 3.

The results of Examples 1 to 2 with respect to Reference Example 1a show that the inks I-1 and I-2 (that is, the weight ratio of the insulating material to the p-type semiconductor material in the ink is 0.75/1.5=50/100) containing 0.75 wt % of the insulating material can yield an active layer having a thickness equal to that of an active layer produced from an ink containing no insulating material, even when the rotation speed at the time of application by the spin coating method is increased.

The result of Example 3 with respect to Reference Example 1b shows that the ink I-3 (that is, the weight ratio of the insulating material to the p-type semiconductor material in the ink is 0.75/1.5=50/100) containing 0.75 wt % of the insulating material Z-3 can yield an active layer thicker than that of an active layer produced from an ink containing no insulating material, even when the rotation speed at the time of application by the spin coating method is increased.

The result of Example 4 with respect to Reference Example 2 and the result of Example 5 with respect to Reference Example 3 show that the inks I-4 and I-5 in which the p-type semiconductor material and the n-type semiconductor material are changed can also yield an active layer having a thickness equal to or more than that of an active layer produced from the ink containing no insulating material, even when the rotation speed at the time of spin coating is increased.

The result of Comparative Example 1 with respect to Reference Example 4 shows that the ink C-1 containing a fullerene compound as an n-type semiconductor material can also yield an active layer thicker than that of an active layer produced from an ink containing no insulating material, even when the rotation speed at the time of application by the spin coating method is increased.

The above results show that inclusion of the insulating material in the ink allows production of a film having a thickness equal to or more than that of an ink containing no insulating material by the spin coating method under a higher rotation speed condition, and thus improves the film formability.

[Measurement Result of EQE]

The EQE₁ according to each of Examples 1 to 5 and Comparative Example 1 is normalized by dividing the EQE (EQE₁) according to each of Examples 1 to 5 and Comparative Example 1 in which the active layer was produced with an ink containing an insulating material by the EQE (EQE_{R}) according to the reference example in which the active layer was produced with an ink containing no insulating material, and the ratio EQE_{I}/EQE_{R} was calculated. Specifically, the ratio EQE_{I}/EQE_{R} was calculated based on a combination of the example or the comparative example, and the reference example as shown in Table 4. The calculation results are also shown in Table 4.

In Table 4, EQE₁ represents the EQE of Examples 1 to 5 or Comparative Example 1. EQE_{R} indicates the EQE of the reference examples.

TABLE 4

| | | EQE_{I}/ |
|---|---|---|
| Example (used ink) | Reference Example (used ink) | EQE_{R} |
| Example 1 (I-1) | Reference Example 1a (R-1) | 1.00 |
| Example 2 (I-2) | Reference Example 1a (R-1) | 0.88 |
| Example 3 (I-3) | Reference Example 1b (R-1) | 1.05 |
| Example 4 (I-4) | Reference Example 2 (R-2) | 1.09 |
| Example 5 (I-5) | Reference Example 3 (R-3) | 0.99 |
| Comparative Example 1 (C-1) | Reference Example 4 (R-4) | 0.41 |

The following matters can be seen from the results in Table 4.

The results show that, in the photoelectric conversion elements according to Examples 1 to 5, the value of EQE_{I}/EQE_{R} is around 1, and the EQE is not significantly reduced as compared with the photoelectric conversion elements according to the reference examples which contain no insulating material.

On the other hand, when the used ink contains no non-fullerene compound as an n-type semiconductor material and the n-type semiconductor material is composed of only a fullerene compound, the value of EQE_{I}/EQE_{R} of the photoelectric conversion element according to Comparative Example 1 is remarkably small, and the EQE is significantly reduced as compared with the photoelectric conversion elements according to the reference examples which contain no insulating material.

The above results show that a composition containing a p-type semiconductor material, an n-type semiconductor material, an insulating material, and a solvent, in which the composition contains a non-fullerene compound as the n-type semiconductor material, is useful as an ink for producing an active layer of a photoelectric conversion element, and such a composition can improve the film formability of the active layer while maintaining EQE.

<Evaluation of Ink Stability 1: Film Formability and Stability of EQE>

### [Preparation Example 6] Preparation of Ink I-6

The polymer P-1 which is a p-type semiconductor material was added to the mixed solvent so as to have a concentration of 1.1 wt % with respect to the total weight of the ink.
The compound N-1 which is an n-type semiconductor material was added to the mixed solvent so as to have a concentration of 1.1 wt % with respect to the total weight of the ink.
As an insulating material, the compound Z-3 was used in place of the compound Z-1, and the compound Z-3 was added to the mixed solvent so as to have a concentration of 0.55 wt % with respect to the total weight of the ink.

An ink I-6 was obtained by the same operation as in Preparation Example 1 except for the above items.

### [Preparation Example 7] Preparation of Ink I-7

The polymer P-1 which is a p-type semiconductor material was added to the mixed solvent so as to have a concentration of 0.88 wt % with respect to the total weight of the ink.
The compound N-1 which is an n-type semiconductor material was added to the mixed solvent so as to have a concentration of 1.1 wt % with respect to the total weight of the ink.
As an insulating material, the compound Z-3 was used in place of the compound Z-1, and the compound Z-3 was added to the mixed solvent so as to have a concentration of 0.77 wt % with respect to the total weight of the ink.

An ink I-7 was obtained by the same operation as in Preparation Example 1 except for the above items.

### [Comparative Preparation Example 2] Preparation of Ink C-2

The polymer P-1 which is a p-type semiconductor material was added to the mixed solvent so as to have a concentration of 1.4 wt % with respect to the total weight of the ink.
The compound N-1 which is an n-type semiconductor material was added to the mixed solvent so as to have a concentration of 1.4 wt % with respect to the total weight of the ink.
The compound Z-1 as an insulating material was not added to the mixed solvent.

An ink C-2 was obtained by the same operation as in Preparation Example 1 except for the above items.

The formulation of each preparation example is shown in Table 5 below.

In Table 5 below, the total solid content concentration indicates the total content of the p-type semiconductor material, the n-type semiconductor material, and the insulating material in the ink.

TABLE 5

| | | | p-type semiconductor | | n-type semiconductor | | | | Total solid |
|---|---|---|---|---|---|---|---|---|---|
| | | | material | | material | | Insulating material | | content |
| | | | | Concentration | | Concentration | | Concentration | concentration |
| | | Solvent | Type | (wt %) | Type | (wt %) | Type | (wt %) | (wt %) |
| Preparation | I-6 | TNP/BBZ | P-1 | 1.10 | N-1 | 1.10 | Z-3 | 0.55 | 2.75 |
| Example 6 | | | | | | | | | |
| Preparation | I-7 | TNP/BBZ | P-1 | 0.88 | N-1 | 1.10 | Z-3 | 0.77 | 2.75 |
| Example 7 | | | | | | | | | |
| Comparative | C-2 | TNP/BBZ | P-1 | 1.40 | N-1 | 1.40 | — | — | 2.80 |
| Preparation | | | | | | | | | |
| Example 2 | | | | | | | | | |

### Examples 6 and 7 and Comparative Example 2

The ink I-6, I-7, or C-2 prepared on the previous day was used as an ink, and the rotation speed X was set as shown in Table 6.

Photoelectric conversion elements were produced and evaluated in the same manner as in Example 1 except for the above items. The thickness of the obtained active layer is shown in Table 6.

### Example 6′, Example 7′, Comparative Example 2′, Comparative Example 2″

The ink I-6, I-7, or C-2 stored at normal temperature in a dark place for 30 days after preparation was used as an ink, and the rotation speed X was set as shown in Table 6.

Photoelectric conversion elements were produced and evaluated in the same manner as in Example 1 except for the above items. The thickness of the obtained active layer is shown in Table 6.

TABLE 6

| | | Number of ink | Spin coating | |
|---|---|---|---|---|
| | | storage days | rotation speed | Film thickness |
| | Ink | (day) | (rpm) | (nm) |
| Example 6 | I-6 | 0 | 900 | 270 |
| Example 6′ | I-6 | 30 | 900 | 270 |
| Example 7 | I-7 | 0 | 900 | 270 |
| Example 7′ | I-7 | 30 | 900 | 270 |
| Comparative | C-2 | 0 | 700 | 270 |
| Example 2 | | | | |
| Comparative | C-2 | 30 | 700 | 330 |
| Example 2′ | | | | |
| Comparative | C-2 | 30 | 800 | 270 |
| Example 2″ | | | | |

[Evaluation Result of Film Formability]

The results of Examples 6 and 7 with respect to Comparative Example 2 show that the inks I-6 and I-7 in which a part of the p-type semiconductor material and the n-type semiconductor material is replaced with the insulating material without changing the total solid content concentration can yield an active layer having the same thickness as that of an active layer produced from the ink C-2 containing no insulating material, even when the rotation speed at the time of application by the spin coating method is increased.

Further, the result of Example 6′ with respect to Example 6 and the result of Example 7′ with respect to Example 7 show that, even when an ink after storage for 30 days is used, an active layer having the same thickness as that of an active layer produced using an ink before storage can be produced under the same conditions (rotation speed) of the spin coating method as in the case of using the ink before storage.

On the other hand, the results of Comparative Example 2′ and Comparative Example 2″ with respect to Comparative Example 2 show that, when the ink C-2 containing no insulating material is stored for 30 days, the film formability of the ink C-2 changes as compared with the film formability before storage. That is, with an ink after storage for 30 days, an active layer having a thickness larger than that in the case of using the ink before storage is obtained under the same spin coating conditions (rotation speed) as in the case of using the ink before storage (Comparative Example 2′). In order to obtain an active layer having a thickness equal to that in the case of using the ink before storage, it was necessary to readjust the conditions of the spin coating method (Comparative Example 2″).

The above results show that the variation in film formability due to storage is suppressed by containing the insulating material in the ink.

[Measurement Result of EQE]

The EQE₁ according to each of Examples 6 to 7 and 6′ to 7′ was normalized by dividing the EQE (EQE₁) according to each of Examples 6 to 7 and 6′ to 7′ in which the active layer was produced from an ink containing an insulating material by the EQE (EQE_{c}) according to each of Comparative Examples 2 and 2′ in which the active layer was produced from an ink containing no insulating material, and the ratio EQE_{I}/EQE_{c} was calculated. Specifically, the ratio EQE_{I}/EQE_{c} was calculated by a combination of the example and the comparative example as shown in Table 7. The calculation results are also shown in Table 7.

In Table 7, EQE₁ represents the EQE of Example 6, Example 6′, Example 7, or Example 7′. EQE_{c} represents the EQE of Comparative Example 2, Comparative Example 2′, or Comparative Example 2″.

TABLE 7

| Example | Comparative Example | EQE_{I}/EQE_{C} |
|---|---|---|
| Example 6 | Comparative Example 2 | 0.90 |
| Example 6′ | Comparative Example 2″ | 0.90 |
| Example 7 | Comparative Example 2 | 0.95 |
| Example 7′ | Comparative Example 2″ | 1.01 |

The results in Table 7 show that the photoelectric conversion elements produced using the inks I-6 and I-7 in which a part of the p-type semiconductor material and the n-type semiconductor material is replaced with an insulating material without changing the total solid content concentration have an EQE of 90% or more with respect to the EQE of the photoelectric conversion element produced using the ink C-2 containing no insulating material.

<Evaluation of Ink Stability 2: Stability of Viscosity>

The viscosity of each of the ink I-6, the ink I-7, and the ink C-2 prepared in Preparation Example 6, Preparation Example 7, and Comparative Preparation Example 2 was measured on the day of preparation, and defined as an initial viscosity B₀ (cP). Further, these inks were stored at normal temperature in a dark place for 30 days, and then the viscosity thereof was measured and defined as a viscosity B₃₀ (cP) after storage.

The viscosity was measured with a rotary viscometer (“DV2TLV”, manufactured by Brookfield Engineering Laboratories, Inc.) under the conditions of a spindle temperature of 30° C. and a rotation speed of 10 rpm. The rate of change in viscosity of each ink during storage for 30 days was calculated according to the following equation.

Rate of viscosity change (%)=(B₃₀−B₀)/B₀×100

The results are shown in Table 8.

TABLE 8

| | Viscosity B₀ (cP) | Viscosity B₃₀ (cP) | |
|---|---|---|---|
| | (number of storage | (number of storage | Rate of viscosity |
| | days: 0 days) | days: 30 days) | change |
| I-6 | 13.4 | 16.9 | 26.1% |
| I-7 | 10.9 | 13.1 | 20.2% |
| C-2 | 14.6 | 20.7 | 41.8% |

The results in Table 8 show that the rate of viscosity change is remarkably lower in the inks I-6 and I-7 than in the ink C-2, and the ink containing an insulating material can suppress the temporal change in viscosity (particularly, increase in viscosity). Thus, the stability of the film forming process can be improved by improving the stability of the ink. When the film forming process is stable, a film having stable quality can be produced without significantly changing the conditions in the film forming step.

### DESCRIPTION OF REFERENCE SIGNS

1 Image detection part
2 Display device
10 Photoelectric conversion element
11, 210 Supporting substrate
12 First electrode
13 Hole transportation layer
14 Active layer
15 Electron transportation layer
16 Second electrode
17 Sealing member
20 CMOS transistor substrate
30 Interlayer insulating film
32 Interlayer wiring part
40 Sealing layer
42 Scintillator
44 Reflective layer
46 Protective layer
50 Color filter
100 Fingerprint detection part
200 Display panel part
200a Display region
220 Organic EL element
230 Touch sensor panel
240 Sealing substrate
300 Vein detection part
302 Glass substrate
304 Light source part
306 Cover part
310 Insertion part
400 Image detection part for TOF type distance measuring device
402 Floating diffusion layer
404 Photogate
406 Light shielding part

1. A composition comprising: a p-type semiconductor material; an n-type semiconductor material; an insulating material; and a solvent, wherein the n-type semiconductor material contains a non-fullerene compound.

2. The composition according to claim 1, wherein the insulating material is a material that dissolves in an amount of 0.1 wt % or more in the solvent at 25° C.

3. The composition according to claim 1, wherein the insulating material contains a polymer containing a constituent unit represented by the following Formula (I): 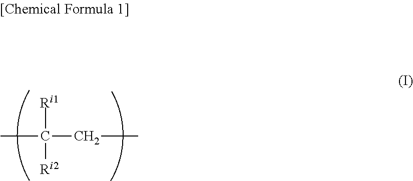
wherein
Rⁱ¹ represents a hydrogen atom, a halogen atom, or an alkyl group having 1 to 20 carbon atoms, and
Rⁱ² represents a hydrogen atom, a halogen atom, an alkyl group having 1 to 20 carbon atoms, a group represented by the following Formula (II-1), a group represented by the following Formula (II-2), or a group represented by the following Formula (II-3): 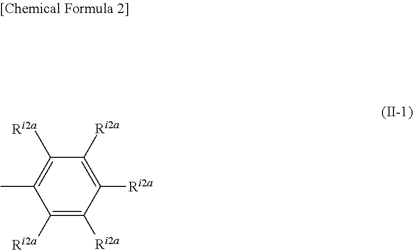
wherein
a plurality of R^{i2a}s each independently represent a hydrogen atom, a halogen atom, or an alkyl group having 1 to 20 carbon atoms; 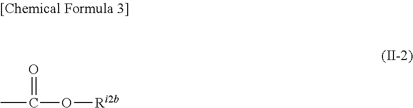
wherein
R^{i2b} represents a hydrogen atom or an alkyl group having 1 to 20 carbon atoms; and 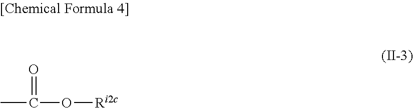
wherein
R^{i2c} represents an alkyl group having 1 to 20 carbon atoms.

4. The composition according to claim 1, wherein the p-type semiconductor material contains a polymer containing one or more types of constituent units selected from the group consisting of a constituent unit represented by the following Formula (III) and a constituent unit represented by the following Formula (IV): 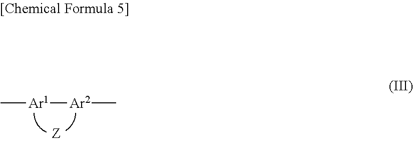
wherein
Ar¹ and Ar² each independently represent a trivalent aromatic heterocyclic group optionally having a substituent, and
Z represents a group represented by the following Formulae (Z-1) to (Z-7): 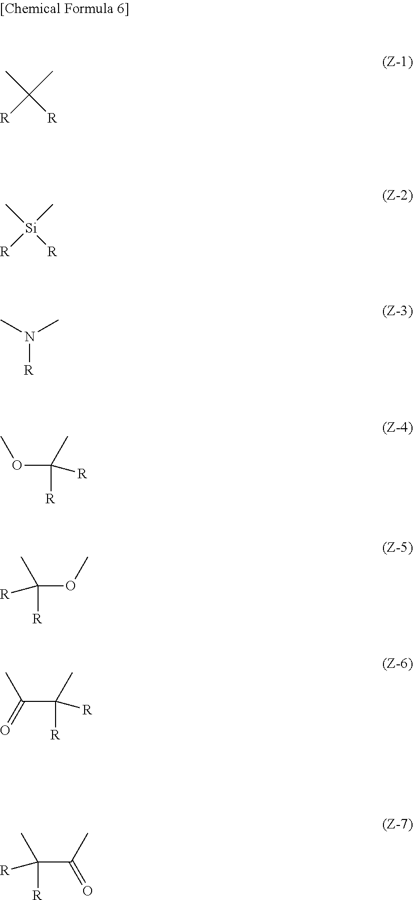
wherein
R is
a hydrogen atom,
a halogen atom,
an alkyl group optionally having a substituent,
a cycloalkyl group optionally having a substituent,
an alkenyl group optionally having a substituent,
a cycloalkenyl group optionally having a substituent,
an alkynyl group optionally having a substituent,
a cycloalkynyl group optionally having a substituent,
an aryl group optionally having a substituent,
an alkyloxy group optionally having a substituent,
a cycloalkyloxy group optionally having a substituent,
an aryloxy group optionally having a substituent,
an alkylthio group optionally having a substituent,
a cycloalkylthio group optionally having a substituent,
an arylthio group optionally having a substituent,
a monovalent heterocyclic group optionally having a substituent,
a substituted amino group optionally having a substituent,
an imine residue optionally having a substituent,
an amide group optionally having a substituent,
an acid imide group optionally having a substituent,
a substituted oxycarbonyl group optionally having a substituent,
a cyano group,
a nitro group,
a group represented by —C(═O)—R^{a}, or
a group represented by —SO₂—R^{b},
R^{a} and R^{b} each independently represent
a hydrogen atom,
an alkyl group optionally having a substituent,
a cycloalkyl group optionally having a substituent,
an aryl group optionally having a substituent,
an alkyloxy group optionally having a substituent,
a cycloalkyloxy group optionally having a substituent,
an aryloxy group optionally having a substituent, or
a monovalent heterocyclic group optionally having a substituent, and
when there are two Rs, the two Rs may be the same or different; and
—Ar³— (IV)
wherein Ar³ represents a divalent aromatic heterocyclic group.

5. A film comprising: a p-type semiconductor material; an n-type semiconductor material; and an insulating material, wherein the n-type semiconductor material contains a non-fullerene compound.

6. An organic photoelectric conversion element comprising: a first electrode; the film according to claim 5; and a second electrode in this order.

7. A photodetection element comprising the organic photoelectric conversion element according to claim 6.
